(19) United States
(12) Patent Application Publication
(10) Pub. No.: US 2018/0350412 A1
(43) Pub. Date: Dec. 6, 2018

(54) SYSTEMS AND METHODS FOR ADAPTIVE PARALLEL-SERIAL CONVERSION OPERATIONS

(71) Applicant: SanDisk Technologies LLC, Plano, TX (US)

(72) Inventors: Jiwang Lee, San Jose, CA (US); Anil Pai, San Jose, CA (US)

(21) Appl. No.: 15/615,598

(22) Filed: Jun. 6, 2017

(51) Int. Cl. G11C 7/10; G11C 8/10; H03M 9/00

(52) U.S. Cl. CPC G11C 7/103; H03M 9/00; G11C 8/10

(57) ABSTRACT

An adaptive parallel-serial converter may receive parallel data comprising a data unit in a first data format and generate a data sequence comprising the data unit in a second format, different from the first data format. The adaptive parallel-serial converter may comprise a serialization circuit comprising a plurality of registers, which may be configured to shift data of the data unit in a circular, reversible pattern. Selection circuitry may select one of the registers to produce a sequence of data values as data is shifted in either a forward direction or a reverse direction. The output selection and shift direction may be configured to convert the format of the data unit as the data unit is serialized.

### BACKGROUND

This disclosure relates to techniques for manipulating data formatting and, more specifically, for manipulating the format of data while performing parallel-serial conversions (e.g., while performing parallel-to-serial and/or serial-to-parallel data conversions).

The term “data” typically refers to a collection of data values, such as bits, bytes, and/or the like. A collection of data values may be referred to as a “data unit.” A computing system may be configured to format and/or interpret data units according to a particular format. A computing system may be configured to arrange data units according to a particular “endianness” and/or bit-numbering. As used herein, the “endianness” or “bit-numbering” of a data unit refers to the order in which the bytes and/or bits comprising a data unit are interpreted, stored, read, and/or communicated by a computing system. A first computing system may be configured to write data units to a memory according to a first endian format. The memory may be communicatively coupled to a second, different computing system, which is configured to interpret data according to a second, different endian format. The second computing system may read data units written by the first computing system from the memory. The second computing system may misinterpret the data units due to, inter alia, the different endian format used by the first and second computing systems.

### SUMMARY

Embodiments of an adaptive parallel-serial converter are disclosed. The disclosed adaptive parallel-serial converter may be configured to modify a data format of parallel data as such data is being serialized. Alternatively, or in addition, the disclosed adaptive parallel-serial converter may be further configured to modify a data format of serial data as such data is being arranged in parallel and/or written to memory. Modifying the data format of a data unit may comprise changing the endianness of the data unit from a first endianness to a second, different endianness. The endianness conversion may be performed while the data is being serialized and/or parallelized, which may obviate the need for additional processing steps and/or circuitry (e.g., dedicated endianness conversion operations).

Disclosed herein are embodiments of an apparatus for modifying a data format (e.g., endianness) of a data unit while serializing the data unit. Embodiments of disclosed apparatus may comprise a buffer configured to receive parallel data comprising a data unit, the data unit having a parallel arrangement that corresponds to a first data format for the data unit, and a serialization circuit configured to modify a format of the data unit concurrent with serializing the parallel data. The serialization circuit may be configured to output a data sequence comprising data of the data unit in a sequential order. Modifying the format of the data unit concurrent with serializing the parallel data may comprise arranging the sequential order of the data such that the sequential order of the data in the data sequence corresponds to a second data format for the data unit, different from the first data format. The first data format may correspond to a first endianness, and the second data format may correspond to a second endianness. The data unit may be stored within one or more memory cells of a non-volatile memory structure, and the serialization circuit may be embodied on the non-volatile memory structure.

The serialization circuit may comprise a series of shift buffers configured to circularly shift data of the data unit in a selected shift direction based on a shift control signal. The selected direction may comprise one of a forward direction and a reverse direction, wherein, to circularly shift data in the forward direction, a first shift buffer of the series is configured to shift data to a last shift buffer of the series, and wherein, to circularly shift data in the reverse direction, the last shift buffer is configured to shift data to the first shift buffer. The serialization circuit may further comprise selection logic communicatively coupled to the shift buffers in the series to select one of the shift buffers to output the data sequence based on an output select signal. In some embodiments, the serialization circuit further includes format conversion logic configured to determine the shift control signal and the output select signal in response to comparing the first endianness to the second endianness. The format conversion logic may comprise a plurality of data format conversions, each data format conversion configured to modify the endianness of parallel data from an input endianness to a requested endianness concurrently with serializing the parallel data. The format conversion logic may be configured to identify a data format conversion to modify the endianness of parallel data from the first endianness to the second endianness, and to determine the shift control signal and the output select signal based on the identified data format conversion.

The data unit may comprise a plurality of data elements. A first one of the data elements may be a most significant data element. The most significant data element may be output in a first sequential order in the data sequence in accordance with the first data format. The serialization circuit may be configured to output the first data element in a second sequential order in the data sequence while serializing the parallel data comprising the data unit, the second sequential order different from the first sequential order.

The disclosed apparatus may include a controller configured to receive a request to read the data unit, determine a requested data format for the data unit, and to instruct the serialization circuit to modify a format of the data unit in accordance with the requested data format. In some embodiments, the apparatus comprises memory logic configured to determine that the data unit is stored within the one or more physical storage locations of a memory according to the first data format based on one or more of: metadata pertaining to the data unit stored within the memory, a header of the data unit, configuration data, a register value, a data format table, and/or the like. The serialization circuit may be configured to transmit data of the data sequence on a data bus during each of a plurality of communication periods. The sequential order of the data in the data sequence may determine an order in which the data is transmitted on the data bus during the communication periods.

Disclosed herein are embodiments of methods for performing data format modifications while serializing (and/or parallelizing) data. Embodiments of the methods disclosed herein may comprise: receiving a plurality of data elements of a data unit, wherein parallel data positions of the data elements corresponds to a first endianness for the data unit, and performing a serialization operation configured to modify the endianness of the data while outputting the data elements of the data unit in a series. Performing the serialization operation may include: latching data of the data elements into respective flip flop circuits in a circular series of flip flop circuits, each flip flop circuit being communicatively coupled to output selection circuitry, configuring the circular series of flip flop circuits to shift the data of the data elements in a determined shift direction during the serialization operation, the determined shift direction comprising one of a forward shift direction and a reverse shift direction, configuring the output selection circuitry to a select a flip flop circuit of the circular series of flip flop circuits as an output flip flop for the serialization operation, the output flip flop circuit to output the data elements of the data unit in the series, shifting data latched in circular series of flip flop circuits in the determined shift direction during each of a plurality of cycles of a clock signal, and using the selection circuitry to output the data elements of the data unit from the output flip flop circuit such that each data element is output during a respective cycle of the clock signal, wherein an arrangement of the data elements in the series corresponds to a second endianness for the data unit, the second endianness different from the first endianness.

The shift direction for the serialization operation may be determined by, inter alia, comparing the first endianness to the second endianness. Configuring the circular series of flip flop circuits to shift the data of the data elements in the determined shift direction may comprise generating a shift control signal for the flip flop signals. The output flip flop circuit for the serialization operation may be selected based on the parallel data positions of the data elements of the data unit. The output selection circuitry may comprise multiplexer circuitry, and configuring the output selection circuitry may comprise generating a selection control signal for the multiplexer circuitry.

In some embodiments, the disclosed method includes selecting a data format conversion for the serialization operation from a plurality of data format conversions based on the first endianness and the second endianness, wherein the selected data format conversion specifies a shift direction and the output flip flop circuit for the serialization operation. The series of flip flop circuits may comprise a first flip flop and a last flip flop. Inputs of each of the flip flops may be selectively coupled to outputs of adjacent flip flops in the series such that an input of the first flip flop being selectively coupled to an output of the last flip flop, and an input of the last flip flop being selectively coupled to an output of the first flip flop.

Some embodiments of the method disclosed herein further comprises determining one or more of the first endianness of the data unit and the second endianness for the data unit, and accessing a format conversion library to determine the shift direction and the output flip flop circuit for the serialization operation based on a comparison of the first endianness to the second endianness. The format conversion library may comprise a plurality of data format conversions, each data format conversion configured to convert an input endianness to a requested endianness and comprising a respective shift direction and output location. The method may further include identifying a data format conversion in the library configured to convert the first endianness to the second endianness, such that the determined shift direction for the serialization operation corresponds to the shift direction of the identified data format conversion, and the selected output flip flop for the serialization operation corresponds to the output location of the identified data format conversion.

Disclosed herein are embodiments of circuits for modifying the endianness of data during serialization and/or parallelization operations. The disclosed circuit may include a plurality of data latches connected in sequence, wherein each data latch is configured to store a respective data bit of a data unit, the data unit having a parallel arrangement that corresponds to a first data format for the unit, selection circuitry configured to receive outputs of each of the data latches and to output data bits shifted through a selected one of the data latches in response to the clock signal to produce a sequence of data bits of the data unit, and format control logic configured to control the shift direction of the shift circuitry and the data latch selected by the selection circuitry such that a sequential order of the data bits of the data unit in the sequence correspond to a second data format, the second data format different from the first data format.

The data latches may comprise shift circuitry configured to shift the data bits stored therein to an adjacent data latch in the sequence in one of two or more shift directions responsive to a clock signal, the two or more shift directions comprising a forward shift direction and a reverse shift direction, wherein in the forward shift direction, a data bit stored in a first data latch of the sequence is shifted into a last data latch of the sequence, and wherein in the reverse shift direction a data bit stored in the last data latch is shifted into the first data latch. The sequential positions of the data bits of the data units in the sequence produced on the selected data latch may correspond to the second data format for the data unit. In some embodiments, the data latches comprise reversible latches, and the format control logic is configured to generate a reverse signal to control the shift direction of the reversible latches. The selection circuitry may comprise a multiplexer, and the format control logic may be configured to generate a select control signal for the multiplexer. The format conversion logic may be configured to determine the shift direction for the shift circuitry and the data latch selected by the selection circuitry to produce the sequence of data bits in response to comparing the first data format to the second data format.

Disclosed herein are embodiments of a system for modifying the format of a data while the data unit is serialized and/or parallelized. The system may comprise means for receiving parallel data, the parallel data comprising data elements of a data unit in a first data format, and means for changing the data format of the data unit from the first data format to a second data format while the parallel data is converted into a data sequence comprising the data elements of the data unit. The means for changing the data format may comprise means for circularly shifting the data elements of the data unit responsive to a clock signal, means for generating the data sequence to serialize the parallel data comprising the data unit by outputting a data element at a designated shift location during each of a plurality of cycles of the clock signal, and means for controlling the shift direction and the designated shift location such that a sequential arrangement of the data elements of the data unit in the data sequence generated to serialize the parallel data corresponds to the second data format, different from a sequential arrangement corresponding to the first data format. The data elements may be circularly shifted within a sequence of shift locations in one of two or more shift directions, including a forward direction in which a data element at a last shift location of the sequence is shifted towards first shift location of the sequence and a data element at the first shift location is shifted to the last shift location, and a reverse direction in which the data element at the first shift location is shifted towards the last shift location and the data element at the last shift location is shifted to the first shift location.

### BRIEF DESCRIPTION OF THE DRAWINGS

FIG. 1 depicts exemplary embodiments of a data unit comprising a plurality of data elements.

FIG. 2A is a schematic block diagram depicting an embodiment of a system 200 comprising an adaptive parallel-serial converter configured to modify data formatting while performing parallel-serial conversion operations.

FIG. 2B is a schematic block diagram depicting an embodiment of a system 200 comprising an adaptive parallel-serial converter configured to modify data formatting while performing parallel-serial conversion operations.

FIG. 3 depicts embodiments of data serialization operations that include modifications to the data format of the data being serialized.

FIG. 4 is a schematic block diagram of one embodiment of an adaptive parallel-serial converter.

FIG. 5 is a schematic block diagram of adaptive parallel-serial conversion circuitry.

FIG. 6 is a schematic block diagram of another embodiment of an adaptive parallel-serial converter.

FIG. 7 is a schematic block diagram of an embodiment of serialization circuitry comprising registers having selectable inputs.

FIG. 8 is a schematic block diagram of serialization circuitry comprising reversible latches.

FIG. 9 is a schematic block diagram of one embodiment of a reversible latch circuit.

FIG. 10 is a schematic block diagram of one embodiment of a memory system comprising an adaptive parallel-serial and serial-parallel converter.

FIG. 11 is a schematic block diagram of one embodiment of an adaptive parallel-serial converter configured to modify data formatting during one or more of serialization and parallelization operations;

FIG. 12 is a schematic block diagram of another embodiment of an adaptive parallel-serial converter configured to modify data formatting during one or more of serialization and parallelization operations;

FIG. 13 is a schematic block diagram of another embodiment of parallelization circuitry of the disclosed adaptive parallel-serial converter;

FIG. 14 is a flow diagram of one embodiment of a method for modifying a data format of a data unit during serialization of the data unit.

FIG. 15 is a flow diagram of another embodiment of a method for modifying a data format of a data unit while serializing the data unit.

FIG. 16 is a flow diagram of one embodiment of a method for modifying the data format of a data unit while parallelizing the data unit.

FIG. 17 is a flow diagram of one embodiment of a method for modifying the data format of a data unit while performing one of a parallel-to-serial convesrsion and a serial-to-parallel conversion.

### DETAILED DESCRIPTION

Embodiments of an adaptive parallel-serial converter are disclosed. The disclosed adaptive parallel-serial converter may be configured to modify a data format of parallel data as such data is being serialized. Alternatively, or in addition, the disclosed adaptive parallel-serial converter may be further configured to modify a data format of serial data as such data is being arranged in parallel and/or written to memory. Modifying the data format of a data unit may comprise changing the endianness of the data unit from a first endianness to a second, different endianness. The endianness conversion may be performed while the data is being serialized and/or parallelized, which may obviate the need for additional processing steps and/or circuitry (e.g., dedicated endianness conversion operations).

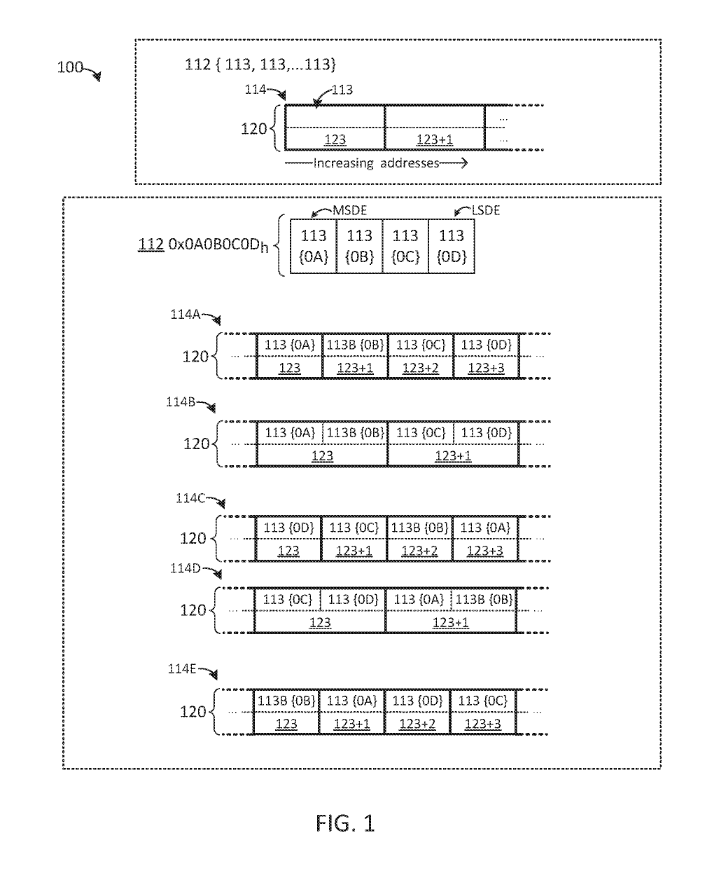

Referring to FIG. 1, computing systems may organize data into “data units” 112. As used herein, a data unit 112 refers to a collection and/or range of two or more data elements 113. A data element 113 refers to a quantum of data such as a byte (e.g., an eight-bit quantity), 16 bits of data, 32 bits of data, and/or the like. A data element 113 may correspond to an atomic element size of a computing system. A data unit 112 may be of any suitable size and may comprise any number of data elements 113. A data unit 112 may, for example, comprise four eight-bit data elements 113 (e.g., may comprise a 32-bit data unit 112).

A computing system may be configured to manage data units 112 in accordance with a particular data format 114. As used herein, a data format 114 refers to a manner in which the data elements 113 of a data unit 112 are represented, interpreted, and/or arranged by a computing system. The data format 114 of a data unit 112 may refer to one or more of: size (e.g., the number of bits comprising the data element 113), a size and/or configuration of the data elements 113 comprising the data unit 112 (e.g., eight-bit data elements 113, 16-bit data elements 113), an arrangement of the data elements 113 in memory, an ordering of the data elements 113, and so on. The data format 114 of a data unit 112 may define an “endianness” of the data unit 112. The “endianness” of a data unit 112 refers to an arrangement and/or configuration of the data elements 113 of a data unit 112. The endianness of a data unit 112 may determine the order in which data elements 113 of a data unit 112 are written to memory, the order in which data elements 113 are arranged for parallel communication, the sequential order of data elements 113 for serial communication, and so on. The data format 114 used by a computing system may correspond to an architecture and/or instruction set of one or more physical processor(s) of the computing system, an architecture and/or instruction set of one or more virtual processor(s) of the computing system, an architecture and/or instruction set of one or more devices of the computing system (e.g., graphical processing unit(s) of the computing system), an execution platform of the computing system, an application operating on the computing system, and/or the like. In some embodiments, the data format 114 of a computing system corresponds to a “native” data format of a processor of the computing system. A data format 114 may correspond to, inter alia, a particular endianness, which may include, but is not limited to: big endian, little endian, mixed endian, middle endian, PDP-endian, and or the like. A data format 114 may correspond to a byte-level endianness, a bit-level endianness, and/or the like. A data format 114 may further correspond to a particular atomic element size, such as big endian with an eight-bit atomic element size (e.g., eight-bit data elements 113), big endian with a 16-bit atomic element size (e.g., 16-bit data elements 113), little endian with an eight-bit atomic element size, little endian with a 16-bit atomic element size, middle endian with an eight-bit atomic element size, and so on.

As illustrated in FIG. 1, the data format 114 of a data unit 112 may determine the manner in which data elements 113 of the data unit 112 are stored in a memory 120. As shown in FIG. 1, a data unit 112 may comprise a plurality of data elements 113, each of which may be stored at a respective address in a memory (e.g., memory 120, as disclosed in further detail herein). The relative order of the data elements 113 in the memory 120 may correspond to the data format 114 of the data unit 112. By way of non-limiting example, FIG. 1 depicts embodiments of various data formats 114 for a 32-bit data unit 112. By way of non-limiting example, the data unit 112 may comprise the hexadecimal value “0x0A0B0C0D” (168496141 in decimal notation). The data unit 112 may comprise a sequence of data elements 113, which may be ordered by relative significance from a most significant data element (MSDE) 113 {0A} to the least significant data element (LSDE) 113 {0D}. Each data element 113 may comprise a respective eight-bit data quantity (e.g., a respective byte of the data unit 112 {0x0A0B0C0D}). The MSDE 113 may comprise data value {0A}, the next most significant data element 113 may comprise data value {0B}, the next most significant data element 113 may comprise data value {0C}, and the least significant data element (LSDE) 113 may comprise data value {0D}.

As disclosed above, the data unit 112 may be written to storage in accordance with a particular data format 114. FIG. 1 depicts the data unit 112 with hexadecimal value “0x0A0B0C0D” in different data formats 114A-E. Each data format 114 may specify the manner in which the data elements 113 of the data unit 112 are written to memory, communicated in parallel, and/or communicated in sequence. The data format 114A may correspond to big-endian with eight-bit atomic elements. The data format 114A may comprise writing the data elements 113 in order of significance, with the MSDE 113 {0A} being written at a first storage address 123, and the other data elements 113 (0B, 0C, and 0D) being written by decreasing order of significance, such that the LSDE 113 {0D} is written to the last storage address for the data unit 112 (storage address 123+3).

The data format 114B may correspond to big endian with 16-bit atomic elements (e.g., each storage address 123 corresponding to two eight-bit quantities, or two data elements 113 of the data unit). In the data format 114B, the MSDE 113 {0A} and the next most significant data element 113 {0B} are written to the first storage address 123, and the less significant data elements 113 {0C, 0D} are written to storage address 123+1.

The data format 114C may correspond to little endian with eight-bit atomic elements. In the data format 114C, the order of the data elements 113 may be reversed relative to the data format 114A, such that the LSDE 113 {0D} is written to the first storage address 123 followed by the other data elements 113 in increasing order of significance, with the MSDE 113 {0A} being written at the last storage address 123+3 for the data unit 112.

The data format 114D may correspond to little endian with 16-bit atomic elements. In the data format 114D, the less significant data elements 113 {0C, 0D} are written at the first storage address 123, and the more significant data elements 113 {0A, 0B} are written to storage address 123+1.

The data format 114E may correspond to middle endian with eight-bit atomic elements. In the data format 114E, the data element 113 {0B} is written to the first storage address 123, the MSDE 113 {0A} is written to storage address 123+1, the LSDE 113 {0D} is written to storage address 123+2, and the data element 113 {0C} is written at the last storage address 123+3 of the data unit 112.

Although FIG. 1 refers to storage addresses, the disclosure is not limited in this regard and could be adapted to arrange the data units 112 for storage within other storage structures, such as memory pages, memory blocks, logical blocks, logical pages, and/or the like. Moreover, although particular examples of the data formats 114A-E are described herein, the disclosure is not limited in this regard and could be adapted for use with any suitable data format 114.

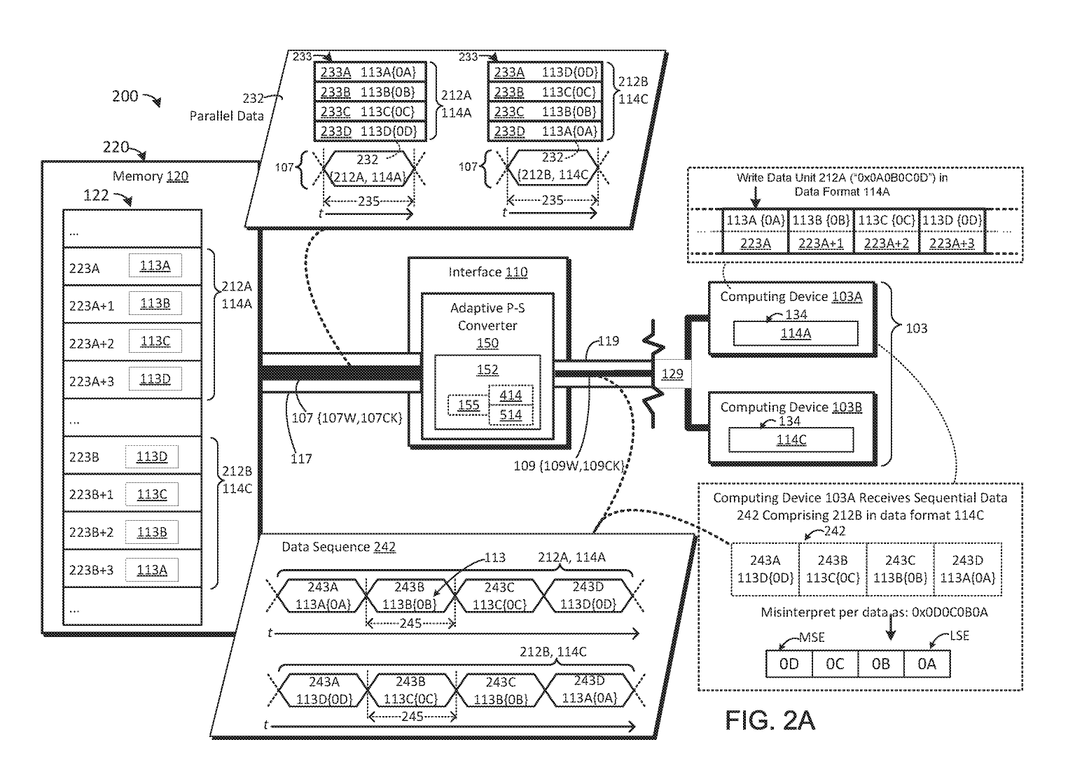

FIG. 2A is a schematic diagram of one embodiment of a system 200 for managing data communication. The system 200 may comprise the adaptive parallel-to-serial converter 150 which may be configured to manipulate and/or modify the format of data units 112 while parallel-to-serial conversion operations are performed on the data units 112. As disclosed in further detail herein, the adaptive parallel-to-serial converter 150 may be further configured to manipulate and/or modify the format of the data units 112 during serial-to-parallel conversion operations.

In the FIG. 2A embodiment, the adaptive parallel-to-serial converter 150 may be embodied within an interface 110. The interface 110 may comprise a data interface configured to manage communication of data units 112 over two (or more) different communication channels, each communication having a different width. As used herein, “communicating” data, such as a data unit 112, refers to any suitable means for communicating, transmitting, transferring, and/or conveying information. Communicating a data unit 112 may comprise communicating data values (bit values) of the data unit 112 as signals (data signals), which may include, but are not limited to: electrical voltage signals, electrical current signals, electro-optical signals (e.g., radio waves, microwaves, infrared radiation signals, and so on), a time variant signal, a digital signal, a modulated signal (e.g., data values may be encoded on a carrier signal), and/or the like. Data signals may be communicated via physical media, which may include, but are not limited to: wires, transmission lines, signal lines, signal traces, semiconductor vias, semiconductor channels, through-silicon vias (TSV), interconnect circuitry, data latches, data registers, switches, field effect devices (e.g., transistors), sense circuitry, signal driver circuitry, signal modulation circuitry, and/or the like. Alternatively, or in addition, data signals may be communicated wirelessly as, by way of non-limiting example, electro-optical signals, radio frequency signals, radio waves, microwaves, optical signals, and/or the like.

As illustrated in FIG. 2A, the interface 110 may be configured to communicate data units 112 in parallel via a first data bus 107 of a first interconnect 117. The first data bus 107 may have a width 107W configured to enable data values of the one or more data units 112 to be communicated in parallel. The first interconnect 117 may be configured to communicatively couple the interface 110 to a data source 220. The data source 220 may comprise any device and/or system capable of communicating the data units 112 including, but not limited to: a memory, a memory logic, a memory circuitry, a memory circuit, a memory semiconductor, a memory die, a memory core, a memory region, a memory plane, a memory chip, a memory package, a memory controller, a memory device, a memory system, a storage medium, a storage medium, a storage circuit, a storage controller, a storage device, a communication interface, a network interface, a computing device, a client computing device, a server computing device, and/or the like. In the FIG. 2A embodiment, the data source 220 comprises the memory 120. The disclosure is not limited in this regard, however, and could be adapted for use with any number and/or type of the data source 220.

The interface 110 may be further configured to communicate data units 112 on a second data bus 109 (of a second interconnect 119), which may have a different width 109W from the width 107W of the first data bus 107. The second data bus 109 may not be configured to communicate data units 112 in parallel. By way of non-limiting example, the width 109W of the second data bus 109 may be less than a size of a data unit 112 (e.g., may not be sufficient for parallel communication of the data values of a data unit 112). The adaptive parallel-to-serial converter 150 may be configured to manage communication of data units 112 between the first interconnect 117 and the second interconnect 119. The adaptive parallel-to-serial converter 150 may be configured to: a) receive data units 112 in parallel via the first data bus 107; and b) serialize the data units 112 for communication via the second data bus 109. Serializing data units 112 may comprise arranging the data units 112 for communication via the second data bus 109, which may comprise arranging the data units 112 for communication in sequence, during a plurality of different communication periods. As disclosed in further detail herein, serializing a data unit 112 may comprise modifying the data format 114 of the data unit 112.

As disclosed above, the interface 110 may be configured to communicate data units 112 in parallel via the first interconnect 117. Data units 112 may be communicated as parallel data 232 on the first data bus 107. As used herein, parallel data 232 refers to a parallel arrangement and/or format of a data unit 112. A parallel arrangement of a data unit 112 may determine the manner in which the data unit 112 is arranged for parallel communication as parallel data 232 (e.g., may correspond to an arrangement of the data elements 113 of the data unit 112 at respective parallel data positions 233). As used herein, a parallel data position 233 of a data value and/or data element 113 refers to a relative position and/or order of the data value and/or data element 113 within parallel data 232 and/or on a data bus, such as the first data bus 107. By way of non-limiting example, the data unit 112 of FIG. 2A may comprise four eight-bit data elements 113 (data elements 113A-D). FIG. 2A illustrates parallel data 232 comprising four parallel data positions 233A-D, each parallel data position 233 corresponding to a parallel arrangement of a respective data element 113A-D of a data unit 112. The parallel data positions 233 may correspond to data channels used to communicate the data unit 112 (e.g., each parallel data position 233 may correspond to a parallel data channel of the first data bus 107). As disclosed in further detail herein, the parallel arrangement of a data unit 112 may correspond to the data format 114 for the data unit 112 (e.g., the data format 114 in which the data unit 112 was stored in the memory 120). The first data bus 107 may be configured to communicate parallel data 232 during respective communication periods (parallel communication periods 235). The parallel communication periods 235 may correspond to a clock of the first data bus 107CK. The size and/or configuration of the parallel data 232 communicated via the first data bus 107 may correspond to properties of the first data bus 107. By way of non-limiting example, the size of the parallel data 232 may correspond to the width 107W of the first data bus 107. Accordingly, parallel data 232 communicated via the first data bus 107 may comprise 107W/N data units 112, where N is the size of a data unit 112. In the FIG. 2A embodiment, the width of the first data bus 107 is N (the size of a data unit 112) and, as such, parallel data 232 communicated on the first data bus 107 during a parallel communication period 235 may comprise a single data unit 112. The disclosure is not limited in this regard, in other embodiments, the width of the first data bus 107 may be greater than the size of a data unit 112. For example, the width 107W may be M times the size of a data unit 112 such that parallel data 232 communicated via the first data bus 107 during a parallel communication period 235 comprises a parallel arrangement of M data units 112.

The adaptive parallel-serial converter 150 may be configured to communicate data units 112 received as parallel data 232 via the second data bus 109. As disclosed above, the data bus 109 may not be configured to communicate data units 112 in parallel. The width 109W of the second data bus 109 may be less than the width 107W of the first data bus 107 (and less than the size of a data unit 112). The second data bus 109 may be configured to communicate 109W data values during a plurality of sequential communication periods 245. The sequential communication periods 245 may correspond to a clock signal 109CK of the second data bus 109. The adaptive parallel-serial converter 150 may receive parallel data 232 comprising a data unit 112 via the first data bus 107, and in response, may generate a corresponding data sequence 242 to communicate the data unit 112 via the second data bus 109. The data sequence 242 may arrange data of the data unit 112 in a sequential order for communication during respective sequential communication periods 245 (as opposed to a single parallel communication period 235). As used herein, a data sequence 242 refers to sequential arrangement and/or format of the data of a data unit 112 (e.g., a sequential order of the data elements 113). A data sequence 242 may comprise a plurality of sequential data positions 243, each sequential data position 243 corresponding to one of a plurality of sequential communication periods 245. In reference to the non-limiting example above, a data unit 112 that comprises N data values may be communicated during the N/109W sequential communication periods 245. The sequential arrangement of a data unit 112 may refer to the sequential data positions 243 of the data values and/or data elements 113 of the data unit 112. The sequential arrangement of a data unit 112 may determine the order in which the data values and/or data elements 113 of the data unit 112 are communicated on the second data bus 109; and may correspond to the data format 114 for the data unit 112. In the FIG. 2A embodiment, the width 109W of the second data bus 109 may correspond to a size of a data element 113. The adaptive parallel-serial converter 150 may serialize a data unit 112 by generating a data sequence 242 comprising each data element 113 of the data unit 112, the data sequence 242 arranging each data element 113A-D at a respective sequential data position 243A-D. Each data element 113A-D in the data sequence 242 may be communicated on the second data bus 109 during a respective sequential communication period 245. The order in which the data elements 113A-D are communicated on the second data bus 109 may correspond to the sequential data positions 243A-D of the data elements 113A-D.

Although particular embodiments for communicating data units 112 in parallel (e.g., as parallel data 232) and/or in sequence (e.g., as a data sequence 242) are described herein, the disclosure is not limited in this regard and could be adapted for use with a first data bus 107 having any suitable width 107W, parallel data 232 of any suitable size and comprising any number of data values and/or data units 112, a second data bus 109 having any suitable width 109W, and/or data sequence(s) 242 configured to communicate data units 112 during any number of sequential communication periods 245.

As disclosed above, the interface 110 may be communicatively coupled to a memory 120 via, inter alia, the first interconnect 117. The memory 120 may comprise a plurality of data storage locations 122, each of which may be configured to store data, such as one or more data units 112. The storage locations 122 of the memory 120 may comprise any suitable means for writing and/or retrieving data including, but not limited to: volatile memory cells, non-volatile memory cells, Flash memory cells, a page of memory cells, a block of memory cells, an array of memory cells, a two-dimensional array of non-volatile memory cells, a three-dimensional array of memory cells, and/or the like.

The storage locations 122 of the memory 120 may be associated with respective addresses and/or address offsets, such as storage addresses 123 through 123+3. The interface 110 may be configured to communicate data units 112 to/from the memory 120 via the first interconnect 117. Data units 112 may be transferred to/from the memory 120 in parallel, as disclosed herein (e.g., as parallel data 232). The interface 110 may be configured to implement storage operations on the memory 120 in response to requests from one or more computing devices 103. The requests may include requests to store data units 112 to the memory 120, requests to read data units 112 from the memory 120, and so on. In some embodiments, the interface 110 may comprise a controller and/or control circuitry of the memory 120. In some embodiments, the memory 120 may be embodied within a memory structure, which may include, but is not limited to: a memory die, package, chip, substrate, semiconductor, and/or the like. The interface 110 may comprise memory circuitry and/or logic embodied on the memory structure with the memory 120. The memory 120 may be embodied within a memory region of the memory structure and the interface 110 may be embodied within a periphery region of the memory structure.

Computing devices 103 may access the memory 120 by use of the interface 110 (and/or second interconnect 119). The computing devices 103 may comprise one or more of: a server computing device, a personal computing device, a mobile computing device (e.g., a smartphone, a tablet, or the like), an embedded computing device, a virtualized computing device (e.g., a virtual machine operating within a virtualization environment of a host computing device), a virtualization host, a virtualization environment (e.g., a virtualization kernel, a hypervisor), and/or the like. The interface 110 may be communicatively coupled to one or more of the computing devices 103 through, inter alia, the second interconnect 119. The second interconnect 119 may, for example, be configured to communicatively and/or electrically couple with I/O infrastructure 129. Alternatively, or in addition, the second interconnect 119 may be a component of the I/O infrastructure 129. The I/O infrastructure 129 may comprise I/O infrastructure of a particular computing device 103, such as an internal bus, an internal interconnect, an I/O bus, a data channel, and/or the like. The I/O infrastructure 129 may include, but is not limited to: an input/output (I/O) bus, an I/O controller, a local bus, a host bridge (Northbridge, Southbridge, or the like), a front-side bus, a peripheral component interconnect (PCI), a PCI express (PCI-e) bus, a Serial AT Attachment (serial ATA or SATA) bus, a parallel ATA (PATA) bus, a Small Computer System Interface (SCSI) bus, a Direct Memory Access (DMA) interface, an IEEE 1394 (FireWire) interface, a Fiber Channel interface, a Universal Serial Bus (USB) connection, a network interface, a network connection, a storage network interface, a Storage Area Network (SAN) interface, a Virtual Storage Area Network (VSAN) interface, a remote bus, a PCI-e bus, an Infiniband interface, a Fibre Channel Protocol (FCP) interface, a HyperSCSI interface, a remove DMA (RDMA) interface, and/or the like. In some embodiments, the computing devices 103 may be selectively coupled and/or decoupled to the second interconnect 119. Coupling the second interconnect 119 to a computing device 103 may comprise electrically and/or communicatively coupling the second interconnect 119 (and second data bus 109) to the computing device (e.g., to the I/O infrastructure 129 of the computing device 103). In some embodiments, the memory 120 and/or the interface 110 are embodied within a stand-alone computing device and may be communicatively coupled to a plurality of computing devices 103. In other embodiments, the memory 120 and/or the interface 110 may be embodied as a peripheral device configured to be deployed within particular one of the computing devices 103 (e.g., coupled to an internal I/O bus of a computing device 103 (e.g., in a PCI-e slot on a motherboard of the computing device 103).

In the FIG. 2A embodiment, a computing device 103A may be communicatively coupled to the interface 110 via the second interconnect 119 and/or I/O infrastructure 129. The computing device 103A may implement storage operations by, inter alia, issuing storage requests to the memory 120. The storage requests may comprise requests to write data units 112 to the memory 120, read data units 112 from the memory 120, and so on.

The computing device 103A may be configured to interpret, represent, communicate, and/or store data units 112 according to a particular data format 114. The particular data format 114 used by the computing device 103A may be referred to as a native data format 134 of the computing device 103A. The native data format 134 of the computing device 103A may correspond to an internal architecture of a processor of the computing device 103A (e.g., architecture of the CPU of the computing device 103A). The native data format 134 of the computing device 103A may determine the data format 114 used to communicate data units 112 to the interface 110. For example, the computing device 103A may communicate data units 112 to the interface 110 for storage in the memory 120 (e.g., in a write request). The data units 112 communicated by the computing device 103A may be in the native data format 134 of the computing device 103A. Accordingly, data units 112 written to the memory 120 by the computing device 103A may be written in the native data format 134 of the computing device 103A. In the FIG. 2A embodiment, the native data format 134 of the computing device 103A is data format 114A (big-endian with 8-bit atomic elements). Accordingly, data units 112 written to the memory 120 by the computing device 103A may be communicated to the interface 110 and/or stored in the memory 120 in data format 114A. The computing device 103A may write a data unit 212A to a specified address 223A of the memory 120. By way of non-limiting example, the data unit 212A may comprise 32 bits of data arranged into four, eight-bit data elements 113A-D (bytes) having the hexadecimal value “0x0A0B0C0D.” The data unit 212A may comprise the following sequence of data elements 113, from the MSDE 113A to the LSDE 113D: {0A, 0B, 0C, 0D}. The computing device 103A may format the data unit 212A in accordance with the native data format 134 thereof (i.e., data format 114A).

The data unit 212A may be written to address 223A through 223A+3 within the memory 120. The arrangement of the data unit 212A in the memory 120 may correspond to the data format 114A. Therefore, when the data unit 212A “0x0A0B0C0D” is written to the memory 120, the data elements 113A-D may be arranged within the memory 120 in ascending order with the MSDE 113A being stored at a first address of the data unit 212A (address 223A), the second data element 113B being stored at a next ascending address (address 223A+1), the third data element 113C being written to a next ascending address (address 223A+2), and the LSDE 113D being written to the next (and last) ascending address for the data unit 212A (address 223A+3). Alternatively, or in addition, the data unit 212A may be written to a storage location 122 of the memory 120 that is capable of holding all of the data elements 113A-D thereof. In such embodiments, the data elements 113A-D may be arranged within the storage location 122 in accordance with the data format 114A of the data unit 112 (e.g., in ascending order in which the MSDE 113A is stored at a first offset within the storage location 122, the next most significant data element 113B is stored at a next ascending offset, and so on, with the LSDE 113D being stored at the last offset for the data unit 212A). Although FIG. 2A depicts the data elements 113A-D being written to a specified address 223A, the disclosure is not limited in this regard and, in some embodiments, the address 223A may comprise a logical identifier, a logical address, a logical block address, and/or the like. The interface 110 may be configured to translate the address 223A to physical address(es) within the memory 120, while retaining the arrangement of data elements 113 of the data unit 112.

The computing device 103A may read the data unit 212A from the memory 120, which may comprise issuing a request to read data from the address 223A. In response to the request, the interface 110 may read data from address 223A (e.g., read the data elements 113A-D stored at address 223A through 223A+3, which may result the following sequence of data elements 113 {0A, 0B, 0C, 0D} in accordance with the data format 114A in which the data unit 212A was stored within the memory 120.

The data read from address 223A through 223A+3 may be communicated from the memory 120 to the interface 110 via the first data bus 107. As disclosed above, the first data bus 107 may be configured to transmit the data unit 212A in parallel (e.g., as parallel data 232). The parallel arrangement of the data unit 212A may correspond to the data format 114A (the data format 114 in which the data unit 112 was stored in the memory 120). For example, the memory 120 may be configured to arrange data element 113 read from the “first” or “base” address of a read request at parallel data position 233A, arrange the data element 113 read from the next address at parallel data position 233B, and so on (with the data element 113 read from “last” address being arranged at parallel data position 233D). Accordingly, the parallel arrangement of a data unit 112 communicated via the first data bus 107 (as parallel data 232) may correspond to the data format 114A in which the data unit 212A is stored in the memory 120.

As disclosed above, reading the data unit 212A from address 223A of the memory 120 may comprise reading a sequence of data elements 113 from addresses 223A, 223A+1, 223A+2, and 223A+3, as follows: 113A{0A}, 113B{0B}, 113C{0C}, 113D{0D} (in ascending address order based on the data format 114A in which the data unit 212A is stored). As disclosed above, the memory 120 and/or the interface 110 may be configured to arrange the data elements 113 in accordance with the arrangement of such data elements 113 in the memory 120. As such, the parallel arrangement of data elements 113A-D may correspond to the data format 114A of the data unit 212A. As illustrated in FIG. 2A, the parallel arrangement of the data elements 113A-D corresponds to the relative order of the data elements 113A-D in the memory 120, with the MSDE 113A {0A} read from the first address 223A being arranged at parallel data position 233A, the next most significant data element 113B {0B} being arranged at parallel data position 233B, and so on, with the LSDE 113D read from the last address 223A+3 of the data unit 212A being arranged at parallel data position 233D.

The interface 110 may receive the parallel data 232 comprising the data unit 212A via the first data bus 107. In response, the interface 110 may be configured to communicate the data unit 212A to the computing device 103A via the second interconnect 119, which may comprise serializing the data unit 212A. As used herein, “serializing” a data unit 112 refers to converting parallel data 232 comprising the data unit 112 into a data sequence 242. The data sequence 242 may be configured to communicate the data unit 112 during a plurality of sequential communication periods 245 (on the second data bus 109). The number of sequential communication periods 245 required to communicate the data unit 112 may correspond to, inter alia, the size of the data unit 112 (and/or data elements 113 thereof) and the width 109W of the second data bus 109. In the FIG. 2A embodiment, the second data bus 109 may be configured to communicate a respective data element 113 during each sequential communication period 245 (e.g., the width 109W of the second data bus 109 may correspond to a size of a data element 113). Accordingly, in the FIG. 2A embodiment, the adaptive parallel-to-serial converter 150 may be configured to serialize the parallel data 232 comprising the data unit 212A by generating a data sequence 242 in which the data elements 113A-D of the data unit 212A are arranged at respective sequential data positions 243A-D (each data element 113A-D to be communicated on the second data bus 109 during a respective sequential communication period 245). The sequential arrangement of the data elements 113A-D (e.g., the respective sequential data positions 243A-D of the data elements 113A-D) may correspond to the data format 114A of the data unit 212A.

As disclosed in further detail herein, the adaptive parallel-serial converter 150 may be configured to modify the data format 114A of the data unit 212A by, inter alia, modifying a serial arrangement of the data elements 113A-D in the data sequence 242 used to communicate the data unit 212A on the second data bus 109. In some embodiments, the adaptive parallel-to-serial converter 150 may be configured to serialize data units 112 in a manner that retains the data format 114 of the data units 112 such that the data format 114 of the data units 112 as communicated via the first data bus 107 (e.g., as parallel data) corresponds to the data format of the data units 112 as communicated via the second data bus 109 (e.g., as a data sequence 242). Maintaining the data format 114 of a data unit 112 during serialization of parallel data 232 comprising the data unit 112 may comprise generating a data sequence 242 comprising the data unit 112, wherein a sequential arrangement of the data unit 112 corresponds to the parallel arrangement of the data unit 112 in the parallel data 232. Maintaining the data format 114 of a data unit 112 may comprise arranging the data elements 113 in sequence, such that the sequential data position 243 of each data elements 113 correspond to the parallel data positions 233 of the data elements 113 in the parallel data 232.

In the FIG. 2A embodiment, the adaptive parallel-serial converter 150 may be configured to maintain the data format 114A of the data unit 212A. Therefore, as disclosed above, the adaptive parallel-serial converter 150 may serialize the parallel data 232 comprising the data unit 212A by outputting the data element 113 (MSDE 113A) at parallel data position 233A first, at sequential data position 243A, outputting the data element 113 at parallel data position 233B next (data element 113B), at sequential data position 243B, and so on, with the data element 113 at parallel data position 113D (LSDE 113D) being output last, at sequential data position 243D, as follows {0A, 0B, 0C, 0D}. Since the sequential arrangement of the data elements 113A-D corresponds to the parallel data arrangement of the data unit 212A in the parallel data 232 (and the arrangement of the data unit 212A in the memory 120), the format of the data unit 212A is retained in the data sequence 242 (remains in data format 114A). More specifically, the sequential arrangement of the data elements 113A-D in the data sequence 242 corresponds to the original data format 114A used to store the data unit 212A within the memory 120 (i.e., big endian data format 114A in which data elements 113A-D are transmitted according to relative significance, with the MSDE 113A being transmitted first and the LSDE 113D being transmitted last). The computing device 103A may receive the data sequence 242 comprising the data unit 212A and, since the sequential arrangement of the data unit 212A corresponds to the data format 114A used by the computing device 103A, the computing device 103A may be capable of correctly interpreting the data unit 212A as communicated via the second data bus 109 (e.g., interpret the data sequence 242 as a 32-bit integer having the hexadecimal value “0x0A0B0C0D”).

As illustrated above, the data format 114 of a data unit 112 may determine: a) an arrangement of the data unit 112 in memory 120 (e.g., the relative addresses and/or offsets at which each data element is stored in the memory 120); b) a parallel data arrangement of the data unit 112 on the first data bus 107 (e.g., the relative parallel data positions 233 of the data elements 113 of the data unit 112 in parallel data 232 comprising the data unit 112); and c) a sequential data arrangement of the data unit 112 on the second data bus 109 (e.g., the relative sequential data positions 243 for the data elements 113 of the data unit 112 in a data sequence 242 comprising the data unit 112). As such, data units 112 having different data formats 114 may have different arrangements in storage (e.g., in memory 120), different parallel arrangements, different sequential arrangements, and so on.

In the FIG. 2A embodiment, the memory 120 may comprise a data unit 212B. The data unit 212B may be stored within the memory 120 in a data format 114C that is different than the native data format 134 used by the computing device 103A (and different from the data format 114A of data unit 212A). The data unit 212B may be arranged in the memory 120 according data format 114C (little endian with eight-bit atomic elements). The data unit 212B may have been written to the memory 120 by a computing device 103 other than the computing device 103A. The data unit 212B may have been written to the memory 120 by computing device 103B (e.g., while the computing device 103B was coupled to the memory 120 and/or the interface 110). The data unit 212B may have been written in the native data format 134 of the computing device 103B (e.g., data format 114C). The data unit 212B may comprise the same value as data unit 212A (hexadecimal value “0x0A0B0C0D”) and, like the data unit 212A, the data unit 212B may comprise four eight-bit data elements 113A-D, including an MSDE 113A having a value of {0A}, data element 113B having a value of {0B}, data element 113C having a value of {0C}, and LSDE 113D having a value of {0D}.

The data unit 212B may be arranged in the memory 120 in accordance with the data format 114C (little endian with eight-bit atomic elements). As such, the data elements 113A-D of the data unit 212B may be arranged in the memory 120 in ascending order of significance and, as such, the arrangement of data unit 212B in the memory 120 may differ from the arrangement of the data unit 212A in the memory 120. The data unit 212B may be stored at address 223B. The data unit 212B may be arranged in the memory 120 in accordance with the data format 114C such that: the LSDE 113D is stored at the first or lowest address for the data unit 212B (address 223B), the next least significant data element 113C is stored at a next address for the data unit 212B (address 223B+1), a next least significant data element 113B is stored at a next address for the data unit (address 223B+2), and the MSDE 113A is stored at the last or highest address for the data unit 212B (address 223B+3).

The computing device 103A may read the data unit 212B from address 223B. When the data unit 212B is read from the memory 120, the data elements 113A-D thereof may have a different parallel arrangement from the parallel arrangement of the data elements 113A-D of data unit 212A. The parallel data arrangement in of data unit 212B may correspond to the data format 114C. As shown in FIG. 2A, in the data format 114C: the data element 113 stored at the first or “base” address for the data unit 212B (address 223B) may be arranged at parallel data position 233A (LSDE 113D), the data element 113 stored at the next address for the data unit 212B (address 223B+1) may be arranged at parallel data position 233B (data element 113C), and so on, with the data element 113 stored at the last or highest address of the data unit 212B (address 223B+3) being arranged at parallel data position 233D (MSDE 113A). As illustrated, the parallel data arrangement of the data unit 212B corresponds to the data format 114C of the data unit 212B, with the data elements 113A-N being arranged in ascending order of significance, and differs from the parallel data arrangement of data unit 212A (data format 114A), in which the data elements 113A-D are arranged in decreasing order of significance.

The data format 114C may also correspond to a particular sequential arrangement, which may differ from the sequential arrangement of data format 114A. As disclosed above, in some embodiments, the adaptive parallel-serial converter 150 is configured to maintain data formatting while serializing parallel data 232 into a data sequence 242. In such embodiments, the adaptive parallel-serial converter 150 may be configured to arrange data elements 113 at sequential data positions 243 that correspond to their parallel data positions 233 within the parallel data 232 (and/or on the first data bus 107). In the FIG. 2A embodiment, the adaptive parallel-serial converter 150 may be configured to maintain the data format 114C of the data unit 212B, which may comprise generating a data sequence 242 wherein the data element 113 at parallel data position 233A (LSDE 113D) is output first, at sequential data position 243A, the data element 113C at parallel data position 233B (data element 113C) is output next, at sequential data position 243B, and so on, with the data element 113 at parallel data position 233D (MSDE 113A) being output last, at sequential data position 243D. As illustrated in FIG. 2A, the sequential arrangement of the data unit 212B may correspond to the original data format 114C of the data unit 212B such that the data elements 113A-D of the data unit 212B are communicated sequentially in ascending order of significance (from the LSDE 113D to the MSDE 113A).

The data format 114C may be incompatible with the computing device 103A. Accordingly, if the computing device 103A were to receive the data sequence 242 comprising the data unit 212B arranged according to the data format 114C, the computing device 103A may be unable to correctly interpret the data unit 212B. As depicted in FIG. 2A, if the computing device 103A were to receive the data sequence 242 comprising data unit 212B arranged in accordance with data format 114C (e.g., data elements 113A-D communicated in ascending order of significance, rather than in descending order of significance per data format 114A), the computing device 103A could interpret the data sequence 242 in accordance with data format 114A, which may comprise incorrectly interpreting the data element 113D at sequential data position 243A as the MSDE 113 of the data unit 112, incorrectly interpreting the next data element 113C at sequential data position 243B as the next most significant data element 113, and so on, with the data element 113A at sequential data position 243D being incorrectly interpreted as the LSDE 113, resulting in interpreting the data unit 212B as “0x0D0C0B0A” rather than “0x0A0B0C0D.”

In some embodiments, the adaptive parallel-serial converter 150 may be configured to selectively modify the data format 114 of data units 112 while performing parallel-to-serial conversion operations and/or serial-to-parallel conversion operations on such data units 112. The adaptive parallel-serial converter 150 may be configured to, inter alia, modify the data format 114 of a data unit 112 while generating a data sequence 242 comprising the data unit 112.

Referring to FIG. 2B, the computing device 103A may issue a read request 203A to read the data unit 212B from the memory 120 (e.g., read address 223B of the memory 120). As disclosed above, the data unit 212B may be stored in data format 114C, which is incompatible with the native data format 134 used by the computing device 103A (e.g., data format 114A). In response to the request 203A, the interface 110 may read the data unit 212B at address 223B (e.g., addresses 223B through 223B+3), which may comprise communicating parallel data 232 comprising the data unit 212B on the first data bus 107. The data unit 212B may be communicated in a parallel arrangement that corresponds to the data format 114C. The interface 110 may receive the parallel data 232 comprising the data unit 212B in the parallel arrangement of data format 114C.

The adaptive parallel-serial converter 150 may be configured to serialize the parallel data comprising the data unit 212B. The adaptive parallel-serial converter 150 may be further configured to selectively modify the format of data units 112 as such data units are serialized. The adaptive parallel-serial converter 150 may determine whether to modify the data format 114 of a data unit 112 by use of format conversion logic 152. The format conversion logic 152 may be configured to determine whether to reformat a data unit 112 by, inter alia, comparing an original or “input format” 414 of the data unit 112 to a requested format 514 for the data unit 112. The input format 414 may correspond to the data format 114 of the data unit 112 as stored in the memory 120 (e.g., the arrangement of the data unit 112 in the memory 120). The input format 414 of a data unit 112 read from the memory 120 may be referred to as the “storage format” or “stored format” of the data unit 112. The input format 414 may correspond to the native data format 134 of the computing device 103 that caused the data unit 112 to be written to the memory 120). The requested format 514 may specify a data format 114 in which the data unit 112 is to be communicated via the second data bus 109. The requested format 514 may correspond to the native data format 134 of the computing device 103 that issued the request to read the data unit 112. The format conversion logic 152 may determine whether to modify the data format 114 of a data unit 112 during serialization by comparing the input format 414 of the data unit 112 to the requested format 514 for the data unit 112. The format conversion logic 152 may be further configured to select a data format modification 155 for the conversion operation. The format modification scheme 155 configure the adaptive parallel-serial converter 150 to modify the data unit 112 from the input format 414 to the requested format 514 while the data unit 112 is serialized. The data format modification 155 may be configured to selectively reorder and/or rearrange data elements 113 of the data unit 112 while a data sequence 242 comprising the data elements 113 is generated by the adaptive parallel-serial converter 150. Implementing modifications to the data format 114 of a data unit 112 during serialization may obviate the need for separate data format modification circuitry, which may reduce the size, area, and/or power requirements of the interface 110.

In the FIG. 2B embodiment, in response to the request 203A, the format conversion logic 152 may determine that the input format 414 of the data unit 212B is data format 114C and that the requested format 514 for the request 203A is data format 114A. The format conversion logic 152 may determine to modify the format of the data unit 212B as the data unit 212B is serialized in response to comparing the input format 414 (data format 114C) to the requested format 514 (data format 114A). The format conversion logic 152 may be further configured to select a data format modification 155 to modify the data unit 212B from the input format 414 to the requested format 514 (e.g., modify the data unit 112 from data format 114C to data format 114A). Further embodiments of data format conversions 155 to convert a data unit 112 from a particular data format 114 to a different data format 114 are disclosed below.

As disclosed in further detail herein, based on the output(s) of the format conversion logic 152, the adaptive parallel-serial converter 150 may modify the data format 114 of the data unit 212B while the data unit 212B is being serialized for transmission to the computing device 103A via the second data bus 109. Modifying the data format 114 of the data unit 212B may comprise modifying the sequential arrangement of the data elements 113A-D comprising the data unit 212B in the data sequence 242, such that the data elements 113A-D are arranged in sequential data positions 243 that correspond to the requested format 514 (data format 114A) rather than the original input format 414 of the data unit 212B (data format 114C). As illustrated in FIG. 2B, the adaptive parallel-serial converter 150 may determine to convert the data unit 212B from data format 114C to data format 114A and, in response, may generate a data sequence 242A. The adaptive parallel-serial converter 150 may modify the sequential arrangement of the data unit 212B in the data sequence 242A in accordance with data format 114A. Rather than arranging the data elements 113A-D in sequence from least significant (113D) to most significant (113A), the adaptive parallel-serial converter 150 may output the data elements 113A-D in accordance with the data format 114A (from the MSDE 113A to the LSDE 113D, or {0A, 0B, 0C, 0D}). The computing device 103A may be capable of correctly interpreting the data sequence 242A comprising the data unit 212B in the modified data format 114A, as disclosed herein.

As also illustrated in FIG. 2B, the computing device 103B may issue a request 203B to read the data unit 212B at address 223B of the memory 120. In response to the request 203B, the interface 110 may read memory address 223B through 223B+3 (e.g., read 0D, 0C, 0B, 0A), and receive parallel data 232 comprising the data unit 212B in a parallel arrangement corresponding to data format 114C. The adaptive parallel-serial converter 150 may serialize the parallel data 232 comprising the data unit 212B for communication to the computing device 103B via the second data bus 109. The format conversion logic 152 may determine that no modifications to the data format of the data unit 212B are required. The format conversion logic 152 may determine that the input format 414 of the data unit 212B (data format 114C) is compatible with the requested format 514 for the request 203B (data format 114C). The format conversion logic 152 may, inter alia, select a data format modification 155 to preserve the original, input format 414 of the data unit 212B during serialization (e.g., a NOP data format modification 155), as disclosed herein. Accordingly, the data sequence 242B generated by the adaptive parallel-serial converter 150 in response to the request 203B may retain the original data format 114C of the data unit 212B, and the data elements 113A-D may have a sequential arrangement that corresponds to data format 114C (e.g., from LSDE 113D to the MSDE 113A, or “0D, 0C, 0B, 0A”).

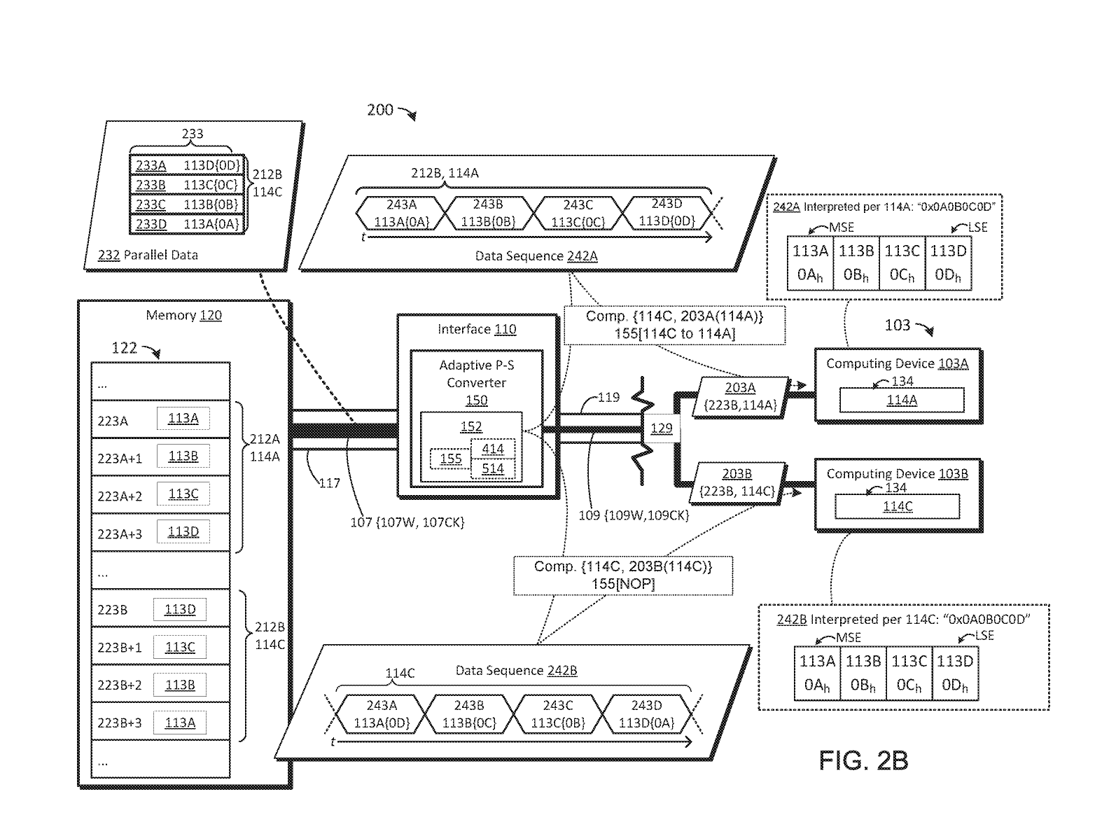

FIG. 3 is a schematic block diagram depicting operations of the adaptive parallel-serial converter 150. In the FIG. 3 embodiment, a data unit 312 comprises N data elements 113. The data unit 312 may be arranged for storage in the memory 120 in accordance with a particular data format 114 (e.g., the storage format of the data unit 112 in the memory 120). The storage format of the data unit 112 may determine the arrangement of the N data elements 113 in the memory 120 (e.g., the relative addresses and/or offsets of each of the N data elements 113). The storage format may correspond to any of the data formats disclosed herein (e.g., data formats 114A-E). The disclosure is not limited in this regard, however, and could be adapted to use any suitable data format 114 corresponding to any suitable arrangement of data elements 113 and/or data values in the memory 120, in parallel, and/or in sequence.

The data unit 312 may be stored within the memory 120 at address α. As disclosed above, the address α may correspond to any suitable addressing scheme and may include, but is not limited to: a physical address, a physical address offset, a page address, a block address, a logical address, a logical block address, a logical page address, a logical address offset, and/or the like. The N data elements 113 of the data unit 312 may be arranged for storage in accordance with the storage format of the data unit 312, which, inter alia, may determine an arrangement of the N data elements 113 at respective addresses and/or offsets relative to address α.

The adaptive parallel-serial converter 150 may be configured to selectively modify the data format 114 of the data unit 312 in response to a request to read the data unit 312 from the memory 120. The N data elements 113 of the data unit 312 may be read from the memory 120 in accordance with their arrangement therein (e.g., in accordance with the storage format of the data unit 312). The N data elements 113 of the data unit 312 may be read from the memory in address order: from the lowest or “base” address of the data unit 312 (address α) to the highest address of the data unit 312 (α+(N−1)). The N data elements 113 may be arranged for parallel communication on the first data bus 107 (as parallel data 232). As disclosed above, the parallel arrangement of the N data elements 113 may correspond to the arrangement of the N data elements 113 in the memory 120. As illustrated in FIG. 3, the N data elements 113 are arranged in parallel such that: the data element 113 read from address α is arranged at the first parallel data position 233A, the data element 113 read from the next address α+1 is arranged at the next parallel data position 233B, and so on, with the data element 113 read from the highest address α+(N−1) of the data unit 312 being arranged at parallel data position 233N. Since the parallel arrangement of the N data elements 113 corresponds to the arrangement of such data elements 113 within the memory 120, the parallel arrangement of the N data elements 113 may correspond to the storage format of the data unit 312.

By way of non-limiting example, FIG. 3 also depicts an exemplary timing diagram 302 for the first data bus 107 and the second data bus 109. As illustrated, the parallel data 232 comprising the N data elements 113 of the data unit 312 may be communicated in parallel via the first data bus 107 during a parallel communication period 235, with data elements 113[α]-113[α+(N−1)] being transmitted in parallel at respective parallel data locations 233A-N. The parallel communication period 235 may correspond to the clock signal 107CK of the first data bus 107.

The adaptive parallel-serial converter 150 may be configured to serialize the data unit 312 for communication via the second data bus 109. Serializing the data unit 312 may comprise producing a data sequence 242 comprising the data unit 312. The data sequence 242 may comprise a series or sequence of the data elements 113, each data element 113 being arranged at a respective sequential data position 243. The sequential data positions 243 may correspond to respective sequential communication periods 245 (e.g., cycles of the clock signal 109CK of the second data bus 109). The sequential data positions 243 of the N data elements 113 may determine the order in which the N data elements 113 are communicated on the second data bus 109 (e.g., determine which sequential communication period 245 each data element 113 is to be communicated via the second data bus 109). Accordingly, serializing the data unit 312 may comprise outputting each of the N data elements 113 of the data unit 312 in series, the N data elements 113 being output at one of N different sequential data positions 243A-N. The sequential arrangement of the N data elements 113 may determine, inter alia, the data format 114 for the data unit 312 communicated via the data sequence 242.

As illustrated in FIG. 3, outputting the N data elements 113 in accordance with the parallel arrangement of the N data elements 113 in the parallel data 232 (and/or in accordance with the arrangement of the N data elements 113 in the memory 120) may result a data sequence 342A in which the data unit 312 is arranged according to the original, storage format thereof (i.e., in which the data unit 312 retains its original storage format). In the FIG. 3 embodiment, the N data elements 113 of the data unit 312 are arranged in the data sequence 342A in accordance with the original, unmodified storage format of the data unit 312. The adaptive parallel-serial converter 150 may generate the data sequence 342A by, inter alia, arranging each of the N data elements 113 according to the parallel data positions 233 thereof within the parallel data 232 (and/or as communicated in parallel via the first data bus 107). In the data sequence 342A, the data element 113[α] at parallel data position 233A is arranged at the corresponding sequential data position 243A, data element 113[α+1] at parallel data position 233B is arranged at the corresponding sequential data position 243B, and so on, with data element 113[α+(N−1)] at parallel data position 233N being arranged at the corresponding sequential data position 243N.

The adaptive parallel-serial converter 150 may be configured to modify the data format 114 of the data unit 312 from the storage format to a requested format 514, concurrently while the data unit 312 is serialized (e.g., while producing a data sequence 242 comprising the data unit 312). The data format 114 of the data unit 312 may be modified by, inter alia, changing the sequential arrangement of the N data elements 113 in the data sequence 242 used to communicate the data element 312 via the second data bus 109. Modifying the data format 114 of the data unit 312 may, therefore, comprise outputting a sequence of data elements 113 of the data unit 312, such that the sequential arrangement of the data elements 113 in the sequence corresponds to a data format different from the original, storage format of the data unit 312. The data format 114 of the data unit 312 may be modified by arranging the N data elements 113 at sequential data positions 243 that differ from the sequential data positions 243 corresponding to the parallel arrangement of the N data elements 113 on the first data bus 107 (e.g., differ from the sequential arrangement corresponding to the arrangement of the N data elements 113 in the memory 120, and/or parallel data 232). Modifying the data format 114 of the data unit 312 may comprise arranging the N data elements 113 in a data sequence 242, such that the N data elements 113 have a sequential arrangement that corresponds to the requested data format 515 for the data unit 312, as disclosed above.

The format conversion logic 152 of the adaptive parallel-serial converter 150 may be configured to determine whether to reformat the data unit 312 by, inter alia, a) determining the input format 414 (e.g., the storage format of the data unit 312 in the memory 120), b) determining the requested format 514 (e.g., the data format 114 for the data unit 312 as communicated in a data sequence 242 via the second data bus 109), and c) comparing the input format 414 to the requested format 514. The conversion logic 152 may be further configured to select a data format modification 155. The data format modification 155 may be configured to convert parallel data 232 in which the data unit 312 is arranged in accordance with the determined input format 414 to a data sequence 242 in which the data unit 312 is arranged in accordance with the requested format 514. In the FIG. 3 embodiment, the adaptive parallel-serial converter 150 may be configured to generate a data sequence 342B in which the data unit 312 is converted from an input format 414 (data format 114C) to a requested format 514 (data format 114A). The input format 414 may comprise an input endianness of the data unit 312, and the requested format 514 may comprise a requested endianness for the data unit 312. Generating the data sequence 342B may comprise reversing the sequential data positions 243 of the N data elements 113, relative to the parallel data positions 233 of the N data elements 113 in the parallel data 232. The adaptive parallel-serial converter 150 may communicate the data element 113[α+(N−1)] at parallel data position 233N at the first sequential data position 243A in the data sequence 342B, and may communicate the data element 113[α] at parallel data position 233A at the last sequential data position 243N. Although a particular data format conversion is described herein, the disclosure is not limited in this regard, and could be configured to convert data units 112 stored in any data format 114 (any input format 414) to any other data format 114 (any requested format 514). Further embodiments of an adaptive parallel-serial converter 150 to implement such data format modifications 155 are disclosed in further detail herein.

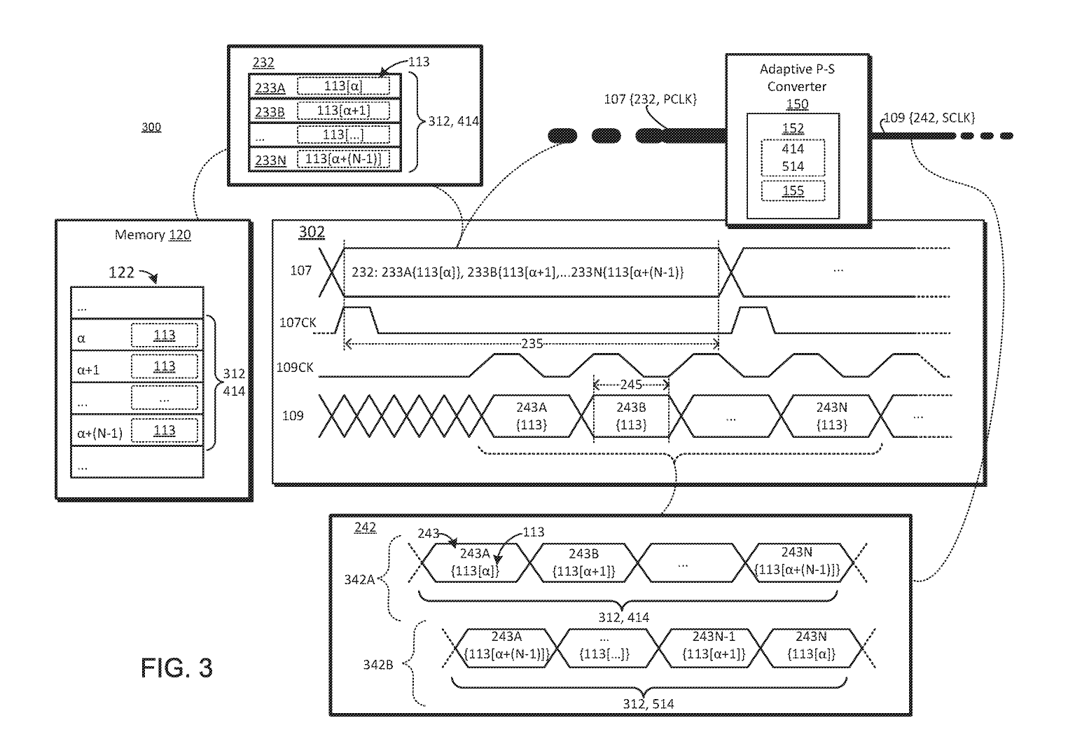

FIG. 4 is a block diagram of one embodiment of means for modifying the data format 114 of a data unit 112 while serializing parallel data 232 comprising the data unit 112 (e.g., generating a data sequence 242 comprising the data unit 112). The adaptive parallel-serial converter 150 may be configured to a) receive parallel data 232 comprising a data unit 412, and b) serialize the parallel data 232 by, inter alia, producing a corresponding data sequence 242 comprising the data unit 412. The data sequence 242 may be configured for serial communication (e.g., for communication via the second data bus 109 of the second interconnect 119). In the FIG. 4 embodiment, the adaptive parallel-serial converter 150 comprises format conversion logic 152 and serialization circuitry 450. The format conversion logic 152 may be configured to determine whether to change, modify, and/or reformat the data unit 412 while the data unit 412 is being serialized and/or select a data format modification 155 to implement while serializing the data unit 412, as disclosed herein (e.g., based on information pertaining to the input format 414 of the data unit 112 and/or a requested format 514 for the data unit 112).

The serialization circuitry 450 may be configured to latch the parallel data 232 comprising the data unit 412 and to produce a corresponding data sequence 242. The data sequence 242 may comprise a sequence of the data values and/or data elements 113 of the data unit 242, each data value and/or data element 113 being arranged at a respective sequential data position 243. As disclosed herein, the sequential arrangement of the data values and/or data elements 113 of the data unit 412 may determine, inter alia, a data format 114 for the data unit 412 in the data sequence 242. The serialization circuitry 450 may be configured to generate a data sequence 242 in accordance with the data format modification 155 selected by the format conversion logic 152.

In the FIG. 4 embodiment, the serialization circuitry 450 comprises a buffer 452. The buffer 452 may be configured to latch data values and/or data elements 113 of the data unit 412 in response to a control signal, such as the clock signal 107CK of the first data bus 107. The buffer 452 may comprise one or more storage modules, each storage modules configured to store a respective data value and/or data element 113 of the data unit 412. The configuration and/or arrangement of the storage modules may correspond to the size and/or configuration of the data unit 412 and/or characteristics for the data sequence 242. In the FIG. 4 embodiment, the data unit 412 comprises four data elements 113, each data element 113 comprising an eight-bit data value. The serialization circuitry 450 may be configured to produce a data sequence 242 that comprises a sequence of four data elements 113 (e.g., a sequence of four eight-bit data values in each of four sequential data positions 243). The disclosure is not limited in this regard, however, and could be adapted to receive data units 112 having any suitable size and/or configuration, and to produce corresponding data sequences 242 comprising any number of sequential data positions 243.

In the FIG. 4 embodiment, the buffer 452 comprises four storage modules (four shift buffers 462A-D). Each shift buffer 462A-D may be configured to hold a respective data element 113 (e.g., store a respective eight-bit data value). The shift buffers 462 may comprise any suitable structure for buffering, storing, latching, registering, and/or shifting data, which may include, but is not limited to: buffer circuitry, storage circuitry, register circuitry, shift circuitry, a buffer circuit, a storage circuit, a register circuit, a shift circuit, a data latch, a shift register, a flip flop, a set-reset (SR) flip flop, and/or the like. The shift buffers 462A-D may comprise a sequence of shift locations from a first shift location 462A to a last shift location 462D. As disclosed above, the buffer 452 and/or shift buffers 462A-D may be sized and/or configured in accordance with the size and/or configuration of the data unit 412 and/or the data sequence 242 to be produced by the serialization circuitry 450. In the FIG. 4 embodiment, the data unit 412 comprises four eight-bit data elements 113, and the serialization circuitry 450 is configured to generate a data sequence 242 comprising four eight-bit data elements 113. The buffer 452 may, therefore, comprise four shift buffers 462A-D, each shift buffer 462A-D configured to hold an eight-bit data value (e.g., a respective data element 113), and have a corresponding output (e.g., OUT-A through OUT-D). The outputs of the shift buffers 462A-D may be communicatively coupled to selection logic 454, which is discussed in further detail below.

The buffer 452 may further comprise shift logic 472, which may be configured to selectively shift data within the buffer 452 (e.g., shift data between storage modules, such as the shift buffers 462A-D). The shift logic 472 may be configured to shift data in a circular, reversible shift pattern in one of a plurality of shift directions (e.g., forward direction 473A and reverse direction 473B). As disclosed above, the buffer 452 may comprise a plurality of shift buffers 462. The shift buffers 462 may be coupled to one another in sequence. The shift buffers 462 may be coupled to enable the shift logic 472 to selectively shift data in one of a plurality of directions, including a “forward” direction 473A and “reverse” direction 473B. Each shift buffer 462A-D may have corresponding adjacent shift buffers 462 in each shift direction 473A and 473B, and may be configured to shift data to an adjacent shift buffer 462 in a selected shift direction 473A or 473B in response to a clock signal (e.g., 109CK, SCLK, or the like). The first shift buffer 462A in the series may be adjacent to shift buffer 462D in the forward direction 473A, and be adjacent to shift buffer 462B in the reverse direction 473B. The shift buffer 462B may be adjacent to shift buffer 462A in the forward direction 473A and be adjacent to shift buffer 462C in the reverse direction 473B), and so on, with the “last” shift buffer 462D in the series being adjacent to shift buffer 462C in the forward direction 473A and adjacent to shift buffer 462A in the reverse direction 473B. As illustrated in FIG. 4, the shift buffers 462A-D are coupled such that: to shift data in the forward direction 473A, an output of the last shift buffer 462D of the sequence is communicatively coupled to an input of shift buffer 462C, an output of shift buffer 462C is communicatively coupled to an input of shift buffer 462B, and so on, with the output of shift buffer 462B being communicatively coupled to an input of the first shift buffer 462A of the sequence; and, in to shift data in the reverse direction 473B, an output of the first shift buffer 462A is communicatively coupled to an input of shift buffer 462B, an output of shift buffer 462B is communicatively coupled to an input of shift buffer 462C, and so on, with an output of shift buffer 462C being communicatively coupled to an input of the last shift buffer 462D. As further illustrated in FIG. 4, the shift buffers 462 may be coupled in a circular configuration, such that: to shift data in the forward direction 473A, the output of the first shift buffer 462A is communicatively coupled to an input of the last shift buffer 462D; and, to shift data in the reverse direction 473B, the output of the last shift buffer 462D is communicatively coupled to an input of the first shift buffer 462A. Accordingly, the buffer 452 may be referred to as a “circular, reversible” buffer and/or may comprise “circular, reversible” shift buffers 462.

The shift buffers 462A-D may comprise a circular series of shift buffers 462A-D (and/or circular series of flip-flop circuits). The shift logic 472 may be configured to selectively shift data between the shift buffers 462 in a selected direction 473A or 473B in response to a control signal, such as the clock signal 109CK of the second data bus 109. The contents of the shift buffers 462A-D may be shifted in a sequential, circular configuration (e.g., data may be shifted circularly in either direction 473A or 473B, as disclosed above). Shifting data in direction 473A may comprise: transferring the contents of shift buffer 462D to shift buffer 462C, transferring the contents of shift buffer 462C to shift buffer 462B, transferring the contents of shift buffer 462B to shift buffer 462A, and transferring the contents of shift buffer 462A to shift buffer 462D. The shift logic 472 may be further configured to cause data to shift in direction 473B. Shifting the data registers 462A-D in direction 473B may comprise: transferring the contents of shift buffer 462A to shift buffer 462B, transferring the contents of shift buffer 462B to shift buffer 462C, transferring the contents of shift buffer 462C to shift buffer 462D, and transferring the contents of shift buffer 462D to shift buffer 462A.

Each shift buffer 462A-D may hold a respective data element 113 and produce a corresponding output. The selection logic 474 may be configured to select one of the shift buffers 462A-D to produce the data sequence 242. Outputs from each of the shift buffers 462A-D may be communicatively coupled to the selection logic 474. The selection logic 474 may receive OUT-A from shift buffer 462A, may receive OUT-B from shift buffer 462B, may receive OUT-C from shift buffer 462C, and so on (receive OUT-D from shift buffer 462D). The selection logic 474 may select one of the outputs OUT-A through OUT-D to produce the data sequence 242. Selecting OUT-A may comprise the selection logic 474 selecting the contents of shift buffer 462A (and output on OUT-A) to produce the data sequence 242, such that the data sequence 242 comprises the sequence of data elements 113 latched and/or shifted into shift buffer 462A. Selecting OUT-B may comprise the selection logic 474 selecting the contents of shift buffer 462B (and output on OUT-B) to produce the data sequence 242, such that the data sequence 242 comprises the sequence of data elements 113 latched and/or shifted into shift buffer 462B, and so on. The selection logic 474 may, therefore, be configured to select the buffer or shift location for the serialization operation. The selection logic 474 may provide for designating a shift location to produce the data sequence 242.

As disclosed above, the data sequence 242 may comprise a sequence of data elements 113, each data element 113 having a respective sequential data position 243. The data sequence 242 may be produced by shifting data elements 113 of the data unit 412 through the buffer 452 (through the shift buffers 462A-D in a selected shift direction). The format conversion logic 152 may be configured to select a data format modification 155 to implement while the data unit 412 is being converted into a data sequence 242. The format conversion logic 152 may select the data format modification 155 in response to comparing an input format 414 of the data unit 412 to a requested format 514. The data format modification 155 may comprise a NOP data format modification 155 in which the data format 114 is not changed during serialization. Serializing the data unit 412 with a NOP data format modification 155 may comprise: a) latching the data elements 113 of the parallel data 232 within corresponding shift buffers 462 (e.g., latching the “first” data element 113 at 233A into shift buffer 462A, latching the data element 113 at parallel data position 233B into shift buffer 462B, and so on, with the “last” data element 113 at parallel data position 233D being latched into shift buffer 462D); b) shifting data elements 113 between the shift buffers 462A-D in the forward direction 473A, and c) using the contents and/or output of shift buffer 462A (OUT-A) to generate the data sequence 242.

As disclosed above, the data elements 113 of the data unit 412 may have a parallel arrangement that corresponds to their arrangement in the memory 120, the data element at the “first” or “initial” memory address of the data unit 412 (address α) may be at parallel data position 233A, the data element 113 at a next address and/or offset of the data unit 412 (address α+1) may be at parallel data position 233B, and so on, with the last data element 113 at a last address and/or offset of the data unit 412 (address α+3) being at parallel data position 233D. Serializing the data unit 412 with a NOP data format modification 155 may, therefore, comprise generating a sequence of data elements 113 in the following order {113[α], 113[α+1], 113[α+2], 113[α+3]}, which may correspond to the arrangement of the data elements 113 within the parallel data 232, on the parallel data bus 107, and/or within the memory 120.

As disclosed above, the adaptive parallel-serial converter 150 may be configured to selectively modify the data format 114 of data units 212 while parallel data 232 comprising such data units 112 are serialized into respective data sequences 242. The adaptive parallel-serial converter 150 may comprise format conversion logic 152 configured to, inter alia: a) determine whether to modify the data format 114 of a particular data unit 112, and b) select a data format modification 155, and c) configure the serialization circuitry 450 to implement the selected data format modification 155 as the data unit 112 is being serialized (by use of format control signals 157, as disclosed in further detail herein).

The adaptive parallel-serial converter 150 may be configured to modify the sequential arrangement of data elements 113 of a data unit 112 by, inter alia, selectively shifting the data elements 113 within the shift buffers 462A-D and/or selecting one of shift buffers 462A-D to produce a data sequence 242 comprising the data unit 412 by use of the shift logic 472 and/or selection logic 474. The format conversion logic 152 may be configured to determine a data format modification 155 to modify the data format 114 of the data unit 412 from the input format 414 to a requested format 514. Implementing the selected data format modification 155 may comprise configuring the shift logic 472 and/or selection logic 474 to generate a particular sequence of data elements 113 for the data sequence 242.

As disclosed above, serializing the data unit 412 may comprise latching data elements 113 of the data unit 412 within the buffer 452 in response to a signal, such as the clock signal 107CK of the first data bus 107. As disclosed above, each shift buffer 462A-D may be configured to latch a data element 113 at a corresponding parallel data position 233A-D. The data register 462A may latch the data element 113 at parallel data position 233A (data element 113[α]), the data register 462B may latch the data element 113 at parallel data position 233B (data element 113[α+1]), data register 462C may latch the data element 113 at parallel data position 233C (data element 113 [α+2]), and data register 462D may latch the data element 113 at parallel data position 233D (data element 113[α+3]).

If the data unit 412 comprises the hexadecimal value “0x0A0B0C0D” in data format 114A (big-endian with eight-bit atomic elements) the shift buffers 462A-D may initially comprise the following sequence of data values:

TABLE 1

| OUT-D | OUT-C | OUT-B | OUT-A |
|---|---|---|---|
| 462D | 462C | 462B | 462A |
| 113 [α + 3] {0D} | 113 [α + 2] {0C} | 113 [α + 1] {0B} | 113 [α ] {0A} |

The adaptive parallel-serial converter 150 may be configured to generate a data sequence 242 having a serial arrangement corresponding to any of the data formats 114A-E by configuring the shift logic 472 and/or selection logic 474 accordingly. Sequential arrangements for each of the data formats 114A-E are listed below. By way of non-limiting example, the sequential arrangements below are illustrated in reference to the exemplary data unit with hexadecimal value “0x0A0B0C0D” comprising four eight-bit data elements 113:

TABLE 2

| | Sequential Arrangement | | | |
|---|---|---|---|---|
| | 243A | | | 243D |
| Data Format | (1^{st} in seq.) | 243B | 243C | (last in seq.) |
| 114A | 113 [α] {0A} | 113 [α + 1] {0B} | 113 [α + 2] {0C} | 113 [α + 3] {0D} |
| Big-endian (8) | | | | |
| 114B | 113 [α] {0A} | 113 [α + 1] {0B} | 113 [α + 2] {0C} | 113 [α + 3] {0D} |
| Big-endian (16) | | | | |
| 114C | 113 [α + 3] {0D} | 113 [α + 2] {0C} | 113 [α + 1] {0B} | 113 [α] {0A} |
| Little endian (8) | | | | |
| 114D | 113 [α + 2] {0C} | 113 [α + 3] {0D} | 113 [α] {0A} | 113 [α + 1] {0B} |
| Little endian (16) | | | | |
| 114E | 113 [α + 1] {0B} | 113 [α] {0A} | 113 [α + 3] {0D} | 113 [α + 2] {0C} |
| Middle endian (8) | | | | |

| | |
|---|---|
| 114 . . . | Any serial arrangement corresponding to any suitable data format (in |
| | addition to the data formats 114A-E explicitly described herein.) |

A serial arrangement corresponding to any of the data formats 114A-E may during serialization by a) determining a shift direction for the serialization operation and b) selecting an output location for the serialization operation. The serialization operation may be implemented by latching data into the buffer 452 (e.g., latching data elements 113 into respective shift buffers 462A-D), circularly shifting data elements in the determined shift direction (e.g., direction 473A or 473B), and using the data element latched and/or shifted into the selected output location to produce the data sequence 242. The data format modification 155 determined by the format conversion logic 152 may be configured to convert the data unit 412 from the input format 414 to the requested format 514. The conversion may comprise modifying the sequential position of one or more of the data elements 113. For example, a first data element 113 of the data unit 112 may be at parallel data position 233A. In a NOP data format modification 155, the sequential order of the first data element 113 may output at a first sequential data position (e.g., sequential positon 243A). Modifying the data unit 112 to the requested format 514 may comprise outputting the first data element 113 in a different sequential order (e.g., at a different sequential position 243B-D from sequential position 243A). Changing the data unit 112 to the requested format 514 may comprise changing the sequential order of the data elements 113 produced while serializing the parallel data 232 from a first sequential order (corresponding to the input format 414) to a second, different sequential order that corresponds to the requested format 514.

The data format modification(s) 155 may be defined as and/or comprise a set of format control signals 157, each set of format control signals 157 being configured to cause the shift logic 472 and selection logic 474 to generate a determined serial arrangement of the data unit 412 based on the original, input format 414 of the data unit 412 (e.g., based on the parallel arrangement of the data unit 412 as received at the adaptive parallel-serial converter 150). The format control signals 157 may include, but are not limited to: a shift control signal 457 (e.g., REV signal) to configure the shift logic 472 to shift the contents of the buffers 452 in one of the forward direction 473A and the reverse direction 473B (responsive to the clock signal 109CK), and an output select signal 459 (SEL) to configure the selection logic 474 to select one of the shift buffers 462A-D to produce the sequence of data elements 113 responsive to each clock signal 109CK (e.g., select the data elements 113 on OUT-A through OUT-D to produce the data sequence 242). The output select signal 459 may designate one of the shift buffers 462A-D as the output shift buffer 462A-D for the parallel-to-serial conversion operation. The contents of the shift buffer 462A-D selected by the output select signal 459 (SEL) may comprise a respective one of the data elements 113 during each period of the clock signal 109CK (e.g., as data elements 113 are shifted between the shift buffers 462A-D in accordance with the shift control signal 457 and SCLK). Although particular data formats 114A-E (and corresponding serial arrangements) are described herein, the disclosure is not limited in this regard and, as indicated above, the adaptive parallel-serial converter 150 could be adapted to convert a data unit 112 to/from any suitable data format 114 (e.g., generate any serial and/or sequential arrangement of data elements 113). The following table shows data elements 113 latched in each shift buffer 462A-D as data is circularly shifted in the forward direction 473A and the reverse direction 473B, respectively:

TABLE 3

| | OUT-D | OUT-C | OUT-B | OUT-A |
|---|---|---|---|---|
| | 462D | 462C | 462B | 462A |
| Shift FWD | 0D | 0C | 0B | 0A |
| 473A | 0A | 0D | 0C | 0B |
| | 0B | 0A | 0D | 0C |
| | 0C | 0B | 0A | 0D |
| Shift REV | 0D | 0C | 0B | 0A |
| 473B | 0C | 0B | 0A | 0D |
| | 0B | 0A | 0D | 0C |
| | 0A | 0D | 0C | 0B |

Data format modifications 155 (and corresponding configuration signals 157) may modify the data format 114A to any other data format 114 while the data unit 112 is being serialized. As illustrated in table 3, the data sequence 242 produced on shift register 462A as data is shifted in direction 473A corresponds to data format 114A or 114B (e.g., 0A, 0B, 0C, 0D). Accordingly, shifting data in direction 473A, and using shift buffer 462A to generate the sequence data 242 may preserve the data format 114 of the data unit 112 (e.g., may comprise a NOP data format modification 155). The sequence of data elements 113 produced on shift buffer 462D as the data elements 113 are shifted in direction 473B corresponds to data format 114C (little endian with eight-bit atomic elements, 0D, 0C, 0B, 0A). Accordingly, a data format modification 155 to convert a data unit 112 from data format 114A to data format 114C may comprise shifting data in direction 473B and using shift buffer 462D to produce the data sequence 242. The sequence of data elements 113 stored within shift buffer 462C as the data elements 113 are shifted in direction 473A corresponds to data format 114D (little endian with 16-bit atomic elements, 0C, 0D, 0A, 0B). Accordingly, a data format modification 155 to convert a data unit 112 from data format 114A to data format 114D may comprise circularly shifting data in direction 473A, and selecting shift buffer 462C to generate the data sequence 242. Finally, the sequence of data elements 113 shifted through shift buffer 462B in direction 473B corresponds to data format 114E (middle endian with eight-bit atomic elements, 0B, 0A, 0D, 0C). Therefore, a data format conversion to convert a data unit 112 from data format 114A to data format 114E may comprise format control signals 157 to shift data in direction 473B and to select shift buffer 462B to produce the data sequence 242. Data format conversions from any-to-any data format 114 may be implemented by a) determining a shift direction for the serialization operation, and b) selecting a buffer location (e.g., OUT-A through OUT-B) to produce the data sequence 242 for the serialization operation (e.g., to produce the sequence of data elements 113 as the data elements 113 are circularly shifted in the determined shift direction). By way of non-limiting example, data format conversions 155 and corresponding format control signals 157 to convert a data unit 112 in data format 114A to a data sequence 242 in which the data unit 112 is formatted according to each data format 114A-E are provided below (in reference to the exemplary data unit 112 comprising four eight-bit data elements 113 and having the hexadecimal value of “0x0A0B0C0D”:

TABLE 4

| | 157 | | |
|---|---|---|---|
| Data Format | Shift | Output | |
| Conversion | Ctl. | Select | |
| 155 | 457 | 459 | Data Sequence 242 |
| 114A to 114A [NOP] | FWD | OUT-A | 113 [α], 113 [α + 1], 113 [α + 2], 113 [α + 3] |
| | 473A | 462A | {0A, 0B, 0C, 0D} |
| 114A to 114A/B | FWD | OUT-A | 113 [α], 113 [α + 1], 113 [α + 2], 113 [α + 3] |
| [NOP] | 473A | 462A | {0A, 0B, 0C, 0D} |
| 114A to 114C | REV | OUT-D | 113 [α + 3], 113 [α + 2], 113 [α + 1], 113 [α] |
| | 473B | 462C | {0D, 0C, 0B, 0A} |
| 114A to 114D | FWD | OUT-C | 113 [α + 2], 113 [α + 3], 113 [α], 113 [α + 1] |
| | 473A | 462C | {0C, 0D, 0A, 0B} |
| 114A to 114E | REV | OUT-B | 113 [α + 1], 113 [α], 113 [α + 3], 113 [α + 2] |
| | 473B | 462D | {0B, 0A, 0D, 0C} |
| 114 . . . to 114 . . . | . . . | . . . | Any sequence corresponding to any |
| | | | suitable data format |

The data format conversions 155 (and the corresponding format control signals 157) listed above may be configured to produce a data sequence 242 comprising the data unit 412, such that the data elements 113 of the data unit 412 are sequentially arranged in accordance with any of the data formats 114A-E. The disclosure is not limited to the data formats 114A-E mentioned herein and could be adapted modify the data format 114 of a data unit 112 from any original or input format 414 to any requested format 514. As noted above, the format control signals 157, and corresponding sequential arrangement(s) of data elements 113, are relative to input data in data format 114A (big endian with eight-bit atomic elements). The disclosure is not limited in this regard, and similar sets of data format conversions 115 and corresponding format control signals 157 could be produced to convert data in from any other data format 114 (e.g., any of data formats 114B-E) to any other data format 114A-E. By way of further non-limiting example, a data unit 112 comprising the hexadecimal value “0x0A0B0C0D” may have a parallel arrangement that corresponds to data format 114E (middle endian with eight-bit atomic elements). The data elements 113 of the data unit 112 may be stored in the following arrangement in the memory 120: {0B, 0A, 0D, 0C} (at increasing memory addresses α through α+3) in accordance with data format 114E. The data unit 112 may be communicated in parallel at respective data positions 233A-D (e.g., 233A {0B}, 233B {0A}, 233C {0D}, 233D {C}). Table 5 illustrates the flow of data elements 113 in the forward direction 473A and the reverse direction 473B, respectively:

TABLE 5

| | OUT-D | OUT-C | OUT-B | OUT-A |
|---|---|---|---|---|
| | 462D | 462C | 462B | 462A |
| Shift FWD | 0C | 0D | 0A | 0B |
| 473A | 0B | 0C | 0D | 0A |
| | 0A | 0B | 0C | 0D |
| | 0D | 0A | 0B | 0C |
| Shift REV | 0C | 0D | 0A | 0B |
| 473B | 0D | 0A | 0B | 0C |
| | 0A | 0B | 0C | 0D |
| | 0B | 0C | 0D | 0A |

As illustrated above, the sequence of data elements 113 shifted through shift buffer 462B in direction 473B produces a data sequence 242 formatted according to data formats 114A and 114B (e.g., big endian with either eight or 16-bit atomic elements, 0A, 0B, 0C, 0D). Accordingly, a data format modification 155 to convert a data unit 112 in data format 114E to data format 114A or 114B may comprise format modification signals 157 to cause the serialization circuitry 450 to implement a circular shift pattern in direction 473B and to select the output of shift buffer 462B to produce the data sequence 242 (e.g., output a data sequence 242 comprising 0A, 0B, 0C, and 0D during respective sequential communication periods 245). As further illustrated in Table 5, the sequence of data elements 113 shifted through shift buffer 462C in direction 473A corresponds to data format 114C (e.g., little endian with eight-bit atomic elements, or 0D, 0C, 0B, 0A). Therefore, a data format modification 155 to convert a data unit 112 from data format 114E to data format 114C may comprise format modification signals 157 to cause the serialization circuitry 450 to implement a circular shift pattern in direction 473A and to select the output of shift buffer 462C to produce the data sequence 242. The sequence of data elements shifted through shift buffer 462D in direction 473B corresponds to data format 114D (little endian with 16-bit atomic elements, 0C, 0D, 0A, 0B). Therefore, a data format modification 155 to convert a data unit 112 from data format 114E to data format 114D may comprise format control signals 157 to cause the data elements 113 to be circularly shifted in direction 473B and to select shift buffer 462D to produce the data sequence 242. A NOP data format modification 155 may be unchanged from the examples above (e.g., may comprise shifting the data elements 113 in direction 473A and selecting shift buffer 462A to produce the data sequence 242). The data format conversions to convert a data unit 112 in data format 114E to any of data formats 114A-E are as follows:

TABLE 6

| | 157 | | |
|---|---|---|---|
| Data Format | | Output | |
| Conversion | Shift Dir. | Select | |
| 155 | 457 | 459 | Data Sequence 242 |
| 114E to 114A | REV | OUT-B | 113 [α + 1], 113 [α], 113 [α + 3], 113 [α + 2] |
| | 473B | 462B | {0A, 0B, 0C, 0D} |
| 114E to 114B | REV | OUT-B | 113 [α + 1], 113 [α], 113 [α + 3], 113 [α + 2] |
| | 473B | 462B | {0A, 0B, 0C, 0D} |
| 114E to 114C | FWD | OUT-C | 113 [α + 2], 113 [α + 3], 113 [α], 113 [α + 1] |
| | 473A | 462C | {0D, 0C, 0B, 0A} |
| 114E to 114D | REV | OUT-D | 113 [α + 3], 113 [α + 2], 113 [α + 1], 113 [α] |
| | 473B | 462D | {0C, 0D, 0A, 0B} |
| 114E to 114E [NOP] | FWD | OUT-A | 113 [α], 113 [α + 1], 113 [α + 2], 113 [α + 3] |
| | 473A | 462A | {0B, 0A, 0D, 0C} |
| 114 . . . to 114 . . . | . . . | . . . | Any sequence corresponding to any |
| | | | suitable data format |

The format conversion logic 152 may configure the serialization circuitry 450 to implement any one of a plurality of data format modifications 155, each of which may correspond to respective control signals 157. The format conversion logic 152 may, therefore, be configured to determine the format control signals 157 to change a data unit 112 having any input format 414 (114A-E) to any requested format 514 (114A-E). The format conversion logic 152 may, in some embodiments, comprise a look-up table, or the like, which may specify format control signals 157 to cause the configurable serialization circuitry 450 to shift the contents of the shift buffers 462A-D in one of the directions 473A and 473B, and to designate a shift location to produce the data sequence 242 in which data elements 113 of the data unit 112 have a sequential arrangement that corresponds to the requested format 514 (e.g., have one of the shift buffers 462A-D be designated to produce a data sequence 242). The format control signals 157 may, therefore, determine whether data is circularly shifted towards the designated shift location (e.g., the selected output location 462A-D) in either the forward direction 473A or the reverse direction 473B. The look-up table may be embodied in firmware, maintained in non-volatile memory, and/or the like. Alternatively, the format control signals 157 may be derived from the input format 414 and/or requested format 514 (e.g., by applying predetermined mappings and/or conversion operators thereto).

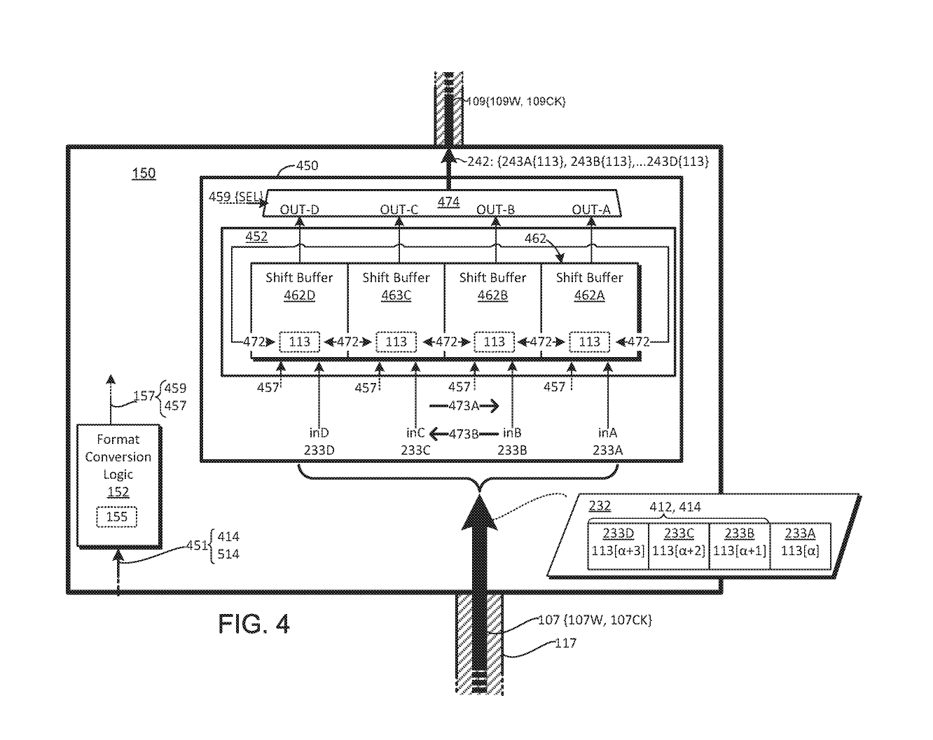

FIG. 5 is a schematic block diagram of another embodiment of an adaptive parallel-serial converter 150 configured to modify the data format 114 of a data unit 112 during serialization. The adaptive parallel-serial converter 150 may comprise format conversion logic 152 and serialization circuitry 450, as disclosed above. In the FIG. 5 embodiment, the serialization circuitry 450 may comprise a plurality of serialization circuits 550. Each serialization circuit 550 may be configured to serialize a respective data value (bit) of each of N data elements 113 of a data unit 112. The serialization circuits 550 may be further configured to modify the data format of the data unit 112 during serialization of the data unit 112, which may comprise each serialization circuit 550 modifying the sequential arrangement of data values in the data sequence 242 to change the data format 114 of a data unit 112 from a determined input format 414 to a requested format 514.

The serialization circuits 550 may be configured in accordance with the data units 112 being processed by the adaptive parallel-serial converter 150 and the data sequence 242 to be produced by the adaptive parallel-serial converter 150. In the FIG. 5 embodiment, the adaptive parallel-serial converter 150 is configured to receive parallel data 232 comprising a data unit 512 that includes four eight-bit data elements 113 and to generate a data sequence 242 comprising four sequential data positions 243, each sequential data position comprising a respective one of the eight-bit data elements 113. The serialization circuitry 450 may, therefore, comprise eight serialization circuits 550 (550[0] through 550[M], where M is 7). The serialization circuit 550[0] may be configured to generate a data sequence 242[0] comprising the data value (0) of each data element 113 of the data unit 512, the serialization circuit 550[1] may be configured to generate a data sequence 242[1] comprising the data value (1) of each data element 113 of the data unit 512, and so on, with serialization circuit 550[M] being configured to generate a data sequence 242[M] comprising data value (M) of each data element 113 of the data unit 512.

In the FIG. 5 embodiment, the adaptive parallel-serial converter 150 comprises a parallel data interface 507, which may be configured to communicatively and/or electrically couple to the first data bus 107 and/or first interconnect 117. The parallel data interface 507 may comprise one or more data pads, buffers, amplifiers, drivers, sense circuits, and/or the like. The parallel data interface 507 may be configured to operate according to particular communication protocol(s) used on the first interconnect 117 and/or first data bus 107. The parallel data interface 507 may be configured to receive parallel data 232 comprising the data unit 512 in response to a clock signal, such as the clock signal 107CK. As illustrated in FIG. 5, the parallel data interface 507 may be further configured to route data value(s) of the parallel data 232 to respective serialization circuits 550. As disclosed above, data units 112 communicated with the first data bus 107 may have a parallel data arrangement, in which each data element 113 of the data unit 112 is communicated at a respective parallel data position 233A-D. The parallel data positions 233A-D may correspond to respective data channels 533A-D of the first data bus 107. The data channels 533A-D may correspond to respective signal lines, communication lines, bus addresses, and/or the like. Each parallel data position 233A-D may be configured to communicate a respective data element 113 (e.g., communicate data values 0 through M, where M corresponds to the size of the data elements 113). In the FIG. 5 embodiment, the data unit 512 may comprise eight-bit data elements 113 and, as such, each parallel data position 233 may comprise eight data bits (e.g., data values 0 through M where M is 7). The parallel data interface 507 may be configured to route respective data values 0 through M (where M is 7) at each parallel data position 233A-D to respective serialization circuits 550[0] through 550[M]. The data value (0) at each parallel data position 233A, 233B, 233C, and 233D may be routed to serialization circuit 550[0] (as parallel data 232[0]), the data value (1) at each parallel data position 233A, 233B, 233C, and 233D may be routed to serialization circuit 550[1] (as parallel data 232[1]), and so on, with the data value (M) at each parallel data position 233 being routed to serialization circuit 550[M] (as parallel data 232[M]). Accordingly, the serialization circuit 550[0] may receive a set of four data values 233A[0] through 233D[0], which may comprise data value (0) of each data element 113 of the data unit 512. Although the serialization circuitry 450 of FIG. 5 is described in reference to data unit 512 having a particular size and/or configuration, the disclosure is not limited in this regard and could be adapted for use with data units 112 of any size and/or configuration. For example, the serialization circuitry 450 may be configured to process data units 512 comprising eight, 16-bit data elements 113. In such embodiments, the serialization circuitry 450 may comprise 16 serialization circuits 550, each serialization circuit 550 configured to generate a sequence of data values corresponding to each of the eight data elements 113 (e.g., receive eight data values as opposed to four data values as depicted in FIG. 5). Each serialization circuit 550 may comprise eight registers 562 (as opposed to four registers 562A-D as illustrated in FIG. 5).

Referring to FIG. 5, by way of non-limiting example, the first data bus 107 may be configured to communicate a data unit 512 read from address α of the memory 120. As disclosed above, the address α may comprise any suitable addressing information (e.g., a physical address, an address offset, a logical address, and/or the like). The data unit 512 may comprise four eight-bit data elements 113 stored at respective offsets (δ) from address α. The data unit 512 may comprise a data element 113 stored at address α (referred to as data element 113[α]), a data element 113 stored at α+δ (referred to as data element 113[α+δ]), a data element 113 stored at α+2δ (referred to as data element 113[α+2δ]), and a data element 113 stored at α+3δ (referred to as data element 113[α+3δ]). The data unit 512 may be communicated as parallel data 232 via the first data bus 107. A parallel arrangement of the data unit 512 may correspond to the input format 414 thereof (e.g., in accordance with the arrangement of the data elements 113 at respective address(es) and/or offsets, a through α+3δ in the memory 120). The data element 113[α] stored at address α may be communicated on data channel 533A (at parallel data position 233A), the data element 113[α+δ] may be communicated on data channel 533B (at parallel data position 233B), the data element 113[α+2δ] may be communicated on § data channel 533C (at parallel data position 233C), and the data element 113[α+3δ] may be communicated on data channel 533D (at parallel data position 233D). Since the data unit 512 is communicated via parallel data channel 533A-D (and at parallel data position 233A-D) that correspond to the arrangement of the data unit 512 in memory 120, the parallel arrangement of the data elements 113A-D (and associations between the data elements 113[α] through [α+3δ] and parallel data positions 233A-D) corresponds to the data format 114 of the data unit 512 within the memory 120. By way of non-limiting example, associations between the data unit 512 with the hexadecimal value “0x0A0B0C0D” arranged into four eight-bit data elements 113 (read from memory address α through α+3) in various storage 414 are as follows:

TABLE 7

| | Parallel Channel/Parallel Data Position | | | |
|---|---|---|---|---|
| | Data element 113 | | | |
| Storage format | 533A/233A | 533B/233B | 533C/233C | 533D/233D |
| 414 | Addr α | Addr (α + δ) | Addr (α + 2δ) | Addr (α + 3δ) |
| 114A | 113 [α] {0A} | 113 [α + 1] {0B} | 113 [α + 2] {0C} | 113 [α + 3] {0D} |
| Big-endian (8) | | | | |
| 114B | 113 [α] {0A} | 113 [α + 1] {0B} | 113 [α + 2] {0C} | 113 [α + 3] {0D} |
| Big-endian (16) | | | | |
| 114C | 113 [α + 3] {0D} | 113 [α + 2] {0C} | 113 [α + 1] {0B} | 113 [α] {0A} |
| Little endian (8) | | | | |
| 114D | 113 [α + 2] {0C} | 113 [α + 3] {0D} | 113 [α] {0A} | 113 [α + 1] {0B} |
| Little endian | | | | |
| (16) | | | | |
| 114E | 113 [α + 1] {0B} | 113 [α] {0A} | 113 [α + 3] {0D} | 113 [α + 2] {0C} |
| Middle endian | | | | |
| (8) | | | | |

| | |
|---|---|
| 114 . . . | Arrangement corresponding to any suitable data format |

As illustrated above, the input format 414 of the data unit 512 determines, inter alia, the parallel arrangement of the data unit 512 and, more specifically, the respective parallel data positions 233A-D of each data element 113A-D of the data unit 512 and/or the parallel data channel 533A-D on which the data elements 113A-D are communicated via the first data bus 107. Therefore, in response to determining the input format 414 of the data unit 512, the format conversion logic 152 may be configured to determine a corresponding data format modification 155 to modify the data format 514 from the input format 414 to a requested format 514 while the data unit 512 is serialized (e.g., using the data format conversions 155 and corresponding format control signals 157, as disclosed herein). In particular, the format conversion logic 152 may be configured to generate a data sequence 242 in which the data elements 113 as communicated during each of four sequential communication periods 245, and have a sequential arrangement that corresponds to a different data format 114, such as a requested format 514, for the data unit 512. The format conversion logic 152 may modify the data format 114 of the data unit by a) selecting a data format modification 155 and b) generating corresponding format control signals 157, as disclosed herein (e.g., as illustrated in tables 4 and 6).

The adaptive parallel-serial converter 150 may be configured to receive the data unit 512 based on signal(s) on the first data bus 107, such as a clock signal 107CK of the first data bus 107. Alternatively, or in addition, the first data bus 107 may comprise other format control signals to notify the adaptive parallel-serial converter 152 that the data unit 512 is being transmitted thereon, such as a communication control signal, an input signal, an interrupt signal, an arbitration signal, and/or the like. In response to receiving the data unit 512 (as parallel data 232 on the first data bus 107), the adaptive parallel-serial converter 150 may be configured to a) latch data values communicated at each of the parallel data positions 233A-D of the first data bus 107 into a respective serialization circuit 550[0]-550[M], b) determine a data format modification 155 to implement during serialization of the data unit 512, and c) serialize the data unit 512 by producing a data sequence 242 comprising the data unit 512, in which data elements 113 of the data units 512 are in a sequential arrangement that corresponds to the requested format 514.

The format conversion logic 152 may be configured to determine the data format modification 155 to implement while serializing the data unit 512 based on information pertaining to the data unit 512, such as information pertaining to the input format 414 of the data unit 512 and the requested format 514. In some embodiments, the adaptive parallel-serial converter 150 receives information pertaining to the input format 414 and/or requested format 514 as via an input 451. Alternatively, or in addition, the adaptive parallel-serial converter 150 may be configured to determine the input format 414 of the data unit 512 from one or more of: information transmitted via the first data bus 107 (and/or the first interconnect 117), a header of the data unit 112, metadata associated with the data unit 112, metadata pertaining to the data unit 512, and/or the like. In some embodiments, the adaptive parallel-serial converter 150 (or memory 120) maintains data format metadata 522, which may indicate the data format 114 of data units 112 stored within the memory 120. The data format metadata 522 may be maintained in a table, index, registers, configuration data, firmware, and/or other suitable data structure (e.g., a data format table, data format index, data format register value, and/or the like). The data format metadata 522 may, in some embodiments, be stored within the memory 120, in firmware of the memory 120 and/or interface 110, in configuration data of the adaptive parallel-serial converter 150, in a storage register, and/or the like. The data format metadata 522 may indicate the data format 114 of particular data units 112. In some embodiments, the data format metadata 522 may identify the data format 114 of data units 112 stored within various regions of the memory 120 (e.g., indicate that data units 112 stored within address range 0-1023 are stored in data format 114A, and that data units 112 stored within address range 1024-4095 are stored in data format 114D). The data format metadata 522 may identify the data format 114 of data units 112 based on physical addresses of the data units 112 in the memory, logical or virtual identifiers associated with the data units 112, and/or the like. The format conversion logic 152 may, therefore, be configured to determine the input format 414 of a data unit 112 based on addressing information pertaining to the data unit 112. In some embodiments, the data format metadata 522 is maintained by a particular component of the memory 120 and/or interface 110, such as a memory controller, memory logic, or the like. The format conversion logic 152 may determine the input format 414 of a data unit 112 by, inter alia, issuing a query to the particular component (via an internal communication interconnect, such as the first interconnect 117).

In some embodiments, the adaptive parallel-serial converter 150 (or other component) is configured to update the data format metadata 522 as data units 112 are written to the memory 120. Commands to write data units 112 to the memory may indicate and/or be associated with an indication of the data format of the data units 112. For example, a write command may comprise a parameter, flag, or other information indicating the data format 114 of the data units 112 being written to the memory 120. Alternatively, or in addition, the data format 114 of data units 112 being written to the memory 120 may be provided in a setting, flag, configuration data, I/O arbitration information, and/or the like. In one non-limiting example, the interface 110 may determine the native data format 134 used by a computing device 103 when being coupled to the computing device 103. The interface 110 may determine the native data format 134 used by the computing device 103A when the computing device 103A is coupled to the memory 120. The interface 110 may then record that data written to the memory 120 by the computing device 103A is formatted in the native data format 134 thereof (e.g., data format 114A). In other embodiments, the computing device 103A may specify the native data format 134 used thereby by issuing one or more message(s) to the interface 110 (via the second interconnect 119), which may indicate the native data format 134 used by the computing device 103A. Although particular examples of techniques for determining and/or maintaining data format metadata 522 are described herein, the disclosure is not limited in this regard and could be configured to determine the input format 414 of a data unit 112 and/or maintain data format metadata 522 pertaining to data units 112 stored within the memory 120 using any suitable technique.

The format conversion logic 152 may be further configured to determine the requested format 514. In some embodiments, the requested format 514 may be provided to the adaptive parallel-serial converter 150 as an input 451. Alternatively, or in addition, the adaptive parallel-serial converter 150 (and/or interface 110) may determine the requested format 514 from a read request. The requested format 514 may, for example, by indicated in a parameter, flag, and/or setting associated with the read request. Alternatively, or in addition, the requested format 514 may be specified at the time the computing device 103 is coupled to the memory 120 (and/or the interface 110). The computing device 103A may, for example, provide configuration data to the memory 120 and/or the interface 110, which may indicate that the computing device 103A is configured to use a particular native data format 134 (e.g., data format 114A). The format conversion logic 152 may, therefore, determine that data units 112 communicated to the computing device 103A should be in data format 114A (e.g., the requested format 514 for such data units 112 is 114A). In some embodiments, the adaptive parallel-serial converter 150 may be configured to maintain client data format metadata 532, which may indicate data formatting preferences and/or requirements of computing devices 103 to which the memory 120 may be coupled. The client data format metadata 532 may be stored in non-volatile storage, such as the memory 120, firmware, configuration data, and/or the like. The client data format metadata 532 may indicate that the computing device 103A is configured to use data format 114A. The computing device 103A may be disconnected from the memory 120. When the computing device 103A is reconnected, the adaptive parallel-serial converter 150 may determine the requested format 514 for read requests associated with the computing device 103A based on client format metadata 532 associated with the computing device 103A. In addition, the adaptive parallel-serial converter 150 may determine the input format 414 for data units 112 written to the memory 120 by the computing device 103A (e.g., data format 114A).

The format conversion logic 152 may be configured to select a data format modification 155 to implement while serializing the data unit 512 by, inter alia, comparing the determined input format 414 of the data unit 112 to the requested format 514 for the data unit 112. As disclosed above, the data format modification 155 may be configured to adapt the sequential arrangement of data elements 113, such that the serialized data unit 112 conforms to the requested format 514. In some embodiments, the format conversion logic 152 selects a data format modification 155 from a library 555 comprising a plurality of data format conversions 155. Each data format conversion 115 in the library 555 may be configured to convert data arranged according to a particular data format 114 (e.g., input format 414) into a data sequence 242 in a different data format (e.g., requested format 514). Each data format modification 155 in the library 555 may further comprise a corresponding set of format control signals 157 to cause the respective serialization circuits 550[0] through 550[M] to perform the specified data modifications while the data unit 112 is serialized (as a data sequence 242). The library 555 may comprise one or more look-up table(s), such as the tables 4 and 6, disclosed above. Each look-up table may comprise a set of format control signals 157 configured to change the data format 114 of a data unit 112 from a first data format 114 to a second data format 114 while the data unit 112 is being serialized. Alternatively, or in addition, the library 555 may be embodied as a state machine and/or other logic circuitry, which may embody rules configured to generate format control signals 157 corresponding to each of a plurality of data format conversions 155 (e.g., produce respective set of format control signals 157 responsive to different combinations of input formats 414 and/or requested data formats 514). The library 555 may be embodied as one or more logic elements, circuits, configuration data, firmware, and/or the like. Portions of the library 555 may be embodied as computer readable instructions stored on a non-transitory storage medium, such as the memory 120, internal storage of the interface 110 and/or memory 120, and/or the like.

In some embodiments, the format conversion logic 152 may be configured to select a data format modification 155 based on the determined input format 414 of the data unit 112 and/or the requested format 514 for the data unit, which may be provided by inputs 451 to the format conversion logic 152 and/or determined thereby. Alternatively, in some embodiments, the format conversion logic 152 may be configured to implement specified data format conversion operation(s), independent of information pertaining to the input format 414 of the data unit 112 and/or requested format 514. Referring to FIGS. 2A and 2B, the computing device 103A may be coupled to the memory 120 after the memory 120 was coupled to a different computing device 103 (e.g., computing device 103B). The computing device 103A may have information pertaining to the data format 114 used by the computing device 103B (e.g., native data format 134, which is data format 114C). The computing device 103A may determine that the native data format 134 used by the computing device 103B is incompatible with the data format 114 used thereby and, as such, may configure the interface 110 to reformat the data unit 112 as such data units 112 are read from the memory 120. The computing device 103A may instruct the interface 110 to convert the data format 114 of data units 112 from a specified input format 414 (e.g., data format 114C) to a specified requested format 514 (e.g., data format 114A). In such embodiments, the format conversion logic 152 may be configured to select a corresponding data format modification 155 without determining input format 414 of each data unit 112 and/or the requested format 514 for each request (until instructed otherwise).

Referring back to FIG. 5, the adaptive parallel-serial converter 150 of the FIG. 5 embodiment comprises a plurality of serialization circuits 550[0] through 550[M], each of which may be configured to generate a respective bit of the data sequence 242 (e.g., produce 242[0] through 242[M], respectively). Each of the serialization circuits 550[0] through 550[M] may comprise configurable shift register circuitry 552. FIG. 5 depicts the configurable shift register circuitry 552 of the serialization circuit 550[0] (the details of the other serialization circuits 55[1] through 550[M] are not shown to avoid obscuring the details of the illustrated embodiments). The shift register circuitry 552 comprises a plurality of registers 562 (registers 562A-D), shift circuitry 572, and selection circuitry 574. The registers 562 may be configured to hold (and/or selectively shift) data values of the data unit 512. The registers 562 may comprise flip flop circuits. The number of registers 562 included in the serialization circuit 550[0] may correspond to the size and/or configuration of the data unit 512 and/or the configuration of the data sequence 242 (e.g., the number of sequential positions 243 in the data sequence 242). In the FIG. 5 embodiment, the serialization circuit 550[0] comprises four registers 562A-D, wherein each register 562A-D is configured to hold the data value (0) of a respective one of four data elements 113 of the data unit 512. The shift circuitry 572 may be configured to selectively shift data between the registers 562A-D in a selected direction 473A or 473B, as disclosed herein. The selection circuitry 574 may be configured to select the contents of one of the registers 562A-D to produce a data sequence 242[0] that comprises data value (0) of each data element 113 of the data unit 512 at respective sequential data positions 243A-D.

After selection of a data format modification 155 (and producing corresponding format control signals 157), the adaptive parallel-serial converter 150 may serialize the data unit 512, which may comprise generating a data sequence 242 in which the data elements 113 of the data unit 112 are arranged in accordance with the requested format 514 rather than the original, input format 414 of the data unit 112. Serializing the data unit 512 may comprise latching parallel data 232 comprising the data unit 512 into the respective serialization circuits 550[0] through 550[M] in response to a control signal (e.g., the clock signal 107CK), as disclosed herein. The serialization circuit 550[0] may be configured to latch data value (0) at each parallel data positions 233A-D (and/or parallel data channel 533A-D), as follows: the data value (0) at parallel data position 233A may be stored in register 562A, the data value (0) at parallel data position 233B may be stored in register 562B, and so on, with the data value (0) at parallel data position 233D being stored in register 562D. The serialization circuits 550[1] through 550[M] may latch data values (0) through (M) in a substantially similar manner.

The shift register circuitry 552 may further comprise shift circuitry 572, which may be configured to selectively shift the data values stored in the registers 562A-D in one of directions 473A and 473B. The registers 562A-D may comprise a circular series of flip flop circuits configured to shift data values in either the forward direction 473A or the reverse direction 473B. The data values may be shifted responsive to a signal, such as the clock signal 109CK of the second data bus 109 (and/or format control signal(s) 157, as disclosed herein). The data values may be shifted in a circular configuration in which data values are shifted between the first register 562A and the last register 562D in either direction 473A or 473B. The serialization circuit 550[0] may further comprise selection circuitry 574, which may be configured to select an output of one of the registers 562A-D to produce data value (0) of the data sequence 242 (e.g., data sequence 242[0]). The selection circuitry 574 may comprise a multiplexer, having inputs coupled to each of the registers 562A-D. The selection circuitry 574 may select one of the registers 562A-D to produce data value (0) of the data sequence 242 (e.g., data sequence 242[0]) based on format control signals generated by the format conversion logic 157). The serialization circuit 550[0] may, therefore, be configured to generate data value (0) of the data sequence 242 (e.g., data sequence 242[0]), which may comprise a sequence of data value (0) of each data element 113 of the data unit 512 being serialized, the data value (0) of the data elements 113 having a serial arrangement that corresponds to the requested format 514 (e.g., modifies the data format 114 of the data unit 112 from the input format 414 to the requested data forma 514).

Each of the other serialization circuits 550[1] through 550[M] may perform corresponding serialization operations (and data format modifications) on data values (1) through (M), respectively. Each serialization circuit 550[0] through 550[M] may receive the same set of format control signals 157 from the format conversion logic 152 and, as such, each serialization circuit 550[0] through 550[M] may output a respective data sequence 242[0] through 242[M], such that the data values of each data element 113 are arranged in sequence in accordance with the requested format 514. As illustrated in FIG. 5, the adaptive parallel-serial converter 150 may be configured to combine data sequence 242[0] through 242[M] of the serialization circuits 550[0] through 550[M] to output the data sequence 242.

The data sequence 242 may comprise a serial arrangement of the data unit 112 corresponding to the requested format 514, which may comprise modifying the sequential arrangement of such data elements 113 relative to the sequential arrangement corresponding to the original, input format 414 of the data unit 112. The serialization circuits 550[0] through 550[M] may be configured to implement data format modification 155 selected by the format conversion logic 157 (in accordance with the format control signals 157). As disclosed above, the format control signals 157 may be configured to cause the serialization circuits 550[0] through 550[M] to a) shift data values in one of directions 473A and 473B by use of shift circuitry 572, and/or b) select one of the registers 562A-D to produce the data sequence 242[0] through 242[M] by use of respective selection circuitry 574. The data sequence 242 may comprise a serial arrangement of data elements 113, each data element 113 having a respective sequential data position 243A-D. Each data element 113 may be output on the second data bus 109 during one of four sequential communication periods 245 (e.g., during four cycles of the clock signal 109CK of the second data bus 109). As disclosed above, the reversible, circular shift operation(s) implemented by the shift circuitry 572 and selection operation(s) implemented by the selection circuitry 574 (responsive to the format control signals 157) may cause the data elements 113A-D to be arranged in the data sequence 242 in accordance with the requested format 514.

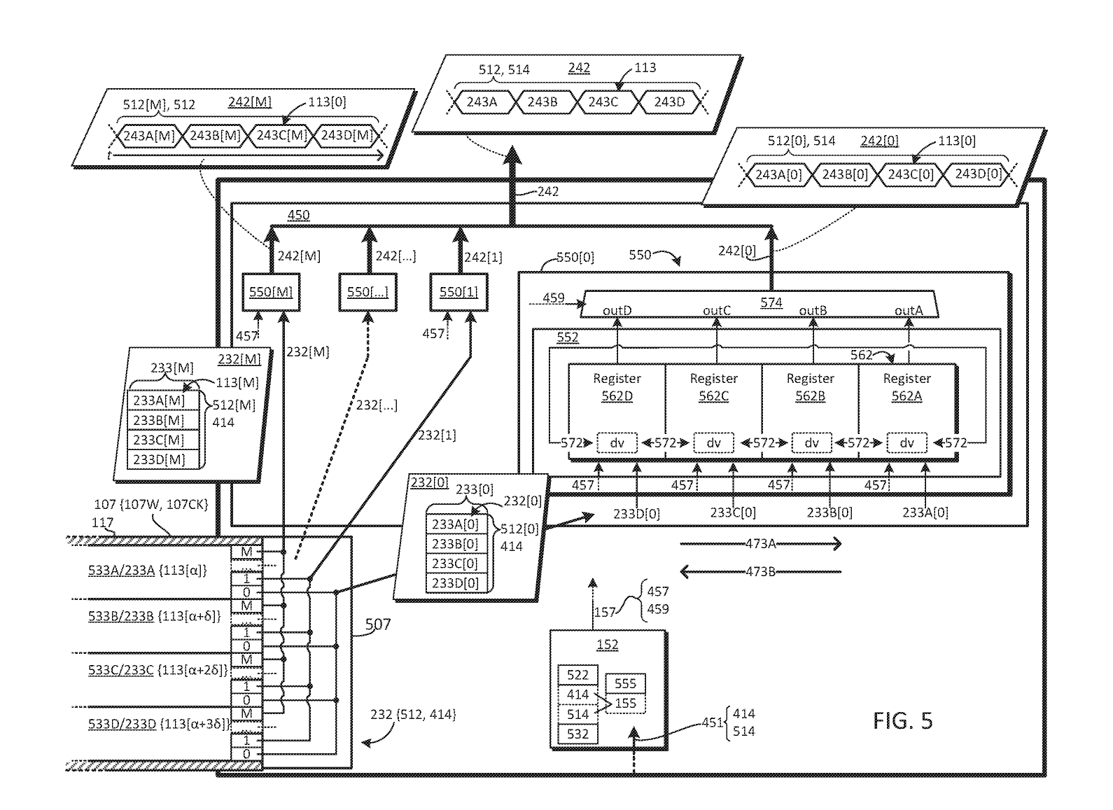

FIG. 6 is a schematic block diagram of another embodiment of an adaptive parallel-serial converter 150. The adaptive parallel-serial converter 150 of the FIG. 6 embodiment may comprise format conversion logic 152 and serialization circuitry 450, as disclosed herein. The serialization circuitry 450 may comprise a plurality of serialization circuits 550, including serialization circuits 550[0] through 550[M], where M corresponds to the size of the data elements 113 of the data unit 612 to be processed by the adaptive-parallel serial converter 150. Each serialization circuit 550 may be configured to produce a respective bit value of a data sequence 242 comprising the data unit 612, as disclosed herein. The serialization circuits 550 may be sized according to the size and/or configuration of the data unit 612 and/or the data sequence 242 to be produced thereby. In the FIG. 6 embodiment, the serialization circuits 550 may be configured to process a data unit 612 comprising four eight-bit data elements 113. As such, the serialization circuitry 450 may comprise eight serialization circuits 550, including serialization circuit 550[0] configured to generate data value (0) of the data sequence 242 through serialization circuit 550[M] configured to generate data value (M) of the data sequence 242 (where M is 7).

The adaptive parallel-serial converter 150 may be configured to receive parallel data 232 comprising the data unit 612 at a parallel data interface 507. The parallel data interface 507 may be configured to route portions of the parallel data 232 to each of the serialization circuits 550[0] through 550[M], as disclosed herein. As illustrated in the FIG. 6 embodiment, the parallel data interface 507 may be configured to route data value (0) at each parallel data position 233A-D to serialization circuit 550[0], to route data value (1) at each parallel data position 233A-D to serialization circuit 550[1], and so on, with the data value (M) at each parallel data position 233A-D being routed to serialization circuit 550[M].

The adaptive parallel-serial converter 150 may be further configured to generate a data sequence 242 comprising the data unit 612 and to output the data sequence 242 on the second data bus 109 (via a serial data interface 609). The serial data interface 609 may be configured to communicatively couple the adaptive parallel-serial converter 150 to the second data interconnect 119 and/or second data bus 109. The serial data interface 609 may be configured to operate according to particular communication protocol(s) used on the second interconnect 119. The serial data interface 609 may be configured to communicate the data units 612 as data sequence(s) 242 on the second data bus 109. The serial data interface 609 may comprise one or more pads, buffers, amplifiers, drivers, sense circuits, and/or the like.

In the FIG. 6 embodiment, each serialization circuit 550[0] through 550[M] may comprise reversible, circular register circuitry 652. The serialization circuit 550[0] comprises four shift registers 662A-D, each shift register 662A-D being configured to receive data value (0) of one of the four data elements 113 of the data unit 612 (e.g., data value (0) at each parallel data position 233A-D). The reversible, circular register circuitry 652 further comprises configurable shift circuitry 672 and selection circuitry 574. The configurable shift circuitry 672 may be configured to shift data values between the shift registers 662A-D in circularly in either direction 473A or 473B. The shift circuitry 672 may comprise selection circuitry, such as routing logic, a multiplexer, and/or the like. The shift circuitry 672 may be configured to selectively couple the shift registers 662A-D in a series and/or sequence (from a first shift register 662A to a last shift register 662D). The shift circuitry 672 may be configured to selectively couple inputs of the shift registers 662A-D to outputs adjoining shift registers 662A-D in the sequence and/or data values of the parallel data 232. As illustrated in FIG. 6, the shift circuitry 672 is configured to selectively couple the input of shift register 662A to either a) the output of proximate shift register 662B with respect to direction 473A, b) the output of proximate shift register 662D with respect to direction 473B, and c) data value at parallel data position 233A[0]. The shift logic 672 may select the input for the shift register 662A in accordance with the control signals 157 generated by the format conversion logic 152 (e.g., the shift control signal 457). The data value selected by the shift logic 672 may be shifted into the shift register 662A responsive to a clock signal, such as 109CK. Inputs of the other shift registers 662B-D may selected in a similar manner. For example, the shift circuitry 672 may be configured to select the input for the last shift register 662D from a) the output of proximate shift register 662A with respect to direction 473A, b) the output of proximate shift register 662C with respect to direction 473B, and c) the data value at parallel data position 233D[0].

The selection circuitry 574 may be configured to select an output of one of the shift registers 662A-D to produce the data value (0) for the data sequence 242[0], as disclosed above. The serial data interface 609 may be configured to output data values (0) through (M) produced by the serialization circuits 550[0] through 550[M] to form the data sequence 242, as disclosed above. The serial data interface 609 may be further configured to communicate the data sequence 242 on the second data bus 109, which may comprise driving data lines of the second data bus 109 during four periods of the clock signal 109CK, such that a different one of the data elements 113 of the data unit 612 is driven on the second data bus 109 during each of the four periods.

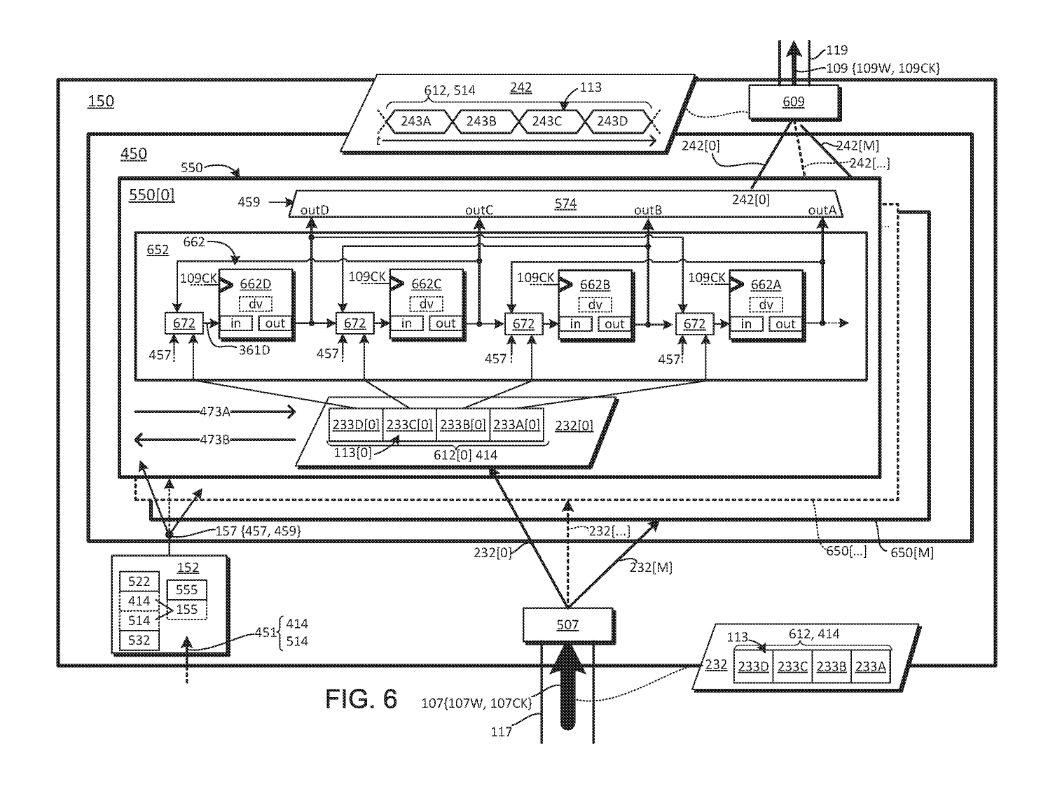

FIG. 7 is a schematic block diagram of another embodiment of an adaptive parallel-serial converter 150. The adaptive parallel-serial converter 150 may comprise format conversion logic 152 and serialization circuitry 450, as disclosed herein. The serialization circuitry 450 may be configured to generate a data sequence 242 comprising a data unit 712 responsive to receiving parallel data 232 comprising the data unit 712. The parallel data 232 may be received via the first data bus 107, as disclosed herein. The data unit 712 may have a parallel data arrangement that corresponds to particular data format 114 (e.g., the input format 414 of the data unit 712). The serialization circuitry 450 may comprise serialization circuits 550, each serialization circuit 550 being configured to generate a sequence of data values (e.g., a data value for each data bit of a data element 113 of the data unit 712), as disclosed herein. The serialization circuit 550 is configured to latch and/or shift a particular number of data bits of the parallel data 232. In the FIG. 7 embodiment, the data unit 712 being serialized may comprise four eight-bit data elements 113. The adaptive parallel-serial converter 150 may be configured to serialize the data unit 712 into a sequence of four data elements 113. The serialization circuitry 450 may, therefore, comprise eight serialization circuits 550, each serialization circuit 550 being configured to latch and/or shift four data values (a data value of each data element 113). Although FIG. 7 is adapted to generate a data sequence 242 having a particular size and/or configuration, the disclosure is not limited in this regard and could be adapted to serialize data unit 712 of any suitable size and/or configuration into a data sequence 242 comprising any number of sequential data positions 243.

The serialization circuit 550[0] comprises shift circuitry 772 and selection circuitry 574 (other serialization circuits 550[1] through 550[7] are omitted to avoid obscuring the details of the illustrated embodiments). The shift circuitry 772 may comprise a plurality of SR flip flops 762, each SR flip flop 762 being configured to hold a respective data value (e.g., a bit). The SR flip flops 762 may be connected in a circular, reversible sequence 763, as disclosed herein. The input of each SR flip flop 762 may be selectively coupled to outputs of proximate SR flip flops 762 in the sequence 763. The SR flip flops 762 may be coupled to one another such that data can be selectively shifted in either a forward direction 473A or a reverse direction 473B. The shift direction may be controlled by a format control signal 157 generated by the format conversion logic 152 (shift control signal 457). In the FIG. 7 embodiment, the format conversion logic 152 is configured to generate a shift control signal 457 signal (REV signal), wherein, when the shift control signal 457 is “0,” the shift circuitry 772 is configured to shift data values in the forward direction 473A, and when the shift control signal 457 is “1”, the shift circuitry 772 is configured to shift data values in the reverse direction 473B. As illustrated in FIG. 7, when the shift control signal 457 is “0” (to shift data in the forward direction 473A): the input of SR flip flop 762A is coupled to the output of SR flip flop 762B, the input of SR flip flop 762B is coupled to the output of SR flip flop 762C, the input of SR flip flop 762C is coupled to the output of SR flip flop 762D, and the input of SR flip flop 762D is coupled to the output of SR flip flop 762A; when the shift control signal 457 is “1” (to shift data in the reverse direction 473B), the input of SR flip flop 762A is coupled to the output of SR flip flop 762D, the input of SR flip flop 762B is coupled to the output of SR flip flop 762A, the input of SR flip flop 762C is coupled to the output of SR flip flop 762B, and the input of SR flip flop 762D is coupled to the output of SR flip flop 762C. The selection circuitry 774 may be configured to select one of the outputs of the SR flip flops 762A-D to produce data value (0) of the data sequence 242 (produce 242[0]), as disclosed herein. As illustrated above, circularly shifting data in the forward direction 473A may comprise shifting data from a first SR flip flop 762A of the sequence 763 to a last SR flip flop 462D of the sequence 763, and circularly shifting data in the reverse direction 473B may comprise shifting data from the last SR flip flop 462D to the first SR flip flop 462A.

The adaptive parallel-serial converter 150 may be configured to receive parallel data 232 comprising the data unit 712 via the first data bus 107. Receiving the parallel data 232 may comprise latching data values of the parallel data 232 into each serialization circuit 550. The serialization circuits 550[0] may be configured to latch data value (0) of each data element 113 of the data unit 712 (e.g., data value (0) at each parallel data position 233A-233D). Data values may be latched into the SR flip flops 762A-D by, inter alia, selectively coupling set/reset inputs of the SR flip flops to data values of the parallel data 232 responsive to a clock signal (PCLK). The PCLK signal may comprise a clock signal and/or other control signal configured to manage communication of parallel data 232 on the first data bus 107. The PCLK signal may correspond to the clock signal 107CK of the first data bus 107. Other serialization circuits 550[1] through 550[7] may be configured to latch other data values (1) through (7), as disclosed herein.

Latching the parallel data 232 may further comprise selecting a data format modification 155 to implement during serialization of the parallel data 232. The format conversion logic 152 may be configured to select a data format modification 155 (and produce corresponding format control signals 157) in response to comparing the input format 414 of the data unit 712 to a requested format 514, as disclosed herein. The input format 414 and/or requested format 514 may be provided as an input 451. Alternatively, the format conversion logic 152 may be configured to determine the input format 414 of the data unit 712 and/or the requested data format 712, as disclosed herein.

The data format modification 155 may be configured to reformat the data unit 712 while the parallel data 232 comprising the data unit 712 is serialized (as a data sequence 242). As disclosed above, the data formation modification 155 may correspond to format control signals 157. In the FIG. 7 embodiment, the format control signals 157 include a shift control signal 457 and an output select signal 459. The shift control signal 457 may configure the shift circuitry 772 of the serialization circuits 550 to shift data in either the forward direction 473A or the reverse direction 473B, as disclosed herein. Data may be shifted in response to an SCLK signal. The SCLK signal may comprise a serial clock signal, which may correspond to the clock signal 109CK of the second data bus 109. The output select signal 459 may select an output of one of the SR flip flops 762A-D to generate respective data values of the data sequence 242 (e.g., data sequence 242[0] through 242[7]). As disclosed above, the shift and select operations implemented by the serialization circuits 550 may modify the data format 114, such that the serial arrangement of the data unit 712 in the data sequence 242 corresponds to the requested format 514 rather than the original, input format 414.

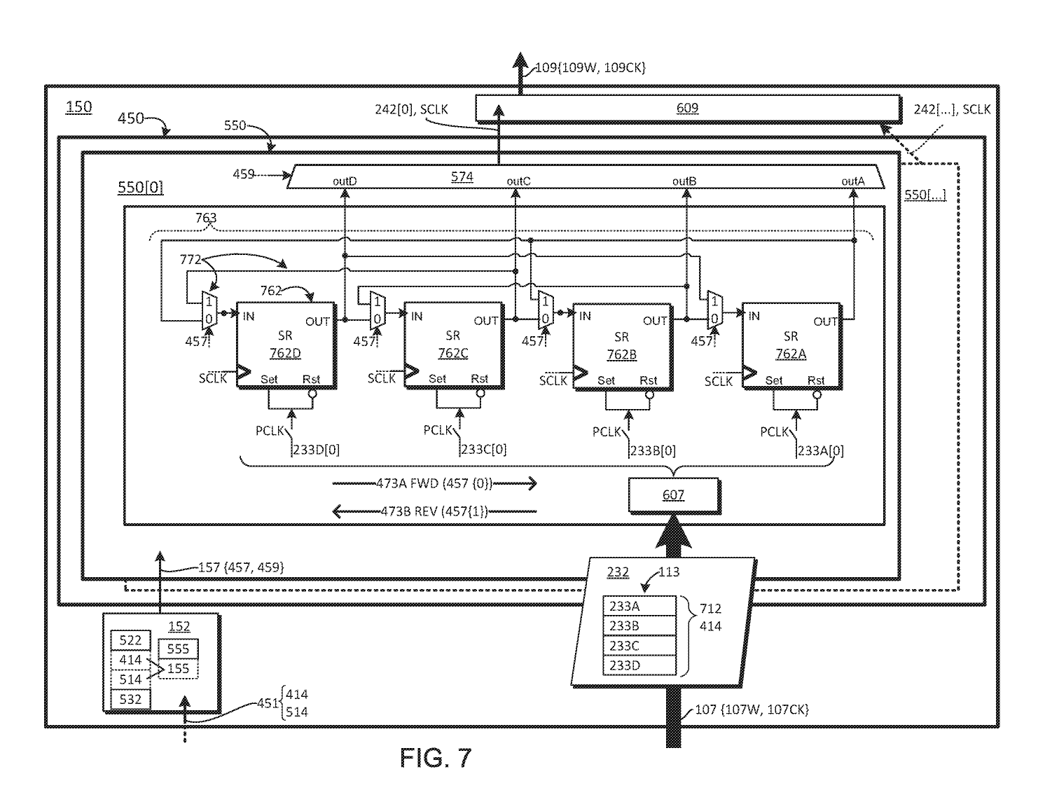

FIG. 8 is a schematic block diagram depicting one embodiment of a serialization circuit 550 of serialization circuitry 450 of an adaptive parallel-serial converter 150 as disclosed herein. The serialization circuitry 550 may comprise a plurality of serialization circuits 550, including serialization circuit 850[0]. The serialization circuit 850[0] may be configured to serialize a particular data value of a data unit 812 (e.g., data value 0). Other serialization circuits 550 are not illustrated to avoid obscuring the details of the disclosed embodiments. The serialization circuit 850[0] may receive data value (0) of each data elements 113 of a data unit 812 (e.g., data value (0) at each of parallel data position 233A-D). The serialization circuit 850[0] may be configured to generate a corresponding data sequence 242[0] comprising data value (0) of each data element 113 at a respective sequence data position 243A-d. The data unit 812 may have a parallel arrangement in the parallel data 232, which may correspond to a first data format 114 (e.g., input format 414 of the data unit 812). The serialization circuit 850[0] may be configured to reformat the data unit 812 into a second, different data format 114 (e.g., a requested format 514) while generating the data sequence 242[0]. In some embodiments, the serialization circuit 850[0] comprises and/or is communicatively coupled to format conversion logic 152, which may be configured to a) determine a input format 414 of the data unit 812 in the parallel data 232, b) determine a requested format 514 for the data unit 812 in the data sequence 242, and c) select a data format modification 155 to reformat the data unit 812 while serializing the data unit 812. The input format 414 and/or requested format 514 may be provided as inputs 451. Alternatively, the format conversion logic 152 may be configured to determine the input format 414 and/or requested format 514, as disclosed herein.

The serialization circuit 850[0] includes register circuitry 852, that comprises a series of reversible latches 862. The reversible latches 862 may be configured to latch parallel data 232 comprising the data unit 812 in response to a PCLK signal, as disclosed herein. In the FIG. 8 embodiment, each reversible latch 862A-D may be configured to latch data value (0) of each of four data elements 113 of the data unit 812. Other register circuitry 852 to serialize other data value(s) of the four data elements 113 are not shown to avoid obscuring the details of the embodiments illustrated in FIG. 8. In other embodiments, each reversible latch 862 may be configured to latch a respective data element 113 (e.g., each reversible latch 862 may be configured to latch an eight-bit data value). In such embodiments, each reversible latch 862 may comprise eight separate reversible latch circuit elements.

The reversible latches 862A-D may be configured to shift data in a selected shift direction (473A or 473B). Data may be shifted circularly within the series of reversible latches 862A-D: in the forward data shift direction 473A data may be shifted from reversible latch 862A to reversible latch 862D and, in the reverse data shift direction 473, data may be shifted from reversible latches 862D to 862A. The data shift direction 473A or 473B may be selected by the shift control signal 457 produced by the format conversion logic 157, as disclosed herein. As illustrated in FIG. 8, each of the reversible latches 862A-D may comprise an IOR terminal and an IOL terminal, which may act as input/output terminals depending on the state of the shift control signal 457 (e.g., REV). When the shift control signal 457 is low (“0”), the reversible latches 862A-D may be configured to shift data in the forward direction 473A (from the IOL terminal to the IOR terminal of proximate reversible latches 862A-D in the series). When the REV signal is high (“1”), the reversible latches 862A-D may be configured to shift data in the reverse direction 473B (from the IOR terminal to the IOL terminal of the proximate reversible latches 862A-D in the series).

The format conversion logic 152 may be configured to determine a data format modification 155 to implement for the data unit 812, as disclosed herein (e.g., by comparing the input format 414 of the data unit 812 to the requested format 514). The format conversion logic 152 may determine the data format modification 155 in response to receiving the parallel data 232. Selecting the data format modification 155 may comprise generating corresponding control signals 157. The control signals 157 may be adapted to configure the reversible latches 862A-D of the register circuitry 852 to shift data in one of the forward direction 473A and the reverse direction 473B responsive to a shift trigger, clock, and/or signal (e.g., SCLK). The control signal 157 may be further adapted to configure the select one of the reversible latches 862A-D to produce the data sequence 242[0] during each SCLK cycle. The output produced on the selected reversible latch 862A-D may comprise data value (0) of each data element 113 of the data unit 812 in sequence (e.g., at respective sequential data positions 243). The sequential arrangement of data values may correspond to the requested format 514.

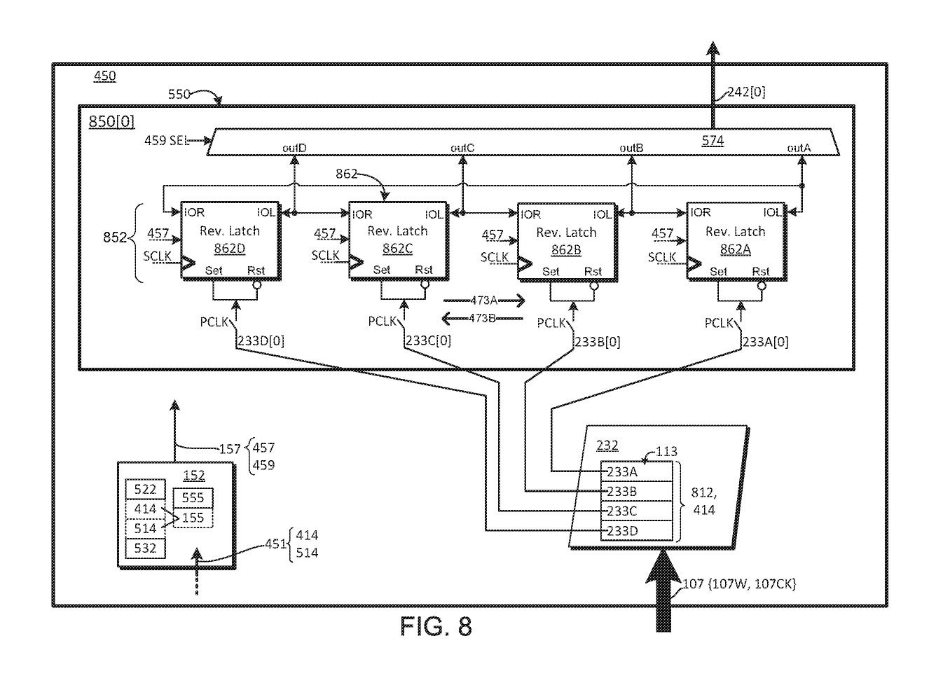

FIG. 9 is a schematic block diagram of one embodiment of a reversible latch 962. The reversible latch 962 of FIG. 9 may be used in any of the embodiments of an adaptive parallel-serial converter 150 disclosed herein (e.g., as a reversible latch 862). The REV format control signal of FIG. 9 may comprise a shift control signal 457, which may configure the reversible latch 962 to shift data in either the reverse direction 473A or the forward direction 473B, as disclosed herein. As illustrated in FIG. 9, the reversible latch 962 may comprise an internal clock signal “clki,” which may correspond to SCLK and/or/SCLK (with phases selected in accordance with the shift control signal 457, referred to as “REV” in FIG. 9).

The IOR terminal of the reversible latch 962 may be coupled a node 971. The node 971 may be coupled to a voltage potential source (Vs) and a ground voltage potential (GND) through transistors 972 and 974, respectively. Transistor 972 may be controlled by the output of NAND logic 964 having inputs comprising the SET signal, PCLK signal, and REV signal (e.g., shift control signal 457) and the transistor 974 may be controlled by the output of NOR logic 966 having inputs comprising an inverse of the RST signal (/RST), an inverse of the PCLK signal (/PCLK), and an inverse of the REV signal (/REV). The IOR terminal may be coupled to first storage circuitry 992 through the transistors 981. The transistors 981 may comprise p-channel transistors. The transistors 981 may be controlled by the internal clock signal. The first storage circuitry 992 may comprise a plurality of tri-state buffers 968 and buffers 969. The tri-state buffers 968 may comprise strong tri-state buffers and the buffers 969 may comprise weak buffers. The first storage circuitry 992 may be coupled to second storage circuitry 994 through switch 983. The transistors 983 may be controlled by an opposite phase of the internal clock “clki” relative to the transistors 981 (may be on when the transistors 981 are off and vice versa). The transistors 983 may comprise p-channel transistors. The second storage circuitry 994 may comprise a plurality of tri-state buffers 968 and buffers 969, as illustrated. The IOL terminal of the reversible latch 962 may be coupled to the storage circuitry 994 at node 979. Node 979 may be coupled to Vs and GND through transistors 976 and 978, respectively. As illustrated, the transistor 976 may be controlled by the output of NAND logic 965 having inputs comprising the SET signal, PCLK signal, and an inverse of the REV signal (/REV). Transistor 978 may be controlled by an output of NOR logic 967 having inputs comprising an inverse of the RST signal (/RST), an inverse of the PCLK signal (/PCLK), and the REV signal. The reversible latch 962 may be configured to set a data value in the storage circuitry 992 and/or 994 responsive to SET and/or RST inputs (e.g., latch a data value of parallel data 232). The reversible latch 962 may be further configured to selectively shift data in the forward direction 473A or the reverse direction 473B in response to the SCLK signal (and the REV signal 157).

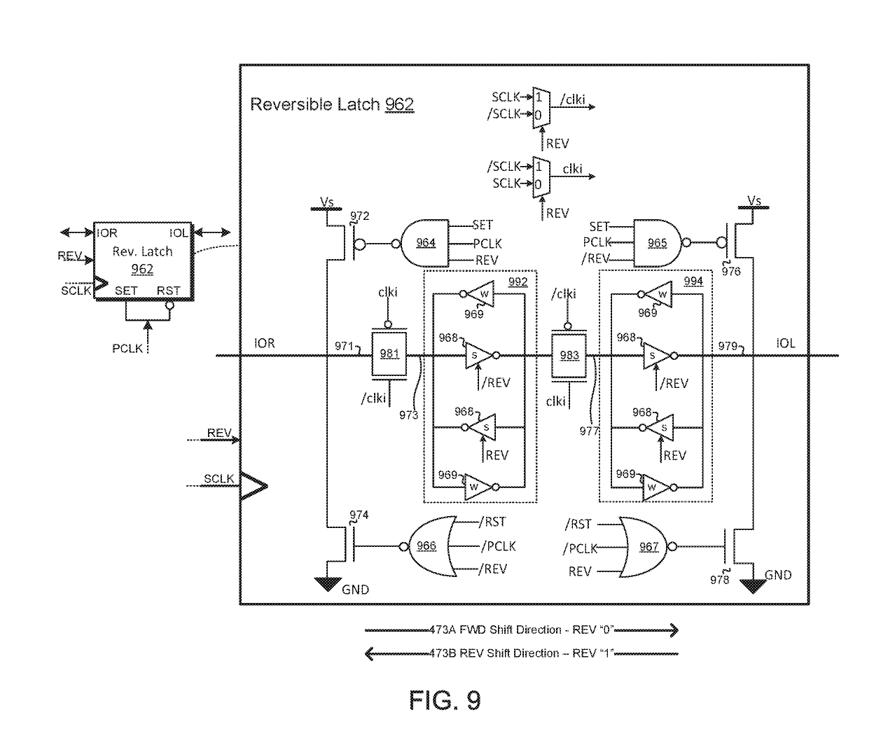

FIG. 10 is a schematic block diagram of another embodiment of an adaptive parallel-serial converter 150. In the FIG. 10 embodiment, the adaptive parallel-serial converter 150 is embodied within a memory system 1021. The memory system 1021 may comprise a non-volatile storage system interfacing with a host 1003 (e.g., a computing device 103). In some embodiments, the memory system 1021 may be embedded within the host 1003. In other embodiments, the memory system 1021 may comprise a memory card and/or a peripheral device.

As depicted, the memory system 1021 includes a memory controller 1006 and a memory 120. The memory 120 may be embodied on a memory structure 1023, which may comprise one or more of a memory die, a memory chip, a memory package, a memory bay, a memory semiconductor, and/or the like. The memory structure 1023 may comprise a non-volatile memory structure comprising one or more non-volatile memory storage locations, non-volatile memory cells, and/or the like. Although a single memory structure 1023 is depicted, the memory system 1021 is not limited in this regard, and could be adapted to include any number of memory structures 1023 (e.g., four or eight memory chips). The memory controller 1006 may receive data and commands from the host 1003 and provide data from the memory 120 to the host 1003 via a host-device interconnect 1019 and/or data bus 1009. The host-device interconnect 1019 and/or bus 1009 may comprise any suitable interconnect and/or bus for communicating data, control, configuration signals, power, and/or the like between the memory system 1021 and the host 1003.

The memory controller 1006 may include one or more state machines, page registers, SRAM, and control circuitry for controlling the operation of the memory 120, and so on. The one or more state machines, page registers, SRAM, and control circuitry for controlling the operation of the memory chip may be referred to as managing or control circuits. The managing or control circuits may facilitate one or more memory array operations including forming, erasing, programming, or reading operations.

In some embodiments, the managing or control circuits (or a portion of the managing or control circuits) for facilitating one or more memory array operations may be integrated within the memory structure 1023. The memory controller 1006 and the memory structure 1023 may be arranged on a single integrated circuit. In other embodiments, the memory controller 1006 and the memory structure 1023 may be arranged on different integrated circuits. In some cases, the memory controller 1006 and the memory structure 1023 may be integrated on a system board, logic board, or a PCB.

The memory structure 1023 includes memory core control circuitry 1026 and a memory core 1024. The memory core control circuitry 1026 may include logic circuitry configured to control the selection of memory storage locations 112 (e.g., memory blocks, pages, and/or the like) within the memory core 1024 (through a memory interconnect 1028), controlling the generation of voltage references for biasing a particular memory array into a read or write state, or generating row and column addresses. The memory core 1024 may include one or more two-dimensional arrays of memory cells or one or more three-dimensional arrays of memory cells. In one embodiment, the memory core control circuits 1026 and the memory core 1024 are arranged on a single integrated circuit. In other embodiments, the memory core control circuitry 1026 (or a portion of the memory core control circuitry 1026) and memory core 1024 may be embodied within different integrated circuit structures. The memory cells may be formed into respective storage locations 122 which, as disclosed herein, may be configured to store data units 112 (e.g., store data elements 113 of data units 112 at respective addresses and/or address offsets within the memory 120). The storage location 122 may comprise one or more non-volatile memory cells.

A memory operation may be initiated when the host 1003 sends instructions to the memory controller 1006, such as a read request, a write request, or the like. The memory controller 1006 may implement memory operations by use of the memory core control circuits 1026, which may provide control signals to the memory core 1024 (via the memory interconnect 1028) in order to perform a read operation and/or a write operation. The memory core control circuits 1026 include any one of or a combination of control circuitry, state machine, decoders, sense amplifiers, read/write circuits, and/or controllers. The memory core control circuits 1026 may perform or facilitate one or more memory array operations including erasing, programming, or reading operations. In one example, the memory core control circuits 1026 comprises an on-chip memory controller for determining row and column address, word line and bit line addresses, memory array enable signals, and data latching signals.

The memory core control circuits 1026 may further comprise an adaptive parallel-serial converter 150, as disclosed herein. In response to a write (or program) request, the host 1003 may send the memory controller 1006 a write command that includes: an address and a data unit 112. The memory controller 1006 may implement the write command by use of the memory core control circuits 1026, which may write the data unit 112 to the specified address. Implementation of the write request may comprise receiving the data unit 112 via the second data bus 109 (as a data sequence 242). The parallel-serial converter 150 may be configured to receive the data sequence 242, and generate corresponding parallel data 232 for communication via the first data bus 107. Generating parallel data 232 may comprise arranging data elements 113 in the data sequence 242 at respective parallel data positions 233. As disclosed above, the parallel arrangement of the data elements 113 may correspond to a data format 114 for the data unit 112. The parallel data 232 may be written to one or more storage location(s) 122 within the memory core 1024 as disclosed herein.

The first data bus 107 may be wider than the second data bus 109. The difference in bus sizes between the first data bus 107 and the second data bus 109 may be due to, inter alia, a clock rate differential between the memory core 1024 and other portions of the memory system 1021 (e.g., the memory controller 1006, periphery region 1027, and/or the like), size considerations, power consumption considerations, thermal characteristics of the memory structure 1023, and/or the like. In some embodiments, the second data bus 109 may be narrower than the first data bus 107 due to the use of a higher clock rate by the memory controller 1006, periphery region 1027, host-device interface 1019, and/or host-device data bus 1009. Alternatively, or in addition, the second data bus 109 may be narrower than the first bus 107 in order to, inter alia, conform to a width of the host-device interface 1019 and/or bus 1009. In some embodiments, the second bus 109 is configured to minimize the area, power consumption, heat generation, and/or latency, required to route signals to/from the memory system 1021 while optimizing a throughput of the memory core 1024 (e.g., while fully utilizing the first bus 107).

As disclosed herein, performing data format conversions on parallel data 232 communicated via the first bus 107, as such parallel data 232 is being converted into respective data sequences 242 for communication via the second bus 109, may enable different hosts 1003 to access the memory 120 even if the hosts 1003 have different native data formats 134. The data format conversions implemented by the adaptive parallel-serial converter 150 may enable the memory system 1021 to appear to the host 1003 as if the memory 120 comprises data stored in the native data format 134 of the host 1003, and without requiring the host 1003 to perform data format conversions on data written to and/or retrieved from the memory system 1021. Implementing data format conversions within the memory system 1021 (e.g., within the periphery region of the memory structure 1023), may enable data format conversions to be implemented with minimal size, power, heat, and/or performance overhead.

In the FIG. 10 embodiment, the native data format 134 of the host 1003 is data format 114C (little endian with eight-bit data elements). The host 1003 may issue a write request to write a data unit 1012A to address α of the memory 120. In response, the memory controller 1006 may communicate a data sequence 242 comprising the data unit 1012A to the memory core control circuits 1026 (the adaptive parallel-serial converter 150). The data elements 113 of the data unit 1012A may be arranged in the data sequence 242 in accordance with the native data format 114C (e.g., may comprise a sequence of data values from the LSDE 0D, 0C, 0B, to the MSDE 0A). The adaptive parallel-serial converter 150 may be configured to generate corresponding parallel data 232. The parallel arrangement of the data elements 113 may correspond to data format 114C and, as such, the data unit 1012A may be stored within the memory in the little-endian data format 114C. By way of non-limiting example, the data unit 1012A comprises the hexadecimal value “0x0A0B0C0D” as four eight-bit data elements 113. The adaptive parallel-serial converter 150 may be configured to record the input format 414 of the data unit 1012A in data format metadata 522, as disclosed herein. The adaptive parallel-serial converter 150 may determine the data format 114C of the data unit 1012A from the write request, a parameter and/or setting, client data format metadata 532 (which may indicate the native data format 134 used by the host 1003), and/or the like.

In some embodiments, the adaptive parallel-serial converter 150 may be configured to selectively modify the parallel arrangement of data units 112 as such data units 112 are being written to the memory 120 (e.g., as data unit 112 are received as data sequence(s) 242 via the second data bus 109). The adaptive parallel-serial converter 150 may determine whether to modify the data format 114 of a data unit 112 based on storage format metadata 1022. The storage format metadata 1022 may determine a data format 114 for use in storing data unit 112 to particular addresses within the memory 120. The storage format metadata 1022 may specify that data units 112 are to be stored in a different data format 114 from the native data format 134 of the host 1003. In the FIG. 10 embodiment, the storage format metadata 1022 may indicate that data written to a particular addresses β be stored in data format 114A (big endian with eight-bit atomic elements). The host 1003 may write a data unit 1012B to address β. The data unit 1012B may comprise four eight-bit data elements 113 (and have the same hexadecimal value “0x0A0B0C0D” as data unit 1012A). The adaptive parallel-serial converter 150 may receive the data sequence 242 comprising the data unit 1012B. The sequential positions 243 of the data elements 113 may correspond to data format 114C (e.g., by communicated from the LSDE 0D, 0C, 0B, to the MSDE 0A).

The adaptive parallel-serial converter 150 may be configured to generate parallel data sequence 242 comprising the data unit 1012B. The adaptive parallel-serial converter 150 may be further configured to modify the data format of the data unit 1012B while generating the parallel data 232 (e.g., while parallelizing the data unit 1012B). The format conversion logic 152 may determine to modify the format of the data unit 1012B in response to determining that the data unit 1012B is formatted in data format 114C, and that the data format 114C is incompatible with the requested storage format 514 for address β (based on the storage format metadata 1022). The format conversion logic 152 may be further configured to select a data format modification 155 to modify the format of the data unit 1012B while the data unit 1012B is being converted from a data sequence 242 to parallel data 232. The data format modification 155 may correspond to the parallel-to-serial data format modifications disclosed herein. In the FIG. 10 embodiment, the adaptive parallel-serial converter 150 may comprise data format modification library 555, which may include a) parallel-to-serial data format modifications to reformat data units 112 during serialization, and b) parallel-to-serial data format modifications to reformat data units 112 during parallelization. The adaptive parallel-serial converter 150 may be configured to implement a parallel-to-serial data format modification configured to convert a data sequence 242 comprising a data unit 112 in data format 114C to parallel data in data format 114A. The parallel data 232 comprising the reformatted data unit 1012B may be written to the memory 120, as disclosed herein. As illustrated in FIG. 10, the data unit 1012B may be arranged in the memory 120 in accordance with data format 114A (big endian with eight-bit atomic elements), rather than data format 114C.

The host 1003 may issue read requests to the memory controller 1006. The memory controller 1006 may implement a request to read a data unit 112 at a particular address by, inter alia, instructing the memory core control circuits 1026 to read the data unit 112 at the particular address. The adaptive parallel-serial converter 150 may receive the data unit 112 as parallel data 232 (via the first data bus 107), and serialize the data unit 112 for communication via the second data bus 109. The adaptive parallel-serial converter 150 may determine whether to modify the data format 114 of the data unit 112 during serialization of the data unit 112, select a data format modification 155 (from the library 555), and implement the selected data format modification 155 while generating the data sequence 242 comprising the data unit 112, as disclosed herein.

As disclosed herein, the adaptive parallel-serial converter 150 may be embodied within a peripheral region of the memory structure 1023 (e.g., a peripheral region of a memory substrate, chip, die, and/or the like). The adaptive parallel-serial converter 150 may, therefore, be embodied as peripheral circuitry 1027 of the memory structure 1023. The peripheral circuitry 1027 may include, but is not limited to: core control circuits 1026, program circuitry, read circuitry, erase circuitry, driver circuitry, sense circuitry, interconnect circuitry, and so on. It may be advantageous to minimize the size, power consumption, and/or logic delays of the peripheral circuitry 1027. Reducing the size of peripheral circuitry 1027 may enable a larger portion of the memory structure 1023 to be used as memory storage (e.g. to implement additional storage locations 122). Reducing power consumption of the peripheral circuitry 1027 may reduce the overall power requirements of the memory system 1021, reduce heat generated within the memory structure 1023, decrease disturb conditions, decrease operating temperature, reduce error rate, increase media life, and so on. Reducing logic delays of peripheral circuitry 1027 may result in increases in the rate at which the memory system 1021 is capable of performing input/output operations (e.g., reduce the latency of input/output operations).

The adaptive parallel-serial converter 150 disclosed herein may be configured to may be configured to implement data format conversions (e.g., endian conversions) while minimizing the size, power consumption, and/or logic delays of the peripheral region circuitry 1027. The adaptive parallel-serial converter 150 may minimize a size and/or power requirements of the peripheral circuitry 1027 by, inter alia, implementing data format conversions, such as the endian conversions, in the serialization circuitry 450, disclosed herein (and/or parallelization circuitry 1255 disclosed in further detail below). The adaptive parallel-serial converter 150 may, therefore, be configured to implement data format conversions during data serialization, and without the need for separate, dedicated format conversion circuitry. Implementing data format conversions in serialization and/or parallelization circuitry may also reduce logic delays that would be imposed by separate data conversion circuitry. The output selection circuitry (e.g., selection logic 474 and/or selection circuitry 574) of the serialization circuitry 450 may be further configured to reduce size, power, and/or logic delays of the peripheral circuitry 1027. As disclosed above, the adaptive parallel-serial converter 150 applies an output select signal 459 to the control the selection logic 474 and/or selection circuitry 574 to perform various data format conversions. The output select signal 459 is generated by the format control logic 152 in response to receiving parallel data 232, and remains the same while a corresponding serial data sequence 242 is produced. Maintaining the output select signal 459 unchanged while a data unit 112 is serialized may reduce power consumption and/or logic delays within the serialization circuitry 450 during serialization since, inter alia, the selection logic 474 and/or selection circuitry 574 are modified, at most, once per serialization operation (at the rate of a parallel data clock, such as PCLK or 107CK), as opposed to being modified at the rate of the serial output (at the rate of a serial data block, such as SCLK or 109CK).

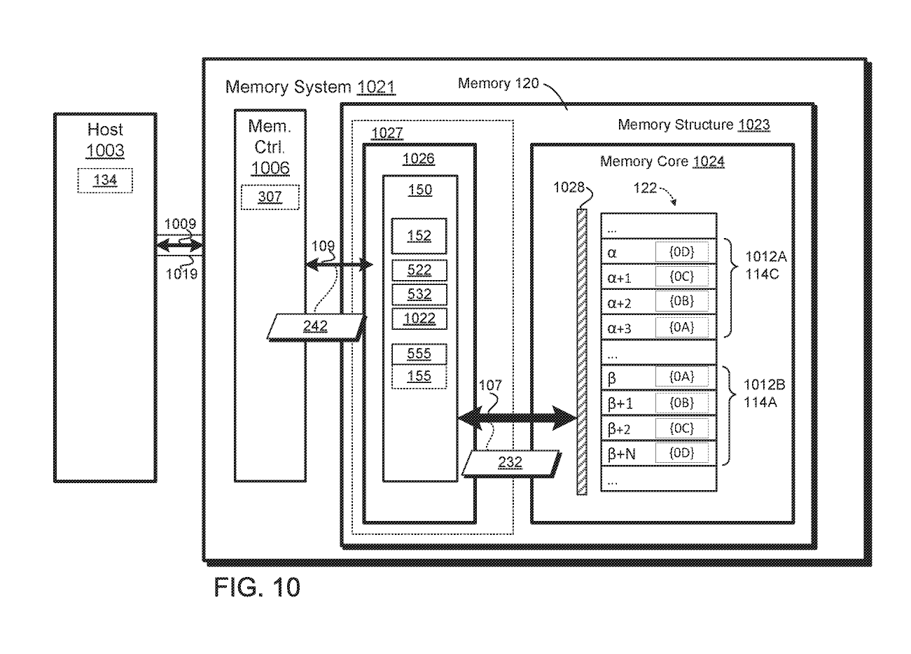

FIG. 11 is a schematic block diagram of one embodiment of an adaptive parallel-serial converter 150 configured to modify data formatting during one or more of serialization and parallelization operations. In some embodiments, the adaptive parallel-serial converter 150 may comprise serialization circuitry 450 and parallelization circuitry 1155. The serialization circuitry 450 may be configured to perform serialization operations, as disclosed herein, which may comprise a) receiving parallel input data 1132 comprising a data unit 112 embodied as parallel data 232 in a particular data format 114 (e.g., input format 414), and b) generating serial output data 1143 comprising the data unit 112 embodied as a data sequence 242 corresponding to a determined data format 114 (requested format 514). The parallelization circuitry 1155 may be configured to perform parallelization operations, which may comprise a) receiving a serial input data 1142 comprising a data unit 112 embodied as a data sequence 242 in a particular data format 114 (input format 414), and b) generating parallel output data 1133 comprising the data unit 112 embodied as parallel data 232 corresponding to a determined data format 114 (requested format 514).

The serialization circuitry 450 and the parallelization circuitry 1155 may be configured to modify the data format 114 of data units 112 during the conversion operations performed on the data units 112 thereby. The data format modifications performed by the serialization circuitry 450 and/or parallelization circuitry 1155 may be determined and/or controlled by format conversion logic 152. The format conversion logic 152 may be configured to determine input formats 414 of data units 112 received at the adaptive parallel-serial converter 150, as disclosed herein. The format conversion logic 152 may be configured to determine input formats 414 for data units 112 received as serial input data 1142 (e.g., data units 112 embodied as data sequences 242, communicated via the second data bus 109, second interconnect 119, and/or the like) and/or parallel input data 1132 (e.g., data units 112 embodied as parallel data 232, communicated via the first data bus 107, first interconnect 117, accessed from a memory 120, or the like). The data format logic 152 may be further configured to determine requested data formats 514 for data units 112 output by the adaptive parallel-serial converter 150. The requested data formats 514 may correspond to serial output data 1143 and/or parallel output data 1133 produced by the adaptive parallel-serial converter 150.

The format conversion logic 152 may be configured to determine data format modifications 155 to implement during a) parallel-to-serial conversion operations performed by the serialization circuitry 450 and b) serial-to-parallel conversion operations performed by the parallelization circuitry 1155. The format conversion logic may comprise format logic circuitry 1152, which may be configured to determine data format modifications 155 for conversion operations based on determined input formats 414 and/or requested formats 514 corresponding to the conversion operations, as disclosed herein. The format logic circuitry 1152 may comprise one or more of storage circuitry, look-up circuitry, logic circuitry, state machine circuitry, a library 555, and/or the like. In some embodiments, the format logic circuitry 1152 comprises and/or is communicatively coupled to non-transitory storage comprising conversion metadata 1153. The conversion metadata 1153 may define a plurality of data format conversions 155, each data format modification 155 corresponding to a respective set of input formats 414 and requested formats 514 and defining respective format control signals 157. The conversion metadata 1153 may be embodied as electronic data stored within one or more of a storage circuit, a non-transitory storage medium, firmware, a register, and/or the like.

The format control signals 157 corresponding to the data format modifications 155 may configure the adaptive parallel-serial converter 150 to implement selected data format conversions 155 during parallel-to-serial and/or serial-to-parallel conversion performed thereby. In some embodiments, the format conversion logic 152 further comprises format control circuitry 1157 configured to assert and/or drive format control signals 157 corresponding to selected data format modifications 155 and/or route the format control signals 157 to one or more of the serialization circuitry 450 and parallelization circuitry 1155. The format control circuitry 1157 may comprise and/or be communicatively coupled one or more signal drivers, signal amplifiers, signal interconnects, control interconnects, and/or the like.

The adaptive parallel-serial converter 150 may further comprise arbitration logic 1105, which may be configured to a) determine an operating mode for the adaptive parallel-serial converter 150, and b) configure the adaptive parallel-serial converter 150 to operate in the determined operating mode. The operating modes of the adaptive parallel-serial converter 150 may include, but are not limited to: a serialization mode and a parallelization mode. When configured for operation in the serialization mode, the adaptive parallel-serial converter 150 may be configured to receive parallel input data 1132 and output corresponding serial output data 1143. When configured for operation in the parallelization mode, the adaptive parallel-serial converter 150 may be configured to receive serial input data 1142 and output corresponding parallel output data 1133. Accordingly, when operating in the serialization mode, the arbitration logic 1105 may configure the serialization circuitry 450 to receive parallel input data 1132 and output serial output data 1143 and, when operating in parallelization mode, the arbitration logic 1105 may configure the parallelization circuitry 1155 to receive serial input data 1142 and output parallel output data 1133.

In some embodiments, the adaptive parallel-serial converter 150 comprises and/or is communicatively coupled to interconnect circuitry, which may be configured to selectively couple the adaptive parallel-serial converter to one or more of the first data bus 107, first interconnect 117, second data bus 109, and/or second interconnect 119. When operating in serialization mode, the arbitration logic 1105 may configure the interconnect circuitry 1103 to communicatively couple the serialization circuitry 450 to one or more of the first data bus 107, first interconnect 117, second data bus 109, and/or second interconnect 119 (by use of mode control signals 1101). When operating in parallelization mode, the arbitration logic 1105 may configure the interconnect circuitry 1103 to communicatively couple the parallelization circuitry 1155 to one or more of the first data bus 107, first interconnect 117, second data bus 109, and/or second interconnect 119.

The arbitration logic 1105 may select the operating mode using any suitable technique or mechanism. By way of non-limiting example, the arbitration logic 1105 may select the operating mode based on, inter alia, control signals communicated via one or more of the first interconnect 117, the first data bus 107, the second interconnect 119, the second data bus 109, command(s) received from a host 1003 and/or computing device 103, and/or the like. As disclosed above, the adaptive parallel-serial converter 150 may comprise a parallel data interface 507 and/or a serial data interface 609, which may be configured to communicatively and/or electrically couple to the first interconnect 117, first data bus 107, second interconnect 119, and/or second data bus 109, respectively. The arbitration logic 1105 may use the parallel data interface 507 and/or serial data interface 609 to select the operating mode for the adaptive parallel-serial converter 150. The arbitration logic 1105 may be further configured to receive communication control signals, arbitrate data communication, and so on, in accordance with interface and/or bus protocols of the parallel data interface 507 and/or serial data interface 609, as disclosed herein.

As disclosed above, the adaptive parallel-serial converter 150 may be configured to perform a conversion operation in response to receiving a data unit 112. The data unit 112 may be received as either parallel input data 1132 or serial input data 1142 (depending on the selected operating mode determined by the arbitration logic 1105). In response to receiving the data unit 112, the adaptive parallel-serial converter 150 may a) produce format control signals 157 corresponding to a selected data format modification 155 for the conversion operation (e.g., by use of the format conversion logic 152, as disclosed herein), and b) convert the data unit 112 to one or more of serial output data 1143 and parallel output data 1133 in which the data unit 112 is formatted according to the requested format 514 (e.g., by use of one or more of the serialization circuitry 450 and parallelization circuitry 1155). The format of the data unit 112 may be modified from the determined input format 414 to the requested data format 514 while the data unit 112 is converted.

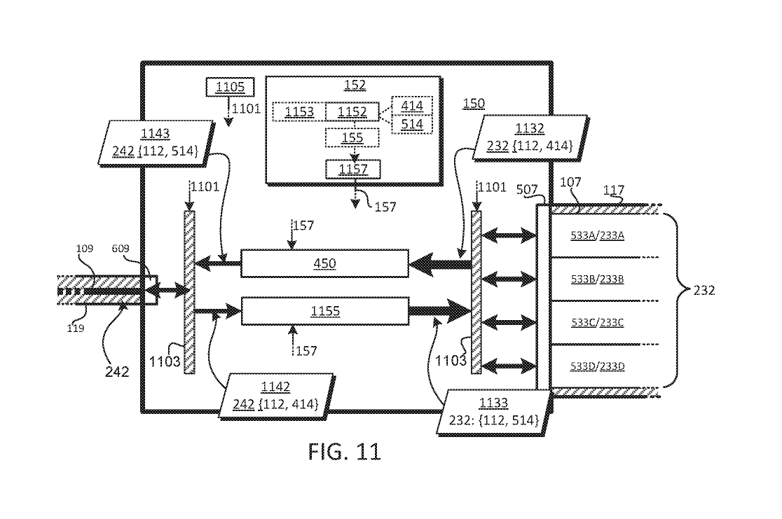

FIG. 12 is a schematic block diagram of another embodiment of an adaptive parallel-serial converter 150 configured to modify data formatting during one or more of serialization and parallelization operations. In the FIG. 12 embodiment, the adaptive parallel-serial converter 150 comprises serialization circuitry 450 and parallelization circuitry 1255. The serialization circuitry 450 may be configured to modify the data format 114 of data units 112 while such data units 112 are being converted from parallel data 232 to corresponding data sequences 242, as disclosed herein. The parallelization circuitry 1255 may be configured to modify the data format 114 of data units 112 while such data units are being converted from data sequences 242 to parallel data 232.

In the FIG. 12 embodiment, the parallelization circuitry 1255 may comprise buffer circuitry 1252 and routing circuitry 1254. The parallelization circuitry 1255 may be configured to receive data sequences 242 via the second data bus 109. A data sequence 242 may comprise a data unit 112. Data elements 113 of the data unit 112 may be arranged within the data sequence 242 at respective sequential data positions 243, each of which may correspond to a respective sequential communication period 245 of the second data bus 109 (e.g., in accordance with the clock signal 109CK). The sequential arrangement of the data elements 113 of a data unit 112 may correspond to the data format 114 of the data unit. The parallelization circuitry 1255 may be configured to a) receive a data sequence 242 comprising a data unit 112 (e.g., via the second data bus 109), and b) generate parallel data 232 comprising the data unit 112 (e.g., for communication via the first data bus 107).

The buffer circuitry 1252 may be configured to buffer one or more data units 112 in a parallel arrangement (for communication on the first data bus 107 as parallel data 232). The buffer circuitry 1252 may be sized and/or configured in accordance with the size and/or configuration of data units 112 being processed by the adaptive parallel-serial converter 150, the width 109W of the second data bus 109, the width 107W of the first data bus 107, and so on. In the FIG. 12 embodiment, the adaptive parallel-serial converter 150 is configured to process data units 112 that comprise four eight-bit data elements 113, the width 109W of the second data bus 109 may be eight bits (to communicate respective data elements 113 during each sequential communication period 245), and the width 107W of the second data bus 107 may comprise 32 bits (to communicate a data unit 112 in parallel, as parallel data 232). The disclosure is not limited in this regard, however, and could be adapted for use with data units 112, a second data bus 109, and/or a first data bus 107 of any suitable size and/or configuration.

As disclosed above, the parallelization circuitry 1255 may be configured to form parallel data 232 comprising the data elements 113 of a data sequence 242 by, inter alia, buffering the data elements 113 in the buffer circuitry 1252. The buffer circuitry 1252 may comprise a plurality of registers 1262, and each register 1262 may be configured to store a respective data element 113 (e.g., each register 1262 may be configured to hold eight data bits). In the FIG. 12 embodiment, the buffer circuitry 1252 comprises four registers 1262A-D, each register being configured to hold one of four data elements 113 of a data unit 112. Each of the registers 1262A-D may correspond to a respective parallel data position 233A-D of parallel data 232 comprising the data unit 112 (and/or data channel 533A-D of the first data bus 107). Accordingly, the arrangement of data elements 113 within the registers 1262A-D may determine, inter alia, the parallel arrangement (and data format 114) of the data unit 112 as communicated as parallel data 232 via the first data bus 107.

The parallelization circuitry 1255 may be configured to selectively route data elements 113 of a data unit 112 to registers 1262A-D of the buffer circuitry 1252. The selective routing may be configured to, inter alia, modify the data format 114 of the data unit 112 during parallelization of the data unit 112. As illustrated in FIG. 11, the parallelization circuitry 1255 may receive a data unit 1212 as a data sequence 242. By way of non-limiting example, the data unit 1212 may comprise the hexadecimal value “0x0A0B0C0D” and may be in data format 114A. The data sequence 242 may comprise four sequential data positions 243A-D, each corresponding to a respective sequential communication period 245 (τ through τ+3). In accordance with data format 114A, the data sequence 242 may comprise: the MSDE 113[T] at the first sequential data position 243A (e.g., received during a first sequential communication period 245, τ), a next most significant data element 113[τ+1] {0B} at a next sequential data position 243B (e.g., received during a next sequential communication period 245, τ+1), and so on, with the LSDE 113[τ+3] {0D} being received at a last sequential data position 243D (e.g., received during a last sequential communication period 245 for the data unit 1212, τ+3).

Format conversion logic 152 of the adaptive parallel-serial converter 150 may be configured to determine whether to reformat data units 112 during parallelization. The format conversion logic 152 may determine whether to reformat the data unit 1212 in response to comparing an input format 1214 of the data unit 1212 to a requested format 514 for the data unit 1212. The input format 1214 may correspond to the sequential order of the data elements 113 in the data sequence 242 (e.g., determine the order in which the data elements 113 are communicated via the second data bus 109). In the FIG. 12 embodiment, the input format 1214 is data format 114A. The format conversion logic 152 may determine the input format 1214 and/or requested format 514 from one or more of: input(s) 451 to the adaptive parallel-serial converter 150, metadata pertaining to the memory 120 (data format metadata 522), metadata pertaining to one or more command(s), metadata pertaining to one or more computing device(s) 103 and/or host 1003 (e.g., client format metadata 532), metadata pertaining to storage operations on the memory 120 (e.g., storage format metadata 1022), and/or the like, as disclosed herein. The format conversion logic 152 may be further configured to select a data format modification 155 to convert the determined sequential format 1214 of the data unit 112 (data format 114A) to a requested format 514 for the data unit 112. The data format modification 155 may be selected from a library 555, as disclosed herein.

Data format conversions 155 to modify the data format 114 of a data unit 112 during parallelization may comprise operations that determine and/or modify the parallel arrangement of the data elements 113 of the data unit 112. As illustrated in FIG. 12, each register 1262A-D may correspond to a respective parallel data position 233 (and/or parallel data channel 533). The registers 1262A-D used to buffer respective data elements 113 may, therefore, determine a data format 114 for the data unit 112. A data format modification 155 for implementation during parallelization of a data unit 112 may comprise, inter alia, routing control signals 1259, which may configure the routing circuitry 1254 to route data elements 113 at particular sequential data positions 243 (e.g., received during particular sequential communication periods 245) to selected registers 1262A-D of the buffer circuitry 152. The routing circuitry 1254 may comprise any suitable circuit elements for selectively communicating data signals including, but not limited to: a de-multiplexer, switch circuitry, interconnect circuitry, and/or the like. A routing control signal 1259 may configure the routing circuitry 1254 to route data signals on the second data bus 109 (a data element 113) to a selected one of the registers 1262A-D.

In the FIG. 12 embodiment, a NOP data format modification 155 may comprise buffering data elements 113 within registers 1262 (and parallel data positions 233) that correspond to the sequential data positions 243 thereof, such that the data element 113 at the first sequential data position 243A in the data sequence 242 is routed to register 1262A (and parallel data position 233A), the data element 113 at the next sequential data position 243B is routed to register 1262B (and parallel data position 233B), and so on. A NOP data format modification 155 for the exemplary data unit 1212 may comprise configuring the routing circuitry 1254 to route the MSDE 113[τ] {0A} at sequential data position 243A to register 1262A (and parallel data position 233A), route the next most significant data element 113[τ+1] at sequential data position 243B to register 1262B (and parallel data position 233B), and so on, with the LSDE 113[τ+3] being routed to register 1262D (and parallel data position 233D). The contents of the buffer circuitry 1252 (e.g., the contents of the registers 1262A-D) may be output as parallel data 232A on the first data bus 107. As illustrated in FIG. 12, the parallel arrangement of the data elements 113 of the data unit 1212 in the parallel data 232A corresponds to data format 114A.

As disclosed above, during parallelization, a data element 113 is received during each of N sequential communication periods 245 (τ through τ+3 for data units 112 comprising four data elements 113[τ] through 113[τ+3]). The routing control signals 1259 for the NOP data format modification 155 may configure the routing circuitry to route the data element 113 communicated during each of the N (4) sequential communication periods 245 to a register 1262A-D, respectively. The routing control signals 1259 may comprise a sequence of select signals which may buffer the data elements 113 of the data unit 1212 as follows: “0” at τ to buffer data element 113[T] within register 1262A (at parallel data position 233A), “1” at τ+1 to buffer data element 113[τ+1] within register 1262B (at parallel data position 233B), “2” at τ+2 to buffer data element 113[τ+2] within register 1262C (at parallel data position 233C), and “3” at τ+3 to buffer data element 113[τ+3] within register 1262D (at parallel data position 233D). FIG. 12 illustrates parallel data 232A that comprises the data unit 1212 in data format 114A (e.g., parallelized in accordance with the NOP data format modification 155, as disclosed herein).

Other data format conversions 155 for implementation during parallelization may be configured to modify the data format 114 of a data unit by, inter alia, modifying the routing control signals 1259 used to buffer the data elements 113 in the data sequence 242. Exemplary data format conversions 155 (and corresponding sets of routing control signals 1259) to convert sequential data 242 comprising a data unit 112 in data format 114A to any other data format 114A-E while producing corresponding parallel data 232 are listed in Table 8 below:

TABLE 8

| Data Format | Route | Seq. Data | | | Seq. Data |
|---|---|---|---|---|---|
| Conversion | Ctrl. | 1262A-233A | Seq. Data | Seq. Data | 1262D-233D |
| 155 | 1259 | (1^{st} in seq.) | 1262B-233B | 1262C-233C | (last in seq.) |
| NOP | 0, 1, 2, 3 | 113 [τ] {0A} | 113 [τ + 1] {0B} | 113 [τ + 2] {0C} | 113 [τ + 3] {0D} |
| 114A to 114B | 0, 1, 2, 3 | 113 [τ] {0A} | 113 [τ + 1] {0B} | 113 [τ + 2] {0C} | 113 [τ + 3] {0D} |
| 114A to 114C | 3, 2, 1, 0 | 113 [τ + 3] {0D} | 113 [τ + 2] {0C} | 113 [τ + 1] {0B} | 113 [τ] {0A} |
| 114A to 114D | 2, 3, 0, 1 | 113 [τ + 2] {0C} | 113 [τ + 3] {0D} | 113 [τ] {0A} | 113 [τ + 1] {0B} |
| 114A to 114E | 1, 0, 3, 2 | 113 [τ + 1] {0B} | 113 [τ] {0A} | 113 [τ + 3] {0D} | 113 [τ + 2] {0C} |
| 114A to . . . | | | | | |

As illustrated in FIG. 12, implementing a data format modification 155 to change data format 114A to data format 114C (114A to 114C) while parallelizing the data unit 1212 may result in parallel data 232B. As also illustrated in FIG. 12, implementing a data format modification 155 to change data format 114A to data format 114E (114A to 114E) while parallelizing the data unit 1212 may result in parallel data 232C.

Although particular examples of data format conversions 155 to modify the data format 114 of data units 112 while such data units 112 are parallelized are described herein, the disclosure is not limited in this regard and could be adapted to implement any number of data format conversions 155 to convert a data sequence 242 comprising a data unit 112 in any suitable data format 114 to parallel data 232 comprising the data unit 112 in any other suitable data format 114. Data format conversions 155 (and corresponding sets of routing control signals 1259) to convert a data sequence 242 comprising a data unit 112 “0x0A0B0C0D” in data format 114E (e.g., data sequence 0B, 0A, 0D, 0C at τ through τ+3) to any other data format 114, are listed in Table 9 below:

TABLE 9

| Data Format | Route | Seq. Data | | | Seq. Data |
|---|---|---|---|---|---|
| Conversion | Ctrl. | 1262A-233A | Seq. Data | Seq. Data | 1262D-233D |
| 155 | 1259 | (1^{st} in seq.) | 1262B-233B | 1262C-233C | (last in seq.) |
| NOP | 0, 1, 2, 3 | 113 [τ] {0B} | 113 [τ + 1] {0A} | 113 [τ + 2] {0D} | 113 [τ + 3] {0C} |
| 114E to 114A | 1, 0, 3, 2 | 113 [τ + 1] {0A} | 113 [τ] {0B} | 113 [τ + 3] {0C} | 113 [τ + 2] {0D} |
| 114E to 114B | 1, 0, 3, 2 | 113 [τ + 1] {0A} | 113 [τ] {0B} | 113 [τ + 3] {0C} | 113 [τ + 2] {0D} |
| 114E to 114C | 2, 3, 0, 1 | 113 [τ + 2] {0D} | 113 [τ + 3] {0C} | 113 [τ] {0B} | 113 [τ + 1] {0A} |
| 114E to 114D | 3, 2, 1, 0 | 113 [τ + 3] {0C} | 113 [τ + 2] {0D} | 113 [τ + 1] {0A} | 113 [τ] {0B} |
| 114E to . . . | | | | | |

Data format conversions 155 to convert data units 112 in other data formats 114 (e.g., data formats 114B-D) during parallelization may be implemented in a similar manner. The data format conversions 155 (and corresponding sets of routing control signals 1259 and/or register control signals 1257) may be embodied within a library 555, logic circuitry, state machine logic, and/or the like as disclosed herein.

As disclosed above, the parallelization circuitry 1255 may be configured to selectively modify the data format 114 of a data unit 112 while producing parallel data 232 comprising the data unit 112 (e.g., while parallelizing the data unit 112). The parallelization circuitry 1255 may parallelize a data unit 112 by: a) receiving a data sequence comprising data elements 113 of the data unit during each of N sequential communication periods 245 (at respective sequential data positions 243), b) buffering the data elements 113 received during each of the N sequential communication periods 245 at respective parallel data positions 233 (e.g., within selected registers 1262A-D), and c) outputting the buffered data elements 113 as parallel data 232 on the first data bus 107. Parallelizing a data unit 112 may further comprise determining whether to modify the data format 114 of the data unit 112, which may comprise a) determining a sequential format 1214 of the data unit 112 as communicated in the data sequence 242, b) determining a requested format 514 for parallel data 232 comprising the data unit 112, and c) comparing the sequential format 1214 to the requested format 514. Parallelizing a data unit 112 may further include: a) selecting a data format modification 155 to implement while parallelizing the data unit 112 based on comparing the sequential format 1214 to the requested format 514; and b) generating format control signals 157 corresponding to the selected data format modification 155. The format control signals 157 may comprise a set of routing control signals 1259, as disclosed herein. The format control signals 157 may further include a register control signal 1257 to configure respective registers 1262A-D to latch data routed thereto by the routing circuitry 1254, output data latched therein, and so on.

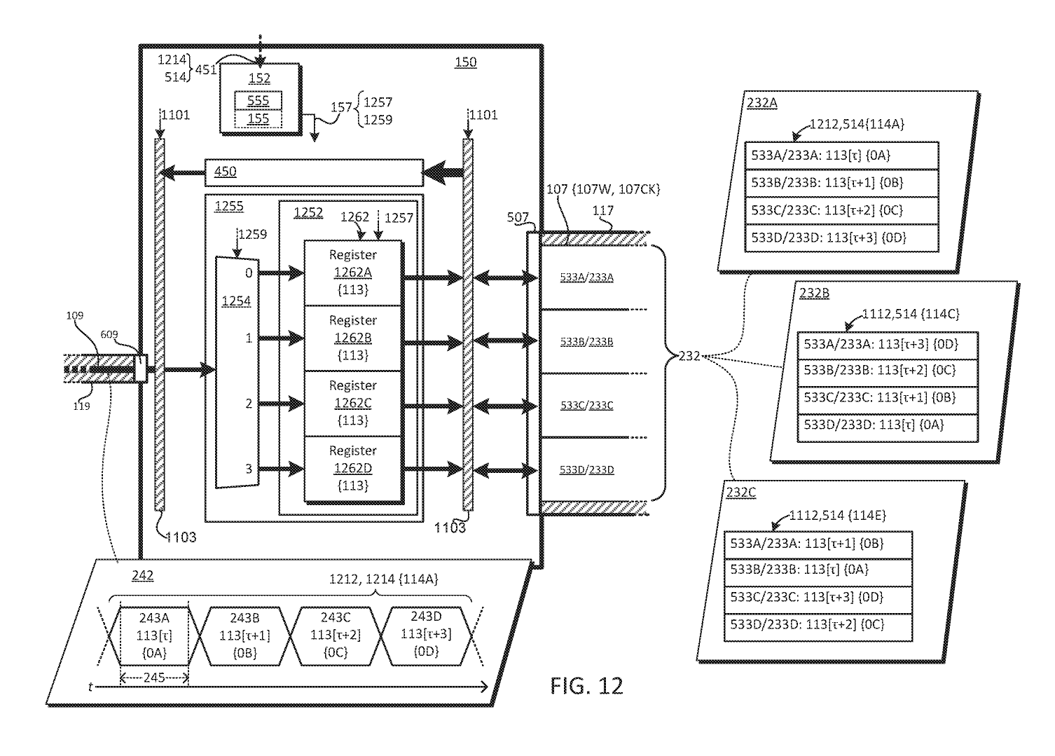

FIG. 13 is a schematic block diagram of another embodiment of parallelization circuitry 1355 of the adaptive parallel-serial converter 150 disclosed herein. The parallelization circuitry 1355 may be configured to modify the data format 1314 of data units 1312 while such data units 1312 are being parallelized (e.g., converted from data sequences 242 to corresponding parallel data 232), as disclosed herein. The adaptive parallel-serial converter 150 may further comprise serialization circuitry 450 (not shown in FIG. 13 to avoid obscuring details of the illustrated embodiments).

The parallelization circuitry 1355 may be configured to receive data units 1312 embodied as respective data sequences 242 and convert the data sequences 242 to parallel data 232, as disclosed herein. Receiving a data unit 1312 as a data sequence 242 may comprise receiving data elements 113 of the data unit 1312 during respective sequential communication periods 245 and in accordance with a sequential order. As disclosed above, the sequential order of the data elements 113 may correspond to the input format 1314 of the data unit 1312. The incoming data elements 113 may be buffered within the parallelization circuitry 1355, which may comprise storing the data elements 113 at respective storage locations (e.g., within selected SR flip flops 762). Incoming data elements 113 may be routed to a selected SR flip flop 762 by use of, inter alia, input select circuitry 1374. The input select circuitry 1374 may comprise a de-multiplexer, switch circuitry, interconnect circuitry, and/or the like. The input select circuitry 1374 may be controlled by an input select signal 1359, which, as disclosed in further detail herein, may correspond to a format control signal 157 of a data format modification 155 being implemented during parallelization of the data unit 1312. The input select signal 1359 may configure the input select circuitry 1374 to direct data elements 113 of the data sequence 242 to an input 461A-D (InA through InD) of a respective one of the SR flip flops 762A-D.

The parallelization circuitry 1355 may comprise a plurality of SR flip flops 762 connected in a circular, reversible sequence 763. By way of non-limiting example, each SR flip flop 762A-D may be configured to hold a respective 8-bit data element 113. The disclosure is not limited in this regard, however, and could be adapted for use with any number of data elements having any suitable size. Shift circuitry 772 may be configured to shift data elements 113 held in the respective SR flip flops 762A-D in a circular, reversible shift pattern (e.g., responsive to a clock signal, such as SCLK). As the data elements 112 of the data sequence 242 are received, the outputs of the SR flip flops 762A-D produce a parallel data output 1332, which may comprise parallel data 232 comprising the data unit 1312. The parallel data output 1332 may be communicated via a suitable mechanism, such as the first data bus 107 and/or first interconnect 117 (per the PCLK signal thereof), as disclosed herein.

The parallelization circuitry 1355 may be configured to receive format control signals 157, which may include a shift control signal 457 and an input select signal 1359. The shift control signal 457 may determine a shift direction of the shift circuitry 772, as disclosed herein (e.g., a value of “0” may cause the shift circuitry 772 to shift data elements 113 in the forward direction 473A and a value of “1” may cause the shift circuitry to shift data elements 113 in the reverse direction 473B). The input select signal 1359 may determine a storage location for incoming data elements 113 of the data sequence 242 (e.g., select the SR flip flop 762A-D to receive incoming data elements 113). In the FIG. 13 embodiment, a value of “0” configures the input select circuitry 1374 to route incoming data elements 113 to the first SR flip flop 762A of the sequence 763, a value of “1” configures the input select circuitry 1374 to route incoming data elements 113 to SR flip flop 762B, a value of “2” configures the input select circuitry 1374 to route incoming data elements 113 to SR flip flop 762C, and a value of “3” configures the input select circuitry 1374 to route incoming data elements 113 to SR flip flop 762D.

The format control signals 157 may be used to modify the data format 114 of data units 112 while the data units 112 are parallelized. The parallelization circuitry 1355 may comprise and/or be communicatively coupled to format conversion logic 152. The format conversion logic 152 may determine an input data format 1314 for data sequences received at the parallelization circuitry 1355, determine a requested format 514 for data unit 1312, and select a data format modification 155 to convert the determined input data format 1314 to the requested format 514, as disclosed herein. The format control signals 157 of the selected data format modification 155 may comprise a shift control signal 457 and input select signal 1359, which may configure the parallelization circuitry 1355 to modify the format of the data unit 1312 while the data unit 1312 is parallelized.

By way of non-limiting example, the parallelization circuitry 1355 may be configured to parallelize sequential data 242 comprising a data unit 1312 comprising four eight-bit data elements 113 and having the hexadecimal value of “0x0A0B0C0D.” The input format 1314 of the data unit 1312 may be big endian with eight-bit atomic elements (e.g., data format 114A). Accordingly, the sequential order of the data elements 113 in the data sequence 242 may correspond to data format 114A (with the MSDE “0A” being ordered first, and the LSDE “0D” being ordered last). The format conversion logic 152 may determine a requested format 514 and select a data format modification 155 to implement while parallelizing the data unit 112 by, inter alia, comparing the input format 1314 to the requested format 514, as disclosed herein. The format conversion logic 152 may be further configured to produce format control signals 157 corresponding to the selected data format modification 155, which may include a shift control signal 457 and input select signal 1359. The format control signals 157 may, therefore, be configured to cause the serial-to-parallel circuitry to modify the format of the data unit 1312 from the input format 1314 to the requested format 514 while the data unit 1312 is parallelized (e.g., converted from a data sequence 242 to parallel data 232).

The shift control signal 457 and input select signal 1359 may be selected to convert the data unit 1312 from any input format 1314 to any requested format 514. By way of non-limiting example, Table 10 below shows the contents of the SR flip flops 762A-D (and parallel output data 1332) produced while parallelizing the data unit 1312 (“0x0A0B0C0D” in data format 114A) using various format control signals 157 (e.g., different combinations of shift control signals 457 and input select signals 1359).

TABLE 10

| | Shift Control 457: | | | | Shift Control 457: | | | |
|---|---|---|---|---|---|---|---|---|
| | {0, FWD 473A} | | | | {1, REV 473B} | | | |
| | OutD | OutC | OutB | OutA | OutD | OutC | OutB | OutA |
| | 233D | 233C | 233B | 233A | 233D | 233C | 233B | 233A |
| Input Select | 0A | X | X | X | 0A | X | X | X |
| 1359: {3, InD} | 0B | 0A | X | X | 0B | X | X | 0A |
| | 0C | 0B | 0A | X | 0C | X | 0A | 0B |
| P. Out 1332: | 0D | 0C | 0B | 0A | 0D | 0A | 0B | 0C |
| Input Select | X | 0A | X | X | X | 0A | X | X |
| 1359: {2, InC} | X | 0B | 0A | X | 0A | 0B | X | X |
| | X | 0C | 0B | 0A | 0B | 0C | X | 0A |
| P. Out 1332: | 0A | 0D | 0C | 0B | 0C | 0D | 0A | 0B |
| Input Select | X | X | 0A | X | X | X | 0A | X |
| 1359: {1, InB} | X | X | 0B | 0A | X | 0A | 0B | X |
| | 0A | X | 0C | 0B | 0A | 0B | 0C | X |
| P. Out 1332: | 0B | 0A | 0D | 0C | 0B | 0C | 0D | 0A |
| Input Select | X | X | X | 0A | X | X | X | 0A |
| 1359: {0, InA} | 0A | X | X | 0B | X | X | 0A | 0B |
| | 0B | 0A | X | 0C | X | 0A | 0B | 0C |
| P. Out 1332: | 0C | 0B | 0A | 0D | 0A | 0B | 0C | 0D |

As illustrated, above, the format control signals 157 may be selected to generate parallel output 1332 in which the data unit 1312 has a parallel arrangement corresponding to any suitable data format 114. The data unit 1312 may be converted to: data format 114C (little endian with eight-bit atomic elements) by setting the shift control signal 457 to “1” (reverse direction 473B) and the input select signal to “0” (to route incoming data elements 113 to input 461A of SR 762A); data format 114D (little endian with 16-bit atomic elements) by setting the shift control signal to “0” and the input select signal to “1” (input 461B); data format 114E (middle endian) by setting the shift control signal 457 to “1” and the input select signal to “2” (input 461C); and so on. A NOP data format modification 155 may comprise format control signals 157 in which the shift control signal 457 is set to “0” and the input select signal is set to “3” (input 461D). Corresponding data format conversions 155 are illustrated in Table 11 below.

TABLE 11

| | | | Input Data Sequence |
|---|---|---|---|
| | 157 | | 242 in 114A |
| Data Format | Shift | Input | {0A, 0B, 0C, 0D} |
| Conversion | Ctrl. | Select | Parallel Data Output 1332 |
| 155 | 457 | 1359 | {233A, 233B, 233C, 233D} |
| 114A to 114A [NOP] | FWD | InD | {0A, 0B, 0C, 0D} |
| | 473A | 461D | |
| 114A to 114B [NOP] | FWD | InD | {0A, 0B, 0C, 0D} |
| | 473A | 461D | |
| 114A to 114C | REV | InA | {0D, 0C, 0B, 0A} |
| | 473B | 461A | |
| 114A to 114D | FWD | InB | {0C, 0D, 0A, 0B} |
| | 473A | 461B | |
| 114A to 114E | REV | InC | {0B, 0A, 0D, 0C} |
| | 473B | 461C | |
| 114 . . . to 114 . . . | . . . | . . . | Any sequence |
| | | | corresponding to any |
| | | | suitable data format |

Although particular non-limiting examples of data format modifications 155 and corresponding format control signals 157 are described herein, the disclosure is not limited in this regard and could be adapted to implement any suitable data format modification 155 (and corresponding format control signals 157) to convert the data unit 1312 from any suitable input data format 1314 to any suitable requested format 514. By way of further non-limiting example, Table 12 illustrates the state of respective outputs of the SR flip flops 762A-D in response to a data sequence 242 comprising the hexadecimal value “0x0A0B0C0D” in data format 114E using various different format control signals 157.

TABLE 12

| | Shift Control 457: | | | | Shift Control 457: | | | |
|---|---|---|---|---|---|---|---|---|
| | {0, FWD 473A} | | | | {1, REV 473B} | | | |
| | OutD | OutC | OutB | OutA | OutD | OutC | OutB | OutA |
| | 233D | 233C | 233B | 233A | 233D | 233C | 233B | 233A |
| Input Select | 0B | X | X | X | 0B | X | X | X |
| 1359: {3, InD} | 0A | 0B | X | X | 0A | X | X | 0B |
| | 0D | 0A | 0B | X | 0D | X | 0B | 0A |
| P. Out 1332: | 0C | 0D | 0A | 0B | 0C | 0B | 0A | 0D |
| Input Select | X | 0B | X | X | X | 0B | X | X |
| 1359: {2, InC} | X | 0A | 0B | X | 0B | 0A | X | X |
| | X | 0D | 0A | 0B | 0A | 0D | X | 0B |
| P. Out 1332: | 0B | 0C | 0D | 0A | 0D | 0C | 0B | 0A |
| Input Select | X | X | 0B | X | X | X | 0B | X |
| 1359: {1, InB} | X | X | 0A | 0B | X | 0B | 0A | X |
| | 0B | X | 0D | 0A | 0B | 0A | 0D | X |
| P. Out 1332: | 0A | 0B | 0C | 0D | 0A | 0D | 0C | 0B |
| Input Select | X | X | X | 0B | X | X | X | 0B |
| 1359: {0, InA} | 0B | X | X | 0A | X | X | 0B | 0A |
| | 0A | 0B | X | 0D | X | 0B | 0A | 0D |
| P. Out 1332: | 0D | 0A | 0B | 0C | 0B | 0A | 0D | 0C |

As illustrated above, a data sequence 242 in data format 114E may be converted to parallel data 232 in any suitable data format 114 by use of the parallelization circuitry 1355 (and format control signals 157). A data sequence 242 may be converted from data format 114E to: data format 114A and/or 114B by setting the input select signal 1359 to 461C and the shift control signal 457 to the reverse direction 473B; data format 114C by setting the input select signal 1359 to 461B and the shift control signal 457 to the forward direction 473A; data format 114D by setting the input select signal 1359 to 461A and the shift control signal to the reverse direction 473B; and data format 114E by setting the input select signal 1359 to 461D and the shift control signal 457 to the forward direction 473A (per the NOP data format modification 155, disclosed above). Corresponding data format conversions 155 are provided in Table 13 below.

TABLE 13

| | | | Input Data Sequence |
|---|---|---|---|
| | 157 | | 242 in 114E |
| Data Format | Shift | Input | {0B, 0A, 0D, 0C} |
| Conversion | Ctrl. | Select | Parallel Data Output 1332 |
| 155 | 457 | 1359 | {233A, 233B, 233C, 233D} |
| 114E to 114A | REV | InC | {0A, 0B, 0C, 0D} |
| | 473B | 461C | |
| 114E to 114B | REV | InC | {0A, 0B, 0C, 0D} |
| | 473B | 461C | |
| 114E to 114C | FWD | InB | {0D, 0C, 0B, 0A} |
| | 473A | 461B | |
| 114E to 114D | REV | InA | {0C, 0D, 0A, 0B} |
| | 473B | 461A | |
| 114E to 114E [NOP] | FWD | InD | {0B, 0A, 0D, 0C} |
| | 473A | 461D | |
| 114 . . . to 114 . . . | . . . | . . . | Any sequence |
| | | | corresponding to any |
| | | | suitable data format |

As disclosed above, the data format conversions 155 of Tables 11 and/or 13 may be maintained in the parallelization circuitry 1355, format conversion logic 152, a library 555, logic element(s), circuit(s), configuration data, firmware, non-transitory storage, and/or the like. The format conversion logic 152 may select suitable data format conversions 155 based on the input format 1314 and requested format 514 determined for particular parallelization operations. The format conversion logic 152 may assert corresponding format control signals 157, which may configure the parallelization circuitry 1355 to implement data format modifications while the parallelization operations are performed (e.g., while producing parallel data outputs 1332 corresponding to the data sequences 242). As disclosed above, parallelizing a data sequence 242 may comprise a) receiving data elements 113 in sequence (responsive to a clock signal, such as SCLK), b) routing the received data elements 113 to a selected input 461A-D of the shift circuitry 772 (per the input select signal 1359), c) circularly shifting the data elements 113 within the shift circuitry 772 (responsive to the SCLK signal and in a selected direction 473A or 473B), and d) forming a parallel data output 1332 from the contents of the shift circuitry 772 (e.g., from the contents of the respective SR flip flops 762A-D, each SR flip flop 762A-D corresponding to a respective parallel data position 233A-D and/or parallel data channel 533A-D). The format control signals 157 may remain constant during respective parallelization operations (e.g., during parallelization of a particular data sequence 242 both the shift control signal 457 and input select signal remain unchanged). Maintaining the format control signals 457 unchanged while data units 112 are parallelized may reduce power consumption and/or logic delays within the parallelization circuitry 1355 since, inter alia, the input selection logic 1374 and/or shift circuitry 772 switch state, at most, once per parallelization operation (at the rate of PCLK), as opposed to being modified at the higher rate of SCLK.

The parallelization circuitry 1355 may be used to implement the parallelization circuitry 1155 of FIG. 11 (and/or portions thereof). In some embodiments, the parallelization circuitry 1355 of FIG. 13 may be implemented with serialization circuitry 450 (not shown in FIG. 13 to avoid obscuring the details of the illustrated embodiments). The parallelization circuitry 1355 may comprise shared and/or common circuitry that embodies portions of both the parallelization circuitry 1355 and serialization circuitry 450. Such shared and/or common circuitry may include, but is not limited to: storage elements (e.g., the SR flip flops 762), shift logic 772 (e.g., SR flip flops 762A-D in the circular, reversible sequence 763 disclosed above), selection circuitry (e.g., selection circuitry 574 and/or input selection circuity 1354), format conversion logic 152, and so on. The parallelization circuitry 1355 may use the shared and/or common circuitry to perform parallelization operations when the adaptive parallel-serial converter 150 is configured to operate in parallelization mode, and the serialization circuitry 450 may use the shared and/or common circuitry to perform serialization operations when the adaptive parallel-serial converter 150 is configured to operate in serialization mode. The use of shared and/or common circuitry may further reduce power consumption and size requirements of the adaptive parallel-serial converter 150.

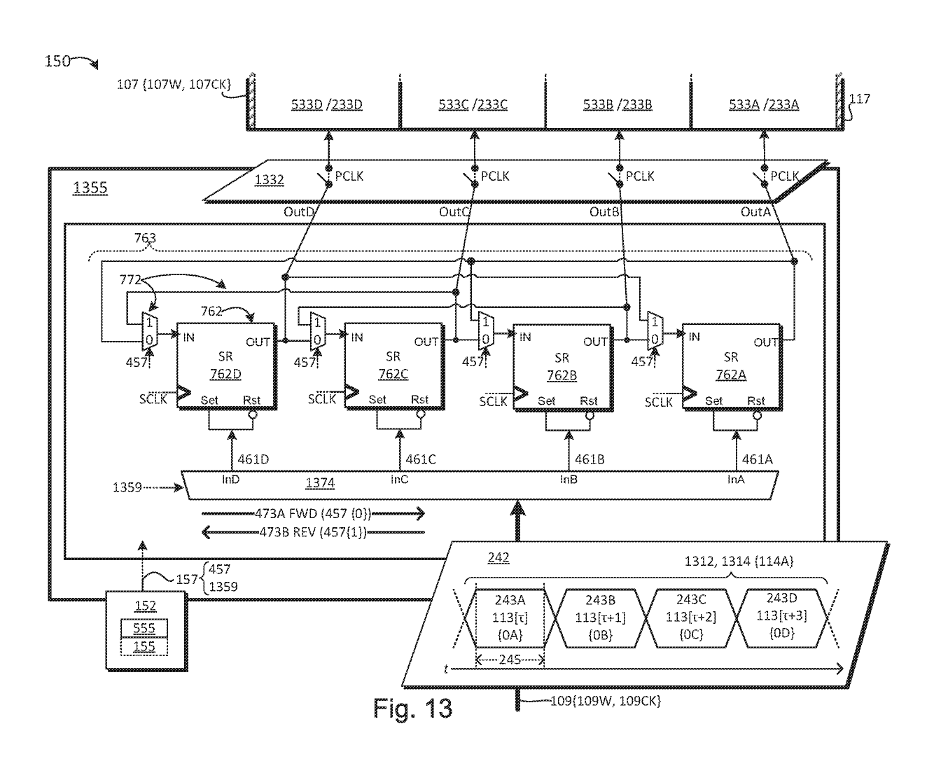

FIG. 14 is a flow diagram of one embodiment of a method 1400 for modifying the data format 114 of a data unit 112 while converting the data unit 112 (e.g., serializing the data unit 112 and/or parallelizing the data unit 112). The steps of method 1400 (and the other methods disclosed herein) may be implemented by use of the adaptive parallel-serial converter 150, serialization circuitry 450, parallelization circuitry 1255 and/or 1355, portions thereof, and/or the like, as disclosed herein. The steps of method 1400 (and the other methods disclosed herein) may, therefore, be implemented by use of hardware components, such as circuitry, logic circuitry, circuit elements, programmable logic, and/or the like. Alternatively, or in addition, steps of the method 1400 (and the other methods disclosed herein) may be implemented by use of instructions stored on a non-transitory storage medium. The instructions may be configured to cause processing logic to implement the disclosed steps (and/or portions thereof).

Step 1410 may comprise receiving a data unit 112 having a particular data format 114. Step 1410 may comprise receiving one of parallel data 232 and a data sequence 242. Receiving parallel data 232 may comprise one or more of: reading the data unit 112 from a memory 120, receiving the data unit 112 via a parallel data bus (e.g., the first data bus 107 and/or first interconnect 117), and/or the like. Receiving a data sequence 242 may comprise receiving a sequence of data elements 113 via a bus (e.g., the second data bus 109 and/or second interconnect 117) during respective sequential communication periods 245, and/or the like.

Step 1420 may comprise selecting and/or identifying a data format modification 155 to implement during conversion of the data unit 112 (e.g., while serializing or parallelizing the data unit 112). Step 1420 may comprise determining an input format 414 of the data unit 112, as disclosed herein. Determining the input format 414 of the data unit 112 may comprise one or more of: receiving information pertaining to the input format 414 of the data unit 112 (e.g., receiving input 451), accessing data format metadata 522 pertaining to data units 112 stored in a memory 120, accessing information pertaining to the input format 414 within the parallel data 232 comprising the data unit 112 (or the data sequence 242 comprising the data unit 112), accessing information pertaining to the input format 414 on a data bus, channel and/or interconnect, and/or the like. Step 1420 may further comprise determining a requested format 514 for the data unit 112. The requested format 514 may be determined from a request pertaining to the data unit 112 (e.g., a read request), data format metadata 522 pertaining to a computing device 103, a setting and/or parameter, and/or the like. Step 1420 may further comprise comparing the input format 414 to the requested format 514 to determine whether the input format 414 is compatible with the requested format 514. Step 1420 may further comprise selecting a data format modification 155 to modify the input format 414 to the requested format 514. The selected data format modification 155 may, therefore, be based on a comparison between the input format 414 and the requested format 514. The selected data format modification 155 may be configured to reformat the data unit 112 from the input format 414 to the requested format 514 while the data unit 112 is being converted (e.g., serialized or parallelized).

Step 1420 may comprise identifying a data format modification 155 in a look-up table, firmware, storage, a register, selection logic, and/or the like. The selected data format modification 155 may be configured to reformat the data unit 112 from the input format 414 to the requested format 514 while the data unit 112 is being converted. The input format 414 may correspond to a first data format and/or first endianness of the data unit 112 (as received at step 1410), and the requested format 514 may correspond to a second, different data format and/or endianness for the data unit 112 (as output as a data sequence 242 and/or parallel data 232). In some embodiments, the data format modification 155 selected at step 1420 may be configured to produce a data sequence 242 from parallel data 232 in which the data unit 112 is arranged in parallel according to the first data format and/or endianness, such that the data elements 113 of the data unit 112 have a sequential arrangement and/or serial ordering that corresponds to the second format and/or endianness for the data unit 112. Alternatively, or in addition, the data format modification 155 selected at step 1420 may be configured to produce parallel data 232 (e.g., a parallel data output 1332) in which data elements 113 have a sequential ordering corresponding to the first data format 114 and are arranged in parallel in accordance with the second data format 114. In some embodiments, step 1420 may comprise selecting a NOP data format modification 155 in response to determining that the input format 414 of the data unit 112 is compatible with the requested format 514. The NOP data format modification 155 may be configured to retain the original, input format 414 of the data unit 112, such that the serial arrangement of the data unit 112 in the data sequence 242 corresponds to the original, input format 414 (and/or the parallel arrangement of the data unit 112 in the parallel data 232 corresponds to the original, input format 414).

Step 1430 may comprise implementing the selected data format modification 155 while converting the data unit 112 (e.g., serializing the data unit 112 or parallelizing the data unit 112). Step 1430 may comprise implementing the selected data format modification 155 while serializing parallel data 232 (e.g., while producing a data sequence 242 from parallel data 232 comprising the data unit 112). Alternatively, step 1430 may comprise implementing the selected data format modification 155 while parallelizing a data sequence 242 (e.g., while generating a parallel data output 1332 from a data sequence comprising the data unit 112).

Serializing the data unit 112 may comprise: a) receiving parallel data 232 comprising the data unit 112, b) latching and/or buffering the data elements 113 of the data unit 112, c) circularly shifting the data elements 113 in either a forward direction 473A or a reverse direction 473B during a plurality of serialization cycles, and d) outputting a selected data element 113 of the data unit 112 during each serialization cycle. The serialization cycles may correspond to a clock signal, such as the clock signal 109CK of the second data bus 109, a serial clock signal (SCLK), and/or the like (e.g., may correspond to sequential communication periods 245, as disclosed herein). Parallelizing the data unit 112 may comprise: a) receiving a data sequence 242 comprising the data unit 112 (e.g., receiving data elements 113 of the data unit 112 during respective sequential communication periods 245), b) routing the incoming data elements to a selected storage element (e.g., a selected SR flip flop 762), c) circularly shifting the data elements 113 in one of the forward 473A and reverse 473B directions, and d) producing a parallel data output 1332 comprising a parallel arrangement of the data elements 113 of the data unit 112.

The selected shift direction, output selection, and/or input selection may correspond to format control signals 457 of the selected data format modification 155. Step 1430 may comprise generating format control signals 457 to configure a buffer 452, shift register circuitry 552, reversible, circular shift circuitry 652, shift circuitry 772, and/or register circuitry 852 to shift data elements 113 and/or data value(s) of the data elements in direction 473A or 473B, as disclosed herein (e.g., by use of shift circuitry 472, 572, 672, routing circuitry 772, and/or the like). Step 1430 may further comprise generating an output select signal 459 to select an output of a particular shift buffer 462, register 562, shift register 662, SR flip flop 762, and/or reversible latch 862 or 962, to form the data sequence 242, as disclosed herein. Alternatively, step 1430 may comprise generating an input select signal 1359 to route an incoming data element 113 to a selected buffer location (e.g., a selected SR flip flop 762A-D). The shift and/or select operations of step 1430 may be configured to produce one or more of a data sequence 242 and parallel data 232 in which data elements 113 of the data unit 112 are arranged in accordance with the requested format 514 (e.g., in which the sequential order of the data elements 113 and/or parallel arrangement of the data elements 113 corresponds to the requested format 514).

Serializing the data unit 112 at step 1430 may comprise latching each of N data elements 113 of the data unit 112 into N shift buffers, each shift buffer being configured to hold a data element 113 (e.g., an eight-bit data value). Step 1430 may further comprise shifting the data elements between the shift buffers during each of N serialization cycle in either direction 473A or direction 473B (in accordance with a shift control signal 457). Step 1430 may further comprise selecting one of the N shift buffers to produce the data sequence 242, such that a data element 113 held within the selected shift buffer comprises a different data element 113 of the data element 113 during each of the N serialization cycles. The data elements 113 of the data unit 112 may, therefore, be arranged in respective ones of N sequential data positions 233, each sequential data position 233 corresponding to a respective one of the N serialization cycles. The shift and select operations of step 1430 may result in a data sequence 242 in which data elements 113 of the data unit 112 are output in a sequential arrangement that corresponds to the requested format 514.

In another embodiment, serializing the data unit 112 at step 1430 may comprise latching each data value of the data unit 112 into respective serialization circuits (e.g., serialization circuits 550). Each serialization circuit may be configured to latch a particular data value of each of the N data elements 113 of the data unit 112. Each of the N data elements 113 may correspond to a respective parallel data position 233A-N within the parallel data 232. Step 1430 may comprise latching data value (0) at each of N parallel data positons 233A-N into serialization circuit (0), latching data value (1) at each of N parallel data positions 233A-N into serialization circuit (1), and so on, with each data value (M) at each of N parallel data positions 233A-N being latched into serialization circuit (M), where M corresponds to the size of the data elements 113 (e.g., with M being 7 for eight-bit data elements 113). Step 1430 may include selecting a) a shift direction 473A or 473B for the serialization circuits, and b) selecting an output from each of the serialization circuits (by use of format control signals 157, as disclosed herein). Step 1430 may further comprise shifting data within serialization circuitry 450 in the selected shift direction (direction 473A or 473B), and using the data value outputs of the serialization circuits to produce the data sequence 242.

Parallelizing the data unit 112 at step 1430 may comprise receiving a respective data element 113 of the data unit 112 during each of a plurality of sequential communication periods 245, such that the data elements 113 are received in a sequential order that corresponds to the input data format 414 of the data unit 112. Step 1430 may further comprise a) routing the data elements 113 to one of a plurality of buffer locations (e.g., SR flip flops 762A-D) based on format control signals of the selected data format modification 155 (e.g., input select signal 1359), b) shifting the data elements 113 in a selected shift direction (e.g., by use of shift circuitry 772 and/or in accordance with a shift control signal 457), and c) generating parallel data output 1332 comprising the data unit 112 by combining outputs of the respective buffers (e.g., SR flip flops 762A-D). The selecting routing, shifting, and combining of step 1430 may result in producing parallel data output 1332 in which the data elements 113 of the data unit 112 have a parallel arrangement that corresponds to the requested format 514 (and is modified relative to a parallel arrangement corresponding to the input format 414).

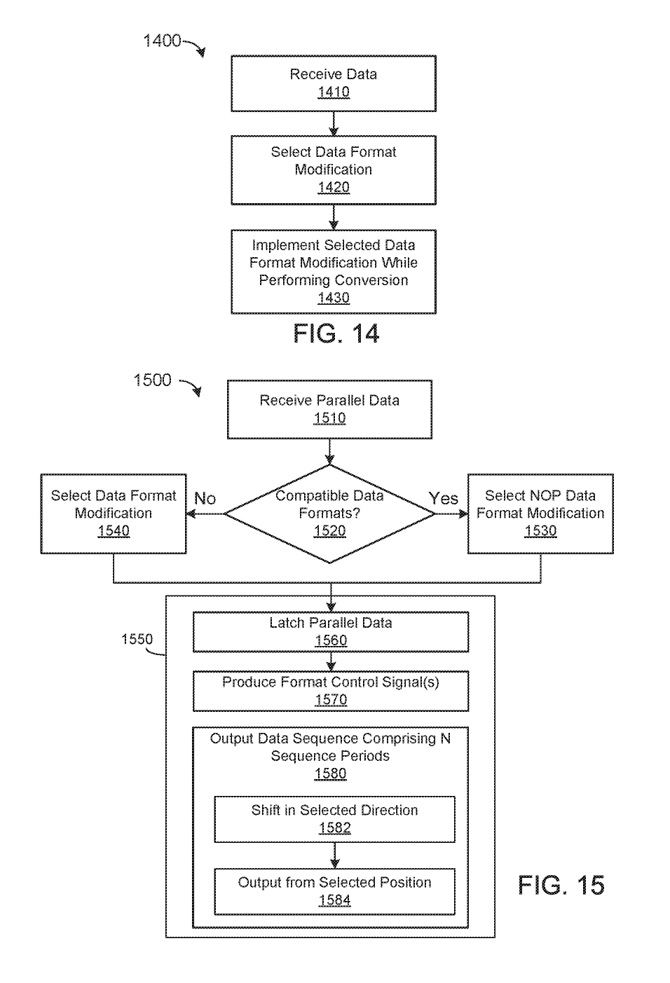

FIG. 15 is a flow diagram of one embodiment of a method for modifying the data format of a data unit 112 while serializing the data unit 112. Step 1510 may comprise receiving parallel data 232 comprising a data unit 112, as disclosed herein. Step 1510 may comprise receiving a communication control signal via one or more of the parallel bus interface 607 and/or serial bus interface 509 of the adaptive parallel-serial converter 150. The communication control signal may indicate that parallel data 232 is being communicated via the first data bus 107. In response, the adaptive parallel-serial converter 150 may select the serialization operating mode by, inter alia, asserting corresponding mode control signals 1101, as disclosed herein. Step 1510 may further comprise receiving the parallel data 232 via the first data bus 107 and responsive to a parallel clock signal (PCLK), such as the clock signal 107CK.

Step 1520 may comprise determining whether an input format 414 of the data unit 112 is compatible with a requested format 514. Step 1520 may comprise determining the input format 414 and the requested format 514 and/or comparing the input format 414 to the requested format 514, as disclosed herein. If the input format 414 is compatible with the requested format 514, the flow may continue to step 1530. Otherwise, the flow may continue at step 1540.

Step 1530 may comprise selecting a NOP data format modification 155 to implement while serializing the data unit 112. As disclosed herein, the NOP data format modification 155 may be configured such that the sequential arrangement of the data unit 112 in the data sequence 242 produced in the method 1500 is the same as the original input format 414 of the data unit 112 (e.g., corresponds to the parallel data arrangement of the data unit 112 in the parallel data 232).

Step 1540 comprises selecting a data format modification 155 to modify the data format 114 of the data unit 112 during serialization of the data unit. The data format modification 155 may be configured to modify the sequential arrangement of the data unit 112 in the data sequence 242. The modifications may be configured to convert the data unit 112 from the parallel data arrangement corresponding to the input format 414 to a sequential data arrangement corresponding to the requested format 514. Steps 1530 and 1540 may comprise selecting a data format modification 155 from a table, look-up logic, library 555, and/or the like, as disclosed herein.

Step 1550 may comprise serializing the data unit 112 while implementing the data format modification 155 selected at steps 1520-1540. Step 1560 may comprise latching data of the data unit 112 into shift circuitry. Step 1560 may comprise routing data values of each of N data elements 113 of the data unit 112 into a respective serialization circuit. Step 1560 may comprise latching data values of each of the N data elements 113 into a respective one of N shift buffers 462, each of the N shift buffers 462 configured to hold a respective one of the data elements 113 (e.g., hold a respective multi-bit data value). Each of the shift buffers 462 may be comprised of a plurality of data storage, register, latch, and/or buffer circuits.

Alternatively, or in addition, step 1560 may comprise latching respective bits of each of N data elements 113 into each of M serialization circuits (e.g., serialization circuits 550[0] through 550[M]). Each of the serialization circuits 550 may be configured to serialize one of M data values of the N data elements 113. A serialization circuit (0) may be configured to latch data value (0) at each parallel data position 233A-N, a serialization circuit (1) may be configured to latch data value (1) at each parallel data position 233A-N, and so on, with a serialization circuit (M) latching data value (M) at each parallel data position 233A-N.

Step 1570 may comprise generating format command signals 157 for use in producing the data sequence 242. The format command signals 157 may correspond to the data format modification 155 selected at steps 1520-1540. Format command signals 157 for the NOP data format modification 155 (selected at step 1430) may be configured to output the data unit 112 in the data sequence 242 such that data of the data unit 112 is in a sequential arrangement that corresponds to the original, input format 414 of the data unit 112. The format command signals 157 may configure the shift buffers 462 and/or serialization circuits 550 to shift data of the data unit 112 in the forward direction 473A and/or select the serialization circuit corresponding to parallel data position 233A (and/or 233[0] through 233[M]) to produce the data sequence 242. Format command signals 157 configured to reformat the data unit 112 in the data sequence 242 may cause the serialization circuitry 550 to a) shift data in the reverse direction 473B and/or b) select a register 562, 662, SR flip flop 772, and/or reversible latch 862/962 corresponding to a parallel data position other than parallel data position 233A to produce the data sequence(s) 242[0] through 242[M].

Step 1580 may comprise generating a data sequence 242 comprising the data unit 112. Step 1580 may comprise N sequence periods, with a respective data element 113 of the data unit 112 being output during each of the N sequence periods. The sequence periods may correspond to a clock signal, such as the clock signal 109CK of the second data bus 109, a serial clock SCLK, and/or the like. The disclosure is not limited to generating a data sequence 242 comprising respective data elements 113. In other embodiments, step 1580 may comprise generating a data sequence 242 comprising N/W sequence periods, where W is a number of data elements 113 capable of being communicated in parallel on the second data bus 109 (e.g., in accordance with the width 109W of the second data bus 109). In some embodiments, W may be less than one. For example, each data element 113 may comprise an eight-bit value, and the second data bus 109 may be limited to transmitting a single bit value during each sequence period. In this embodiment, step 1580 may comprise generating a data sequence 242 comprising 8*N sequence periods. During each of the sequence periods, the method 1500 may comprise shifting the data latched in the shift buffers 462 and/or serialization circuits in accordance with the shift control signal 457 in step 1582 (towards the designated output location in either the forward direction 473A or reverse direction 473B), and generating the data sequence 242 for the sequence period in accordance with the output select signal 459 in step 1584. The shift and select operations performed during each of the N sequence periods (steps 1580-1584) may be configured to arrange the data elements 113 in a sequential arrangement that corresponds to the requested format 514 (e.g., converts the parallel data in the input format 414 into a data sequence 242 arranged in accordance with the requested format 514).

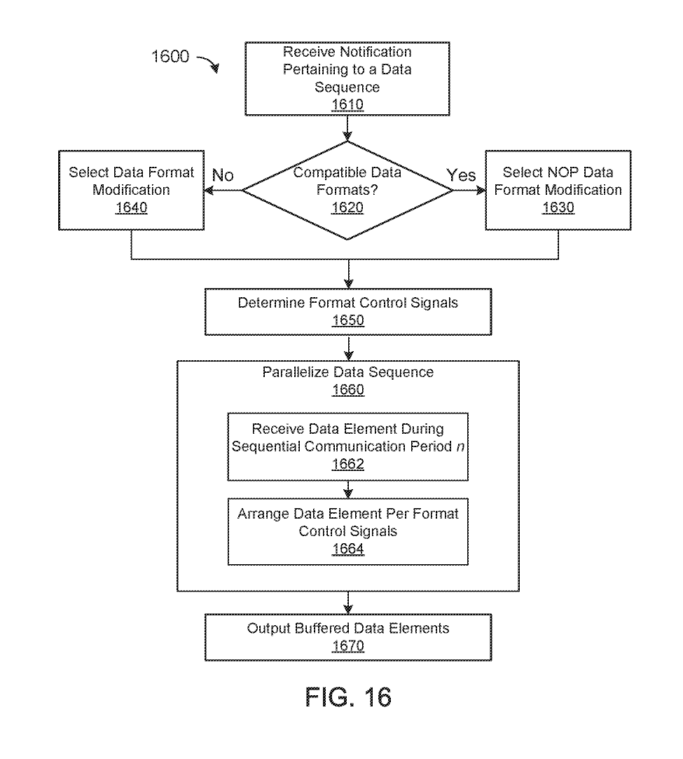

FIG. 16 is a flow diagram of one embodiment of a method 1600 for modifying the data format 114 of a data unit 112 while parallelizing a data sequence 242 comprising the data unit 112. Step 1610 may comprise receiving a notification pertaining to a data sequence 242. The notification of step 1610 may comprise an indication that a data unit 112 is to be communicated as a data sequence 242. Step 1610 may comprise receiving communication control signal(s) via one or more of a serial bus interface 509 and/or parallel bus interface 607 of an adaptive parallel-serial converter 160, as disclosed herein. Step 1610 may comprise selecting the operating mode for the adaptive parallel-serial converter 150 to a parallelization mode (using mode control signal 1101), as disclosed herein.

Step 1620 may comprise determining whether an input data format 414 of the data unit 112 (as arranged in the data sequence 242) is compatible with a requested format 514 for the data unit 112. Step 1620 may comprise determining the sequential data format 414, determining the requested format 514, and/or comparing the input format 414 to the requested format 514, as disclosed herein. If the input format 414 is compatible with the requested format 514, the flow may continue to step 1630. Otherwise, the flow may continue to step 1640.

Steps 1630 and 1640 may comprise selecting a data format modification 155 to implement during parallelization of the data unit 112 (while converting the data sequence 242 comprising the data unit 112 to parallel data 232). Step 1630 may comprise selecting a NOP data format modification 155 (in response to determining that the requested format 514 is compatible with the input format 414). Step 1640 may comprise selecting a data format modification 155 configured to convert the data unit 112 from the input format 414 to the requested data format 514. The data format modification 155 selected at step 1640 may be configured to convert data elements 113 having a sequential order corresponding to the input format 414 into parallel data 232 in which the data elements are arranged in accordance with the different requested data format 514 (such that the parallel arrangement of the data unit 112 in the parallel data 232 differs from a parallel arrangement corresponding to the original, input format 414 of the data unit 112). Step 1630 and/or 1640 may comprise accessing a library 555, implementing look-up and/or state machine logic, and/or the like, as disclosed herein.

Step 1650 may comprise determining format control signals 157 to implement the data format modification 155 of step 1630 or 1640. In one embodiment, step 1650 may comprise determining a set of routing control signals 1259, which may be configured to buffer data elements 113 received during each of N sequential communication periods 245 at a selected parallel data position 233. The set of routing control signals 1259 may include N signals, each of the N signals to select one of a plurality of registers 1262. The routing control signals 1259 may determine a parallel arrangement of the data elements 113 and, as such, may implement any-to-any data format conversions (e.g., as illustrated in Tables 8 and 9 above). Alternatively, or in addition, step 1650 may comprise determining one or more of a shift control signal 457 and input select signal 1359. The shift control signal 457 may determine a shift direction of shift circuitry 772 of the parallelization circuitry 1355 and the input select signal 1359 may configure input select circuitry 1374 to route data elements 113 of the data sequence 242 to a designated storage location (e.g., SR flip flop 762A-D).

Step 1660 may comprise parallelizing the data sequence 242 by use of the format control signals of step 1650. Step 1660 may comprise receiving a plurality of data elements 113, each data element 113 being received during a respective sequential communication period 245 (e.g., in response to a clock signal, such as SCLK). The data elements 113 may be received via a serial communication channel, such as the second data bus 109 and/or second interconnect 119.

Step 1662 may comprise receiving a data element 113 of the data sequence 242 during a particular sequential communication period 245 (e.g., sequential communication period n). Step 1664 may comprise arranging the data element 113 per the format control signals of step 1650 (in accordance with the selected data format modification 155).

In some embodiment, arranging the data elements 113 at step 1664 may comprise routing the data elements 113 to selected parallel data positions 233 within buffer circuitry 1252 of the parallelization circuitry 1255 illustrated in FIG. 12. In these embodiments, step 1664 may comprise routing data elements 113 to one of a plurality of registers 1262A-D of the parallelization circuitry 1255 based on, inter alia, the routing control signal 1259 applied to the routing circuitry 1254 during particular sequential communication periods 245. As disclosed above, the routing control signals 1259 may be configured to modify the data format 114 of the data unit 112 during parallelization, such that the parallel arrangement of the data elements 113 buffered during steps 1660, 1662, and 1664 is modified from the original, input format 414 of the data unit 112 (as communicated in the data sequence 242) to parallel data 232 comprising the data unit 112 in the requested format 514.

In other embodiments, arranging the data elements at step 1664 may comprise routing the data elements 113 to a selected storage location by use of input select circuitry 1374 (and input select signal 1359) of the parallelization circuitry 1355 illustrated in FIG. 13. Step 1664 may further comprise shifting data elements 113 within the parallelization circuitry 1355 by use of shift circuitry 772 (and in response to the SCLK signal). The data elements 113 may be shifted in one of a forward direction 473A and reverse direction 473B based on the state of the shift control signal 457. The input select signal 1359 and shift control signal 457 of the parallelization circuitry 1355 may remain constant during parallelization of the data unit 112.

After each of the N data elements 113 have been received and arranged at steps 1660-1664, the flow may continue to step 1670. Step 1670 may comprise outputting the parallel data 232 comprising the data unit 212 (e.g., generating parallel data output 1332 comprising the data unit 112). Step 1670 may comprise outputting parallel data 232 comprising the data unit 112 in a parallel arrangement that corresponds to the requested format 514 (e.g., such that parallel data positions 233 of the data elements 113 of the data unit 112 correspond to the requested format 514). Step 1670 may further comprise communicating the parallel data 232 on the first data bus 107 and/or first interconnect 117, as disclosed herein.

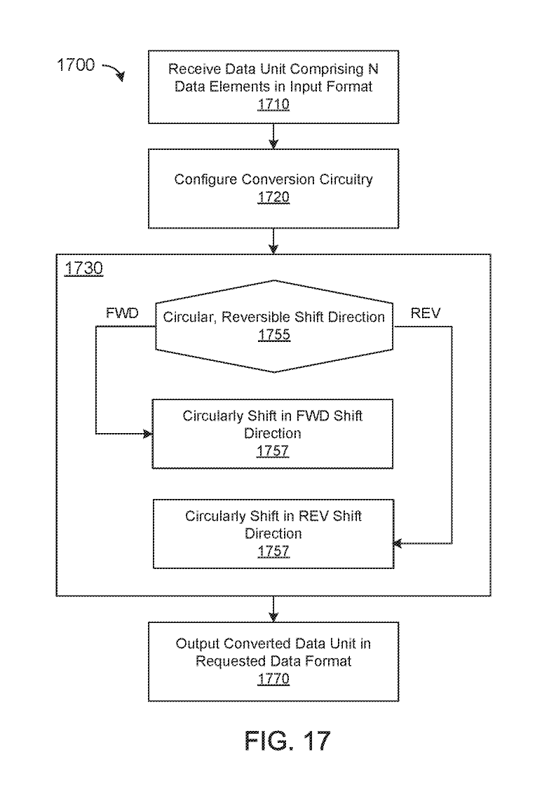

FIG. 17 is a flow diagram of another embodiment of a method for implementing data format modifications while performing parallel-to-serial and/or serial-to-parallel conversions (e.g., by use of embodiments of the adaptive parallel-serial converter 150 disclosed herein).

Step 1710 may comprise receiving input data comprising a data unit 112. The data input 112 may comprise N data elements 113. The data unit 112 may be in a particular data format 114 (e.g., input format 414). The data unit 112 may be received as one or more of parallel data 232, a data sequence 242, and/or the like. When received as parallel data 232 (e.g., read from memory storage and/or communicated in parallel via a data bus), the N data elements 113 of the data unit 112 may have a parallel arrangement corresponding to the input format 414. When received as a data sequence 242, the N data elements 113 may ordered in accordance with the input data format 414 (e.g., each of the N data elements 113 may be communicated during a respective sequential communication period 245 in accordance with the input format 414).

Step 1720 may comprise configuring conversion circuitry to implement a selected data format conversion while performing one or more of a parallel-to-serial conversion and a serial-to-parallel conversion. Step 1720 may comprise selecting a data format modification 155 to convert the data unit 112 from the input format 414 to a requested format 514, as disclosed herein. Step 1720 may further comprise determining one or more of: shift control signal, and output select signal 459, an input select signal 1359, and/or the like, as disclosed herein. The shift control signal may configure circular, reversible shift circuitry of the adaptive parallel-serial converter 150 to circularly shift the N data elements 113 of the data unit 112 in one of a forward shift direction 473A and a reverse shift direction 473B. The output select signal 459 may configure the adaptive parallel-serial converter 150 form an output data sequence 242 from data at a selected location within the circular, reversible shift circuitry (when performing a parallel-to-serial conversion of the data unit 112). The input select signal 1359 may configure the adaptive parallel-serial converter 150 to route data elements 113, of the N data elements 113, to a selected location within the circular, reversible shift circuitry (when performing a serial-to-parallel conversion of the data unit 112). The control signals of step 1720 may remain constant during conversion of the data unit 112.

Step 1730 may comprise implementing the selected data format conversion of step 1720 while performing one of a parallel-to-serial conversion and a serial-to-parallel conversion. Step 1730 may comprise circularly shifting data elements 113, of the N data elements 113 comprising the data unit 112, within a circular, reversible shift circuit of the adaptive parallel-serial converter 150. When performing a parallel-to-serial conversion, step 1730 may comprise latching data elements 113 at respective parallel data positions 233 of input parallel data 232 into respective locations within the circular, reversible shift circuit, and forming an output data sequence 242 as the data elements 113 shifted through a selected location within the circular, reversible shift circuit. When performing a serial-to-parallel conversion, step 1730 may comprise routing data elements 113 of an input data sequence 242 to a selected location within the circular, reversible shift circuitry (based on the input select signal 1359 determined at step 1720), and forming a parallel data output 232 from the contents of the circular, reversible shift circuitry. Step 1755 may comprise determining whether to shift the circular, reversible shift circuitry in the forward shift direction 473A or the reverse shift direction 473B (in accordance with the shift control signal 457 determined at step 1720). When the shift control signal 457 is FWD, step 1730 comprises circularly shifting in the forward shift direction 473A at step 1757. When the shift control signal 457 is REV, step 1730 comprises circularly shifting in the reverse shift direction 473B at step 1759. Performing conversion may comprise performing N (or more) shift iterations on the circular, reversible shift circuit. Each shift iteration may be performed in the same shift direction throughout the conversion (as determined at step 1720 by, inter alia, the shift control signal 457).

Step 1770 may comprise producing an output comprising the data unit 112. The data unit 112 may be embodied as one of parallel data 232 (when performing a serial-to-parallel conversion) and a data sequence 242 (when performing a parallel-to-serial conversion). Parallel data 232 comprising the data unit 112 may comprise each of the N data elements 113 at parallel data positions 233 corresponding to the requested format 514. A data sequence comprising the data unit 112 may comprise an ordered sequence of the N data elements 113, wherein the N data elements 113 are ordered in accordance with the requested format 514. The data elements 113 of the data sequence 242 may be formed from the contents of a selected position within the circular, reversible shift circuit (e.g., by use of the output select signal 459 determined at step 1720).

This disclosure has been made with reference to various exemplary embodiments. However, those skilled in the art will recognize that changes and modifications may be made to the exemplary embodiments without departing from the scope of the present disclosure. For example, various operational steps, as well as components for carrying out operational steps, may be implemented in alternative ways depending upon the particular application or in consideration of any number of cost functions associated with the operation of the system (e.g., one or more of the steps may be deleted, modified, or combined with other steps). Therefore, this disclosure is to be regarded in an illustrative rather than a restrictive sense, and all such modifications are intended to be included within the scope thereof. Likewise, benefits, other advantages, and solutions to problems have been described above with regard to various embodiments. However, benefits, advantages, solutions to problems, and any element(s) that may cause any benefit, advantage, or solution to occur or become more pronounced are not to be construed as a critical, a required, or an essential feature or element. As used herein, the terms “comprises,” “comprising,” and any other variation thereof are intended to cover a non-exclusive inclusion, such that a process, a method, an article, or an apparatus that comprises a list of elements does not include only those elements but may include other elements not expressly listed or inherent to such process, method, system, article, or apparatus. Also, as used herein, the terms “coupled,” “coupling,” and any other variation thereof are intended to cover a physical connection, an electrical connection, a magnetic connection, an optical connection, a communicative connection, a functional connection, and/or any other connection.

Additionally, as will be appreciated by one of ordinary skill in the art, principles of the present disclosure may be reflected in a computer program product on a machine-readable storage medium having machine-readable program code means embodied in the storage medium. Any tangible, non-transitory machine-readable storage medium may be utilized, including magnetic storage devices (hard disks, floppy disks, and the like), optical storage devices (CD-ROMs, DVDs, Blu-ray discs, and the like), flash memory, and/or the like. These computer program instructions may be loaded onto a general purpose computer, special purpose computer, or other programmable data processing apparatus to produce a machine, such that the instructions that execute on the computer or other programmable data processing apparatus create means for implementing the functions specified. These computer program instructions may also be stored in a machine-readable memory that can direct a computer or other programmable data processing apparatus to function in a particular manner, such that the instructions stored in the machine-readable memory produce an article of manufacture, including implementing means that implement the function specified. The computer program instructions may also be loaded onto a computer or other programmable data processing apparatus to cause a series of operational steps to be performed on the computer or other programmable apparatus to produce a computer-implemented process, such that the instructions that execute on the computer or other programmable apparatus provide steps for implementing the functions specified.

While the principles of this disclosure have been shown in various embodiments, many modifications of structure, arrangements, proportions, elements, materials, and components that are particularly adapted for a specific environment and operating requirements may be used without departing from the principles and scope of this disclosure.

What is claimed is:

1. An apparatus, comprising:
a buffer configured to receive parallel data comprising a data unit, the data unit having a parallel arrangement that corresponds to a first data format for the data unit;
a serialization circuit configured to modify a format of the data unit concurrent with serializing the parallel data, wherein to serialize the parallel data, the serialization circuit is configured to output a data sequence, the data sequence comprising data of the data unit in a sequential order, and wherein to modify the format of the data unit concurrent with serializing the parallel data, the serialization circuit is configured to arrange the sequential order of the data of the data unit output by the serialization circuit to serialize the parallel data such that the sequential order of the data of the data unit in the data sequence corresponds to a second data format for the data unit, the second data format different from the first data format.

2. The apparatus of claim 1, wherein the first data format corresponds to a first endianness, and wherein the second data format corresponds to a second endianness, the second endianness different from the first endianness, and wherein the serialization circuit comprises:
a series of shift buffers configured to circularly shift data of the data unit in a selected shift direction in the series based on a shift control signal, wherein the selected direction is one of a forward direction and a reverse direction, wherein, to circularly shift data in the forward direction, a first shift buffer of the series is configured to shift data to a last shift buffer of the series, and wherein, to circularly shift data in the reverse direction, the last shift buffer is configured to shift data to the first shift buffer;
selection logic communicatively coupled to the shift buffers in the series and configured to select one of the shift buffers to output the data sequence based on an output select signal; and
format conversion logic configured to determine the shift control signal and the output select signal in response to comparing the first endianness to the second endianness.

3. The apparatus of claim 2, wherein the format conversion logic comprises a plurality of data format conversions, wherein each data format conversion is configured to modify the endianness of parallel data from an input endianness to a requested endianness concurrently with serializing the parallel data, and
wherein, to determine the shift control signal and the output select signal, the format conversion logic is configured to identify a data format conversion configured to modify the endianness of parallel data from the first endianness to the second endianness, and to determine the shift control signal and the output select signal based on the identified data format conversion.

4. The apparatus of claim 1, wherein the data unit comprises a plurality of data elements, wherein a first one of the data elements is a most significant data element of the data unit, wherein the most significant data element is to be output in a first sequential order in the data sequence in accordance with the first data format, and
wherein the serialization circuit is configured to output the first data element in a second sequential order in the data sequence while serializing the parallel data comprising the data unit, the second sequential order different from the first sequential order.

5. The apparatus of claim 1, wherein the data unit is stored within one or more memory cells of a non-volatile memory structure, and wherein the serialization circuit is embodied on the non-volatile memory structure.

6. The apparatus of claim 1, wherein the data unit is stored at one or more addresses of the non-volatile memory, the apparatus further comprising memory logic configured to determine that the data unit is stored within the one or more physical storage locations according to the first data format based on one or more of: metadata pertaining to the data unit stored within the non-volatile memory, a header of the data unit, configuration data, a register value, and a data format table.

7. The apparatus of claim 1, wherein the data unit is stored on a non-volatile storage medium, the apparatus further comprising a controller configured to receive a request to read the data unit, determine a requested data format for the data unit, and to instruct the serialization circuit to modify a format of the data unit in accordance with the requested data format.

8. The apparatus of claim 1, wherein the serialization circuit is configured to transmit data of the data sequence on a data bus during each of a plurality of communication periods, and wherein the sequential order of the data in the data sequence determines an order in which the data is transmitted on the data bus during the communication periods.

9. A method, comprising:
receiving a plurality of data elements of a data unit, wherein parallel data positions of the data elements corresponds to a first endianness for the data unit; and
performing a serialization operation configured to modify the endianness of the data while outputting the data elements of the data unit in a series, wherein performing the serialization operation comprises:
latching data of the data elements into respective flip flop circuits in a circular series of flip flop circuits, each flip flop circuit being communicatively coupled to output selection circuitry,
configuring the circular series of flip flop circuits to shift the data of the data elements in a determined shift direction during the serialization operation, the determined shift direction comprising one of a forward shift direction and a reverse shift direction,
configuring the output selection circuitry to a select a flip flop circuit of the circular series of flip flop circuits as an output flip flop for the serialization operation, the output flip flop circuit to output the data elements of the data unit in the series,
shifting data latched in circular series of flip flop circuits in the determined shift direction during each of a plurality of cycles of a clock signal, and
using the selection circuitry to output the data elements of the data unit from the output flip flop circuit such that each data element is output during a respective cycle of the clock signal, wherein an arrangement of the data elements in the series corresponds to a second endianness for the data unit, the second endianness different from the first endianness.

10. The method of claim 9, further comprising determining the shift direction for the serialization operation in response to comparing the first endianness to the second endianness, wherein configuring the circular series of flip flop circuits to shift the data of the data elements in the determined shift direction comprises generating a shift control signal for the flip flop signals.

11. The method of claim 9, further comprising selecting the output flip flop circuit for the serialization operation based on the parallel data positions of the data elements of the data unit, wherein the output selection circuitry comprises multiplexer circuitry, and wherein configuring the output selection circuitry comprises generating a selection control signal for the multiplexer circuitry.

12. The method of claim 9, further comprising selecting a data format conversion for the serialization operation from a plurality of data format conversions based on the first endianness and the second endianness, wherein the selected data format conversion specifies a shift direction and the output flip flop circuit for the serialization operation.

13. The method of claim 9, wherein the series of flip flop circuits comprises a first flip flop and a last flip flop, wherein inputs of each of the flip flops are selectively coupled to outputs of adjacent flip flops in the series, an input of the first flip flop being selectively coupled to an output of the last flip flop, and an input of the last flip flop being selectively coupled to an output of the first flip flop.

14. The method of claim 9, further comprising:
determining one or more of the first endianness of the data unit and the second endianness for the data unit; and
accessing a format conversion library to determine the shift direction and the output flip flop circuit for the serialization operation based on a comparison of the first endianness to the second endianness.

15. The method of claim 14, wherein the format conversion library comprises a plurality of data format conversions, each data format conversion configured to convert an input endianness to a requested endianness and comprising a respective shift direction and output location, the method further comprising identifying a data format conversion in the library configured to convert the first endianness to the second endianness, such that:
the determined shift direction for the serialization operation corresponds to the shift direction of the identified data format conversion, and
the selected output flip flop for the serialization operation corresponds to the output location of the identified data format conversion.

16. A circuit, comprising:
a plurality of data latches connected in sequence, wherein each data latch is configured to store a respective data bit of a data unit, the data unit having a parallel arrangement that corresponds to a first data format for the unit,
wherein the data latches comprise shift circuitry configured to shift the data bits stored therein to an adjacent data latch in the sequence in one of two or more shift directions responsive to a clock signal, the two or more shift directions comprising a forward shift direction and a reverse shift direction, wherein in the forward shift direction, a data bit stored in a first data latch of the sequence is shifted into a last data latch of the sequence, and wherein in the reverse shift direction a data bit stored in the last data latch is shifted into the first data latch;
selection circuitry configured to receive outputs of each of the data latches and to output data bits shifted through a selected one of the data latches in response to the clock signal to produce a sequence of data bits of the data unit; and
format control logic configured to control the shift direction of the shift circuitry and the data latch selected by the selection circuitry such that a sequential order of the data bits of the data unit in the sequence correspond to a second data format, the second data format different from the first data format.

17. The circuit of claim 16, wherein sequential positions of the data bits of the data units in the sequence produced on the selected data latch correspond to the second data format for the data unit.

18. The circuit of claim 16, wherein the data latches comprise reversible latches, and wherein the format control logic is configured to generate a reverse signal for the reversible latches, the reverse signal to control the shift direction of the reversible latches.

19. The circuit of claim 16, wherein the selection circuitry comprises a multiplexer, and wherein the format control logic is configured to generate a select control signal for the multiplexer.

20. The circuit of claim 16, wherein the format conversion logic is configured to determine the shift direction for the shift circuitry and to determine the data latch selected by the selection circuitry to produce the sequence of data bits in response to comparing the first data format to the second data format.

21. A system, comprising:
means for receiving parallel data, the parallel data comprising data elements of a data unit in a first data format; and
means for changing the data format of the data unit from the first data format to a second data format while the parallel data is converted into a data sequence comprising the data elements of the data unit, comprising:
means for circularly shifting the data elements of the data unit responsive to a clock signal, wherein the data elements are circularly shifted within a sequence of shift locations in one of two or more shift directions, including
a forward direction in which a data element at a last shift location of the sequence is shifted towards first shift location of the sequence and a data element at the first shift location is shifted to the last shift location, and
a reverse direction in which the data element at the first shift location is shifted towards the last shift location and the data element at the last shift location is shifted to the first shift location,
means for generating the data sequence to serialize the parallel data comprising the data unit by outputting a data element at a designated shift location during each of a plurality of cycles of the clock signal, and
means for controlling the shift direction and the designated shift location such that a sequential arrangement of the data elements of the data unit in the data sequence generated to serialize the parallel data corresponds to the second data format, different from a sequential arrangement corresponding to the first data format.
